(19) United States
(12) Patent Application Publication
(10) Pub. No.: US 2024/0055480 A1
(43) Pub. Date: Feb. 15, 2024

(54) SEMICONDUCTOR STRUCTURE AND MANUFACTURING METHOD THEREOF

(71) Applicant: Taiwan Semiconductor Manufacturing Company, Ltd., Hsinchu (TW)

(72) Inventors: Yun Chen TENG, New Taipei City (TW); Chen-Fong TSAI, Hsinchu City (TW); Li-Chi YU, Hsinchu County (TW); Huicheng CHANG, Tainan City (TW); Yee-Chia YEO, Hsinchu City (TW)

(73) Assignee: Taiwan Semiconductor Manufacturing Company, Ltd., Hsinchu (TW)

(21) Appl. No.: 17/886,921

(22) Filed: Aug. 12, 2022

(51) Int. Cl. H01L 29/06; H01L 29/775; H01L 29/66; H01L 29/786; H01L 21/8238

(52) U.S. Cl. CPC H01L 29/0673; H01L 29/0649; H01L 29/775; H01L 29/66439; H01L 29/78696; H01L 29/7869; H01L 21/823807; H01L 21/823814; H01L 21/823821

(57) ABSTRACT

A method includes forming fin structures upwardly extending above a semiconductor substrate; conformally depositing a first dielectric layer over the fin structures; depositing a flowable oxide over the first dielectric layer and between the fin structures; performing, at a temperature lower than about 500° C., a steam annealing process on the flowable oxide to cure the flowable oxide; after performing the steam annealing process, etching the cured flowable oxide until a top surface of the cured flowable oxide is lower than top surfaces of the fin structures; forming a second dielectric layer over the cured flowable oxide; forming a first gate structure extending across a first one of the fin structures and a second gate structure extending across a second one of the fin structures; forming first sources/drain regions on the first one of the fin structures and second sources/drain regions on the second one of the fin structures.

### BACKGROUND

Semiconductor integrated circuit (IC) industry has experienced rapid growth. Technological advances in IC materials and design have produced generations of ICs where each generation has smaller and more complex circuits than the previous generation. However, these advances have increased the complexity of processing and manufacturing ICs and, for these advances to be realized, similar developments in IC processing and manufacturing are needed.

In the course of IC evolution, functional density (i.e., the number of interconnected devices per chip area) has generally increased while geometry size (i.e., the smallest component (or line) that can be created using a fabrication process) has decreased. This scaling down process generally provides benefits by increasing production efficiency and lowering associated costs. Such scaling-down also produces a relatively high power dissipation value, which may be addressed by using low power dissipation devices such as complementary metal-oxide-semiconductor (CMOS) devices.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1-27 illustrate perspective views and cross-sectional views of intermediate stages of a semiconductor structure in accordance with some embodiments.

FIGS. 28-56 illustrate perspective views and cross-sectional views of intermediate stages of a semiconductor structure in accordance with some embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

As used herein, “around,” “about,” “approximately,” or “substantially” may mean within 20 percent, or within 10 percent, or within 5 percent of a given value or range. One skilled in the art will realize, however, that the value or range recited throughout the description are merely examples, and may be reduced with the down-scaling of the integrated circuits. Numerical quantities given herein are approximate, meaning that the term “around,” “about,” “approximately,” or “substantially” can be inferred if not expressly stated.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

Embodiments of the present disclosure are directed to, but not otherwise limited to, a fin-like field-effect transistor (FinFET) device. The FinFET device, for example, may be a complementary metal-oxide-semiconductor (CMOS) device including a P-type metal-oxide-semiconductor (PMOS) FinFET device and an N-type metal-oxide-semiconductor (NMOS) FinFET device. The following disclosure will continue with one or more FinFET examples to illustrate various embodiments of the present disclosure. It is understood, however, that the application should not be limited to a particular type of device, except as specifically claimed.

The fins may be patterned by any suitable method. For example, the fins may be patterned using one or more photolithography processes, including double-patterning or multi-patterning processes. The double-patterning or the multi-patterning processes combine photolithography and self-aligned processes, allowing patterns to be created that have, for example, pitches smaller than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used to pattern the fins.

Some embodiments discussed herein are discussed in the context of nano-PETs formed using a gate-last process. In some embodiments, a gate-first process may be used. Also, some embodiments contemplate aspects used in planar devices, such as planar FETs, or in fin field-effect transistors (FinFETs). For example, FinFETs may include fins on a substrate, with the fins acting as channel regions for the FinFETs. Similarly, planar FETs may include a substrate, with portions of the substrate acting as channel regions for the planar FETs.

In order to forming an isolator between two active devices, a dummy fin structure is provided. The dummy fin can be a core-shell structure including a metal oxide layer wrapping around a flowable CVD oxide. The metal oxide layer can enlarge the subsequent etch process window (e.g., high selectivity to Si,SiGe,oxide), and the flowable CVD oxide has an improved k-value for the dummy fin. However, an annealing process with a high temperature for curing the flowable CVD oxide may oxidize a surrounding semiconductive fin structure, which in turn damages the semiconductive fin structure, and thereby reducing the yield of the IC structure. Therefore, the present disclosure in various embodiments provides a method for curing the flowable CVD oxide without a high temperature, and thus the surrounding semiconductive fin structure will not be impacted by the curing process.

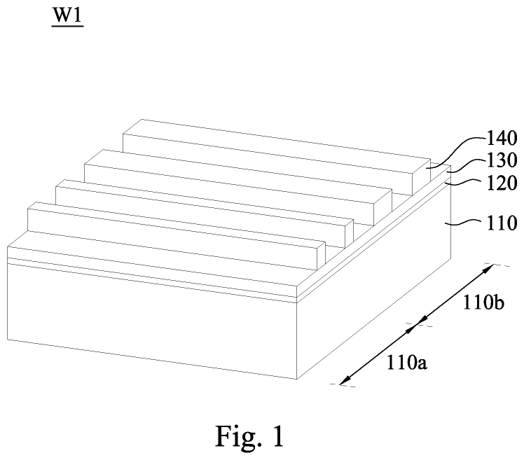

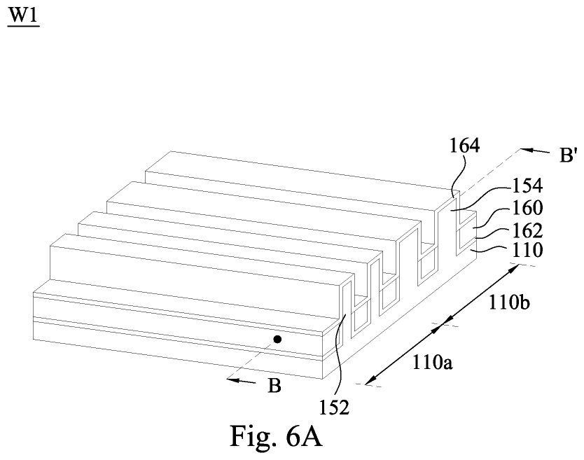

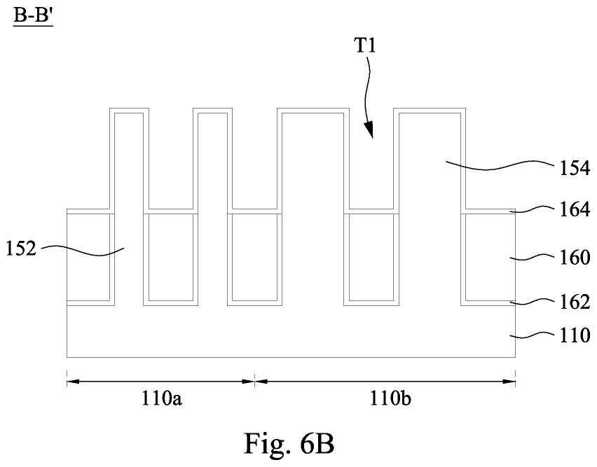

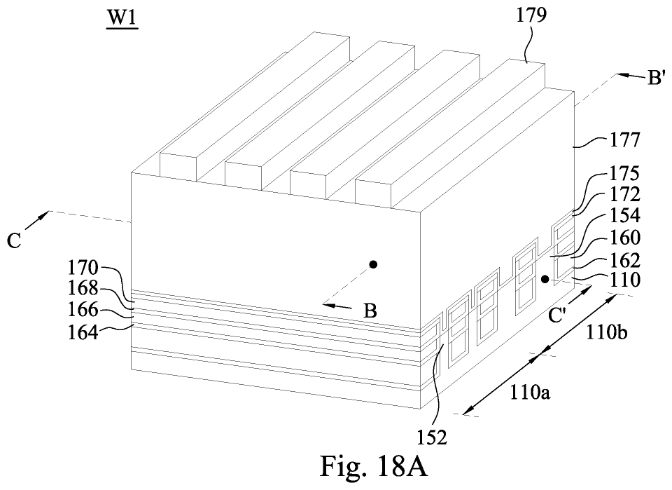

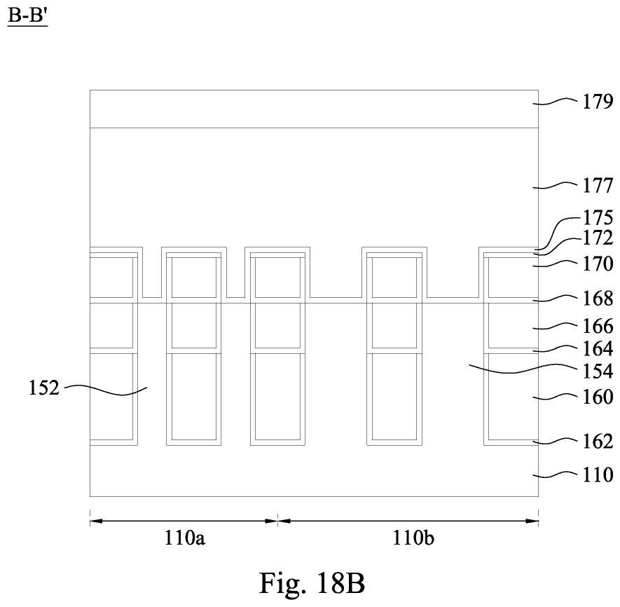

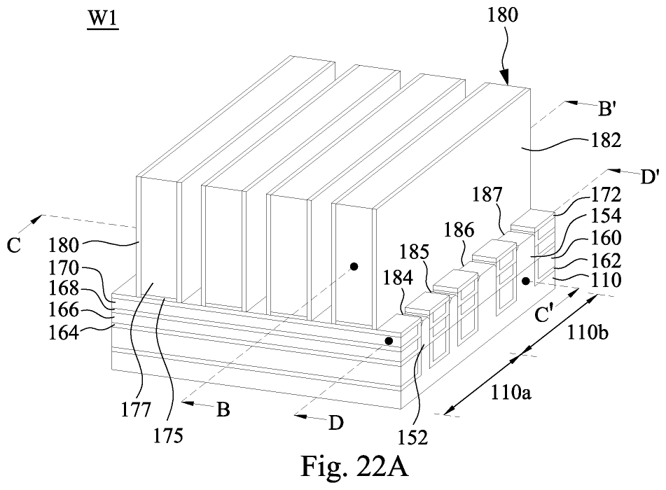

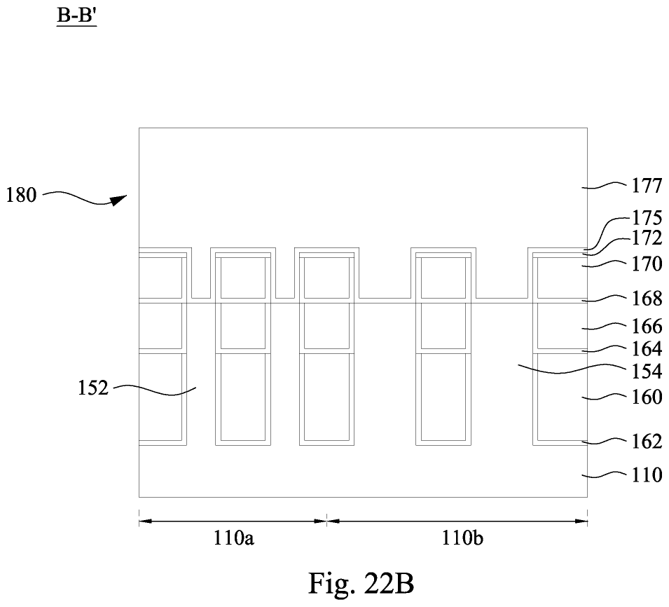

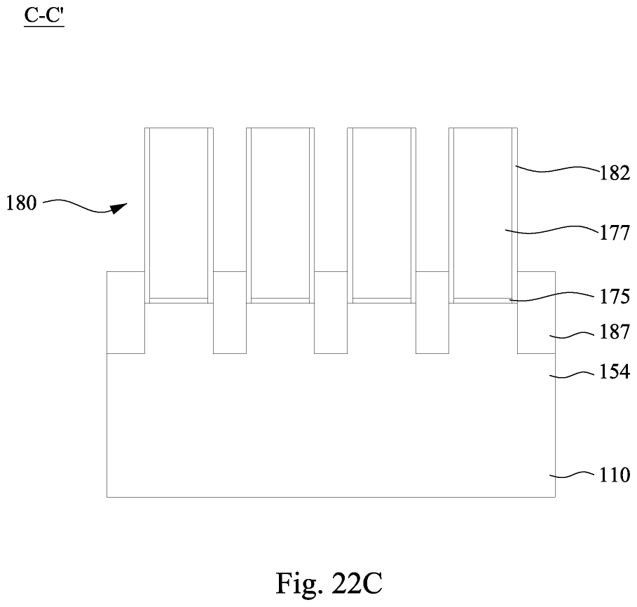

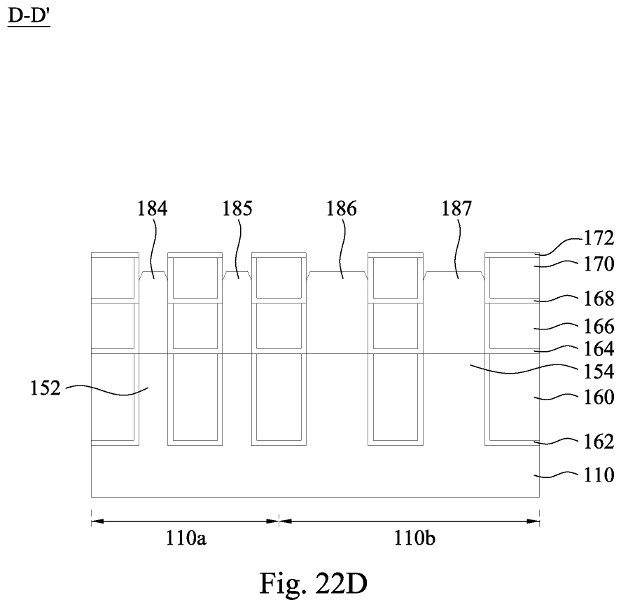

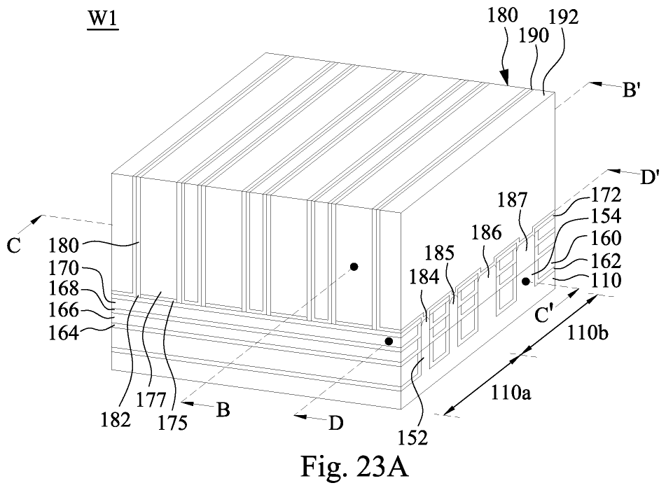

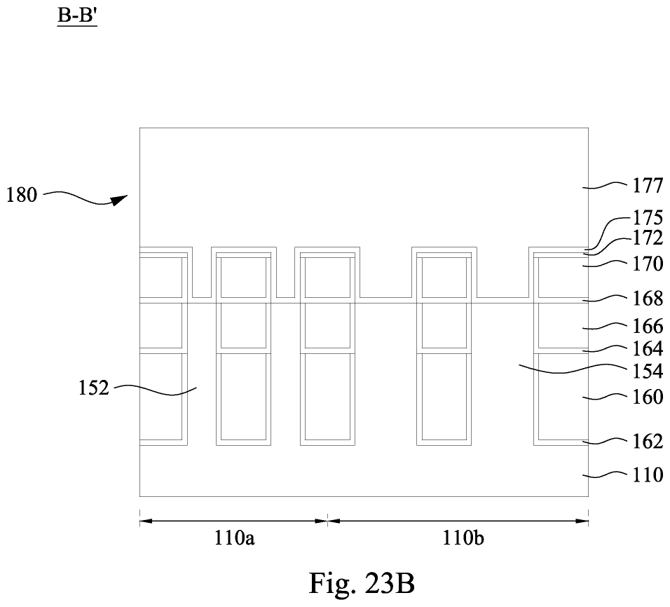

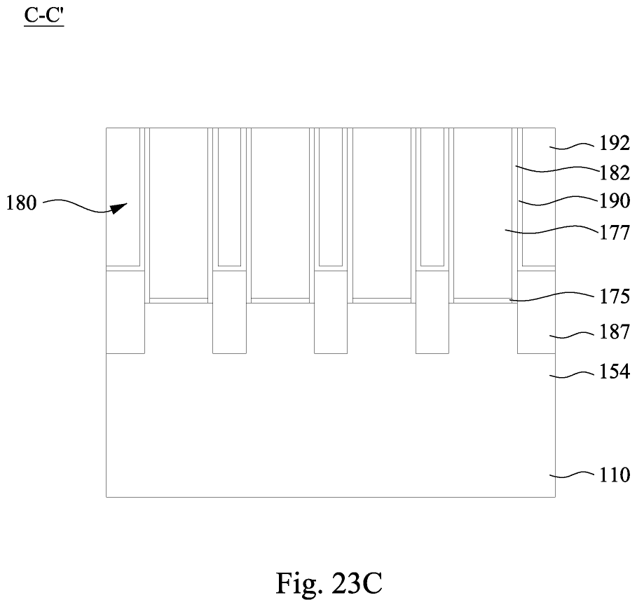

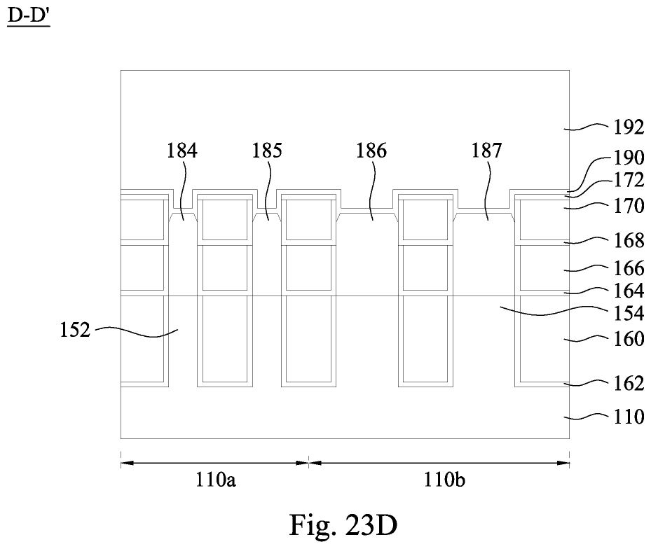

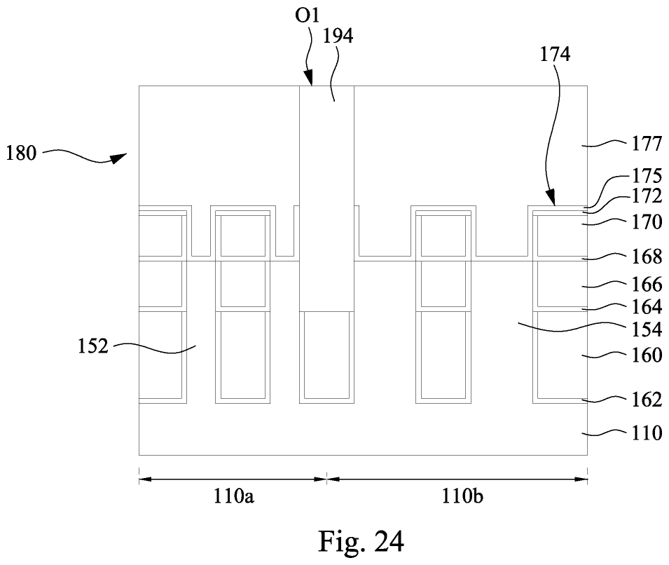

Reference is made to FIGS. 1-27. FIGS. 1, 2, 3, 4, 5, 6A, 7A, 8A, 9A, 10A, 11A, 12A, 13A, 14A, 15A, 16A, 17A, 18A, 19A, 20A, 21A, 22A, and 23A illustrate perspective views of intermediate stages of a semiconductor structure in accordance with some embodiments. FIGS. 6B, 7B, 8B, 9B, 10B, 11B, 12B, 13B, 14B, 15B, 16B, 17B, 18B, 19B, 20B, 21B, 22B, and 23B illustrate cross-sectional views obtained from the reference cross-sections B-B′ in FIGS. 6A, 7A, 8A, 9A, 10A, 11A, 12A, 13A, 14A, 15A, 16A, 17A, 18A, 19A, 20A, 21A, 22A, and 23A, respectively. FIGS. 18C, 19C, 20C, 21C, 22C, and 23C illustrate cross-sectional views obtained from the reference cross-sections C-C′ in FIGS. 18A, 19A, 20A, and 21A, respectively. FIGS. 22D and 23D illustrate cross-sectional views obtained from the reference cross-sections D-D′ in FIGS. 22A and 23A, respectively. FIGS. 24, 25, 26, and 27 illustrate cross-sectional views of intermediate stages of a semiconductor structure corresponding to FIGS. 22D and 23D in accordance with some embodiments.

With reference to FIG. 1. A wafer W1 undergoes a series of deposition and photolithography processes, such that a pad layer 120, a mask layer 130 and a patterned photoresist layer 140 are formed on a substrate 110 of the wafer W1. In some embodiments, the substrate 110 is a semiconductor substrate, such as a bulk semiconductor, a semiconductor-on-insulator (SOI) substrate, or the like. An SOI substrate includes a layer of a semiconductor material formed on an insulator layer. The insulator layer may be, by way of example and not limitation, a buried oxide (BOX) layer, a silicon oxide layer, or the like. The insulator layer is provided on a substrate, a silicon or glass substrate. Other substrates, such as a multi-layered or gradient substrate may also be used. In some embodiments, the semiconductor material of the substrate 110 may include silicon; germanium; a compound semiconductor including silicon carbide, gallium arsenic, gallium phosphide, indium phosphide, indium arsenide, and/or indium antimonide; an alloy semiconductor including SiGe, GaAsP, AlInAs, AlGaAs, GaInAs, GaInP, and/or GaInAsP; or combinations thereof.

In some embodiments, the substrate 110 may have device regions 110a and 110b, such as logic region or storage region. In some embodiments, the device region 110a may be served as one of the logic region and the storage region, and the device region 110b may be served as another one of the logic region and the storage region. In some embodiments, both of the device regions 110a and 110b are of the logic region. In some embodiments, both of the device regions 110a and 110b are of the storage region. In some embodiments, a P-type well and an N-type well in the substrate 110 which divide the substrate 110 into separate regions for different types of devices or transistors. Example materials of the P-type well and the N-type well include, but are not limited to, semiconductor materials doped with various types of p-type dopants and/or n-type dopants. In some embodiments, the P-type well includes p-type dopants, and the N-type well includes n-type dopants. The N-type well is a region for forming p-channel metal-oxide semiconductor (PMOS) transistors, and the P-type well is a region for forming n-channel metal-oxide semiconductor (NMOS) transistors. The described conductivity of the well regions and herein is an example. Other arrangements are within the scope of various embodiments.

In some embodiments, the pad layer 120 is a thin film including silicon oxide formed using, by way of example and not limitation, a thermal oxidation process. The pad layer 120 may act as an adhesion layer between the substrate 110 and mask layer 130. The pad layer 120 may also act as an etch stop layer for etching the mask layer 130. In some embodiments, the mask layer 130 is formed of silicon nitride, by way of example and not limitation, using low-pressure chemical vapor deposition (LPCVD) or plasma enhanced chemical vapor deposition (PECVD). The mask layer 130 is used as a hard mask during subsequent photolithography processes. The photoresist layer 140 is formed on the mask layer 130 and is then patterned, forming openings in the photoresist layer 140, so that regions of the mask layer 130 are exposed.

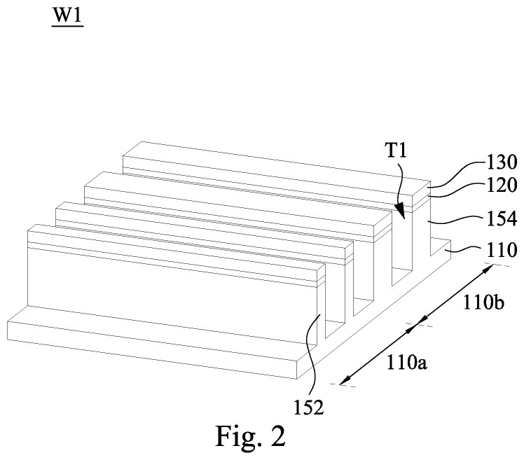

With reference to FIG. 2. The mask layer 130 and pad layer 120 are etched through the photoresist layer 140, exposing the underlying substrate 110. The exposed substrate 110 is then etched, forming trenches T1. Portions of the substrate 110 between the neighboring trenches T1 within the device region 110a can be referred to as semiconductor fin 152. Portions of the substrate 110 between the neighboring trenches T1 within the device region 110b can be referred to as a semiconductor fin 154. After etching the substrate 110, the photoresist layer 140 is removed. Next, a cleaning step may be optionally performed to remove a native oxide of the semiconductor substrate 110. The cleaning may be performed using diluted hydrofluoric (HF) acid, by way of example and not limitation. According to the various aspects of the present disclosure, the semiconductor fins 152 and 154 extend along a first direction. In some embodiments, the semiconductor fins 152 and 154 may also be referred to as oxide-definition (OD) regions, semiconductive channel patterns, or nanostructured pedestals each having a top surface and opposite side surfaces. In some embodiments where the semiconductor fin 152 and/or 154 is made of silicon germanium, the semiconductor fin 152 and/or 154 may have a germanium atomic concentration in a range from about 15% to about 35%, such as 15, 16, 17, 18, 19, 20, 21, 22, 23, 24, 25, 26, 27, 28, 29, 30, 31, 32, 33, 34, or 35%.

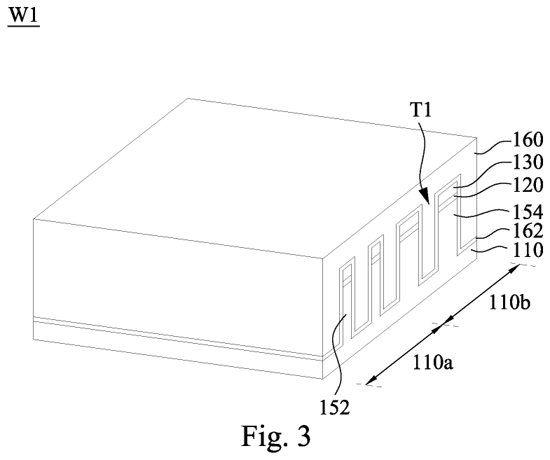

With reference to FIG. 3. A dielectric layer 160 is formed to overfill the trenches T1 and cover the semiconductor fins 152 and 154. The dielectric layer 160 in the trenches T1 can be referred to as a shallow trench isolation (STI) structure. In some embodiments, the dielectric layer 160 may be made of low-K dielectric materials. By way of example but not limiting the present disclosure, the dielectric layer 160 may be made of silicon oxide, silicon nitride, silicon oxynitride, fluoride-doped silicate glass (FSG), silicon carbide, silicon nitride, the like, or a combination thereof. In some embodiments, the dielectric layer 160 may be formed using flowable chemical vapor deposition (FCVD), spin-on coating, CVD, ALD, high-density plasma chemical vapor deposition (HDPCVD), LPCVD, the like, or a combination thereof. In some embodiments where FCVD is used to form the dielectric layer 160, a silicon- and nitrogen-containing precursor (for example, trisilylamine (TSA) or disilylamine (DSA)) is used, and hence the resulting dielectric layer 160 is flowable (jelly-like). In some embodiments, the dielectric layer 160 is formed using an alkylamino silane based precursor. During the deposition of the dielectric layer 160, plasma is turned on to activate the gaseous precursors for forming the flowable oxide. In some embodiments, the dielectric layer 160 may be formed using silane (SiH₄) and oxygen (O₂) as reacting precursors. In some embodiments, the dielectric layer 160 may be formed using a sub-atmospheric CVD (SACVD) process or high aspect-ratio process (HARP), in which process gases may include tetraethylorthosilicate (TEOS) and ozone (O₃). In some embodiments, the dielectric layer 160 may be formed using a spin-on-dielectric (SOD) process, such as hydrogen silsesquioxane (HSQ) or methyl silsesquioxane (MSQ). Other processes and materials may be used. In some embodiments, the dielectric layer 160 can be interchangeably referred to a flowable oxide, a dielectric material, or cured flowable oxide material.

In some embodiments, the dielectric layer 160 can have a multi-layer structure, by way of example and not limitation, a liner layer 162 is conformally formed over the substrate 110. The liner layer 162 is formed in trenches T1 and on the sidewalls of the semiconductor fins 152 and 154. The liner layer 162 may be a conformal layer whose horizontal portions and vertical portions have thicknesses close to each other. By way of example but not limiting the present disclosure, the liner layer 162 may have a thickness between about 10 Å and about 40 Å. The liner layer 162 may prevent (or at least reduce) the diffusion of semiconductor material from substrate 110 into dielectric layer 160 during a subsequent annealing process. Other processes and materials may be used. In some embodiments, the liner layer 162 may be made of an oxide base dielectric material, a carbon base dielectric material, a nitride base dielectric material, combinations thereof, or other suitable materials. By way of example but not limiting the present disclosure, the liner layer 162 may include SiN, SiOC, SiON, SiOCN, or combinations thereof. In some embodiments, the liner layer 162 may be deposited using any suitable method, such as CVD, physical vapor deposition (PVD), ALD, PEALD, PECVD, SACVD, FCVD, spin-on, and/or the like, or a combination thereof. In some embodiments, the liner layer 162 can be interchangeably referred to a dielectric film.

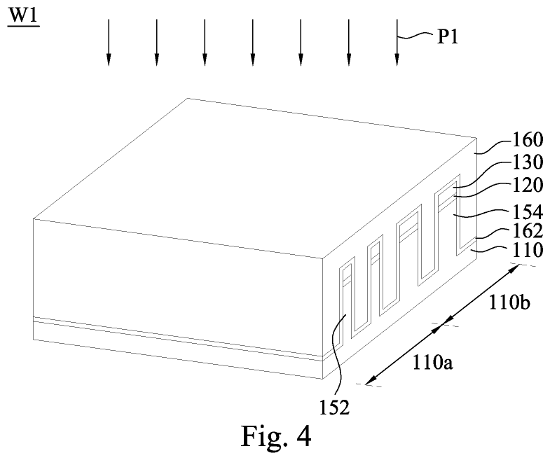

With reference to FIG. 4. An annealing process P1 is performed, which converts flowable dielectric layer 160 into a solid dielectric material. In some embodiments, the annealing process P1 can be interchangeably referred to a thermal treatment. After the flowable dielectric layer 160 is deposited, an in-situ steam thermal annealing step of the annealing process P1 can be performed on the as-deposited flowable dielectric layer 160 to cure the flowable dielectric layer 160. In some embodiments, the steam thermal annealing step of the annealing process P1 can be interchangeably referred to a curing step. In-situ means the steam thermal annealing step of the annealing process P1 is performed in the process chamber for depositing the flowable dielectric layer 160. In some embodiments, the steam thermal annealing step of the annealing process P1 can be performed in a different chamber (or ex-situ). The steam thermal annealing step of the annealing process P1 may increase the oxygen content of the as-deposited flowable dielectric layer 160, which is made of a network of SiO_{A}N_{B}H_{C} (or SiONH), and most of NH ions and H ions of the flowable dielectric layer 160 can be removed. An oxygen source, such as steam (H₂O), can be provided to assist the conversion of the SiONH network into SiO (or SiO₂) network. The steam thermal annealing step of the annealing process P1 causes the flowable dielectric layer 160 to shrink. The duration and the temperature of the steam thermal annealing step of the annealing process P1 affect the amount of shrinkage. The steam thermal annealing step of the annealing process P1 can be conducted in a furnace, in some embodiments. In some embodiments, a temperature for the steam thermal annealing step of the annealing process P1 may be in a range from about 150° C. to about 800° C., such as 150, 200, 300, 400, 500, 600, 700, or 800° C., by way of example and not limitation. In some embodiments, the steam thermal annealing step of the annealing process P1 may starts at about 150° C. and ramps up the temperature gradually to a predetermined temperature, such as about 800° C. The gas or gases used for the steam thermal annealing step of the annealing process P1 may include H₂O, O₂, N₂, or combinations thereof.

After the steam thermal annealing step of the annealing process P1 described above, a “dry” (without steam) thermal annealing step of the annealing process P1 is conducted to convert the SiOH and SiO network into SiO (or SiO₂) network. During the dry thermal annealing step of the annealing process P1, steam is not used. In some embodiments, an inert gas, such as N₂, is used during the dry thermal annealing step of the annealing process P1. In some embodiments, the gas or gases used for the dry thermal annealing step of the annealing process P1 may include O₂. In some embodiments, the anneal temperature of the dry thermal annealing step of the annealing process P1 may be less than about 800° C. The dry thermal annealing step of the annealing process P1 is conducted in a furnace, in some embodiments. The gas or gases used for the dry thermal annealing step of the annealing process P1 may include an inert gas, such as N₂, Ar, He or combinations thereof. The duration of the dry thermal annealing step of the annealing process P1 is a range from about 30 minutes to about 3 hours. The dry thermal annealing step of the annealing process P1 converts the network of SiOH and SiO in the flowable dielectric layer 160 to a network of SiO (or SiO₂). The dry thermal annealing step of the annealing process P1 may also cause flowable dielectric layer 160 to shrink further. The duration and temperature of the dry thermal annealing step of the annealing process P1 affect the amount of shrinkage. The steam annealing step and the dry thermal annealing step of the annealing process P1 of the annealing process P1 cause flowable dielectric layer 160 to shrink. In some embodiments, the volume of the flowable dielectric layer 160 shrinks in a range from about 5% to about 20%. The duration of the steam annealing step and the dry thermal annealing step of the annealing process P1 affect the amount of shrinking.

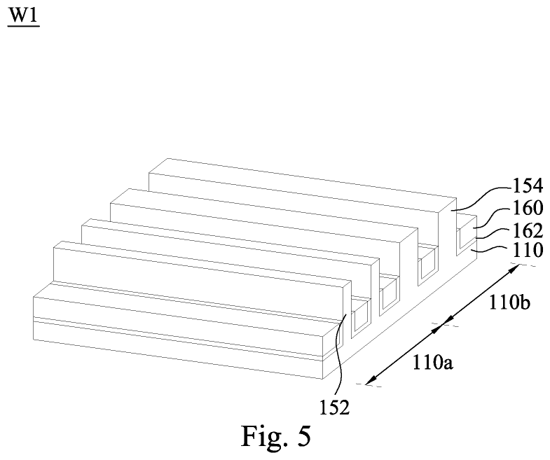

With reference to FIG. 5. A planarization process such as chemical mechanical polish (CMP) is performed to remove the excess dielectric layer 160 and the liner layer 162 over the semiconductor fins 152 and 154. In some embodiments, the planarization process may also remove the mask layer 130 and the pad layer 120 such that top surfaces of the semiconductor fins 152 and 154 are exposed. In some embodiments, the planarization process stops when the mask layer 130 is exposed. In such embodiments, the mask layer 130 may act as the CMP stop layer in the planarization. If the mask layer 130 and the pad layer 120 are not removed by the planarization process, the mask layer 130, if formed of silicon nitride, may be remove by a wet process using hot H₃PO₄, and the pad layer 120, if formed of silicon oxide, may be removed using diluted HF. Subsequently, the dielectric layer 160 and the liner layer 162 are recessed, for example, through an etching operation, in which diluted HF, SiCoNi (including HF and NH₃), or the like, may be used as the etchant. After recessing the dielectric layer 160 and the liner layer 162, portions of the semiconductor fins 152 and 154 are higher than top surfaces of the dielectric layer 160 and the liner layer 162.

It is understood that the processes described above are merely an example of how the semiconductor fins 152 and 154 and the dielectric layer 160 and the liner layer 162 are formed. In some embodiments, a dielectric layer can be formed over a top surface of the substrate 110; trenches can be etched through the dielectric layer; homoepitaxial structures can be epitaxially grown in the trenches; and the dielectric layer can be recessed such that the homoepitaxial structures protrude from the dielectric layer to form fins. In still other embodiments, heteroepitaxial structures can be used for the fin. For example, the semiconductor fins 152 and 154 can be recessed, and a material different from the recessed semiconductor fins 152 and 154 is epitaxially grown in its place. In even further embodiments, a dielectric layer can be formed over a top surface of the substrate 110; trenches can be etched through the dielectric layer; heteroepitaxial structures can be epitaxially grown in the trenches using a material different from the substrate 110; and the dielectric layer can be recessed such that the heteroepitaxial structures protrude from the dielectric layer to form fins. In some embodiments where homoepitaxial or heteroepitaxial structures are epitaxially grown, the grown materials may be in-situ doped during growth, which may obviate prior implanting of the fins although in-situ and implantation doping may be used together. In some embodiments, the semiconductor fins 152 and 154 may include silicon germanium (SiₓGe₁₋ₓ, where x can be between approximately 0 and 1), silicon carbide, pure or substantially pure germanium, a III-V compound semiconductor, a II-VI compound semiconductor, or the like. For example, the available materials for forming III-V compound semiconductor include, but are not limited to, InAs, AlAs, GaAs, InP, GaN, InGaAs, InAlAs, GaSb, AlSb, AlP, GaP, or the like.

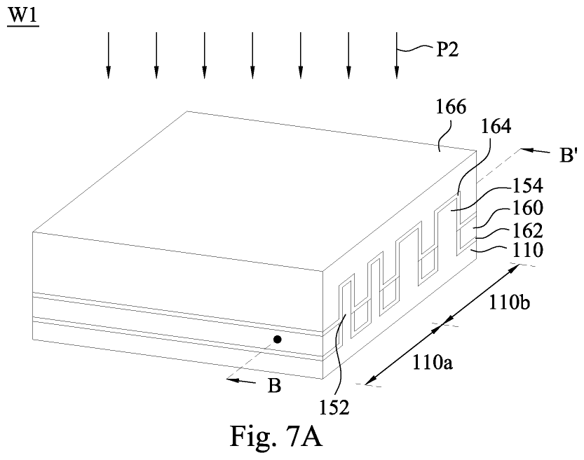

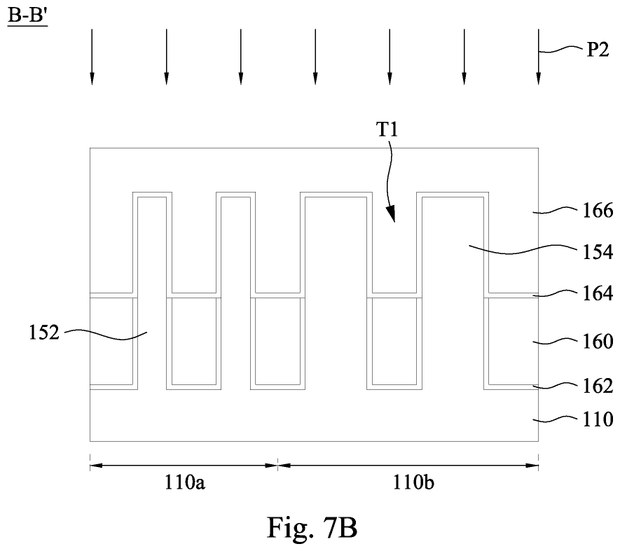

With reference to FIGS. 6A and 6B. A liner layer 164 is conformally formed over the substrate 110. The liner layer 164 is formed in trenches T1 (see FIG. 6B) and on the sidewalls of the semiconductor fins 152 and 154 and the top surfaces of the dielectric layer 160 and the liner layer 162. The liner layer 164 may be a conformal layer whose horizontal portions and vertical portions have thicknesses close to each other. By way of example but not limiting the present disclosure, the liner layer 164 may have a thickness between about 10 Å and about 40 Å. The liner layer 164 may prevent (or at least reduce) the diffusion of semiconductor material from substrate 110 into dielectric layer 166 formed subsequently (see FIGS. 7A and 7B) during a subsequent annealing process. Other processes and materials may be used. In some embodiments, the liner layer 164 may be made of an oxide base dielectric material, a carbon base dielectric material, a nitride base dielectric material, combinations thereof, or other suitable materials. By way of example but not limiting the present disclosure, the liner layer 164 may include SiN, SiOC, SiON, SiOCN, or combinations thereof. In some embodiments, the liner layer 162 may be deposited using any suitable method, such as CVD, physical vapor deposition (PVD), ALD, PEALD, PECVD, SACVD, FCVD, spin-on, and/or the like, or a combination thereof. In some embodiments, the liner layer 164 can be interchangeably referred to a dielectric film.

With reference to FIGS. 7A and 7B. A dielectric layer 166 is formed to overfill the trenches T1 (see FIG. 7B) and cover the semiconductor fins 152 and 154. The dielectric layer 166 in the trenches T1 can be referred to as a shallow trench isolation (STT) structure. In some embodiments, the dielectric layer 166 may be made of low-K dielectric materials. By way of example but not limiting the present disclosure, the dielectric layer 166 may be made of silicon oxide, silicon nitride, silicon oxynitride, fluoride-doped silicate glass (FSG), silicon carbide, silicon nitride, the like, or a combination thereof. In some embodiments, the dielectric layer 166 may be formed using flowable chemical vapor deposition (FCVD), spin-on coating, CVD, ALD, high-density plasma chemical vapor deposition (HDPCVD), LPCVD, the like, or a combination thereof. In some embodiments where FCVD is used to form the dielectric layer 166, a silicon- and nitrogen-containing precursor (for example, trisilylamine (TSA) or disilylamine (DSA)) is used, and hence the resulting dielectric layer 166 is flowable (jelly-like). In some embodiments, the dielectric layer 166 is formed using an alkylamino silane based precursor. During the deposition of the dielectric layer 166, plasma is turned on to activate the gaseous precursors for forming the flowable oxide. In some embodiments, the dielectric layer 166 may be formed using silane (SiH₄) and oxygen (O₂) as reacting precursors. In some embodiments, the dielectric layer 166 may be formed using a sub-atmospheric CVD (SACVD) process or high aspect-ratio process (HARP), in which process gases may include tetraethylorthosilicate (TEOS) and ozone (O₃). In some embodiments, the dielectric layer 166 may be formed using a spin-on-dielectric (SOD) process, such as hydrogen silsesquioxane (HSQ) or methyl silsesquioxane (MSQ). Other processes and materials may be used.

Subsequently, an annealing process P2 is performed, which converts flowable dielectric layer 166 into a solid dielectric material. In some embodiments, the annealing process P2 can be interchangeably referred to a thermal treatment. After the flowable dielectric layer 166 is deposited, an in-situ steam thermal annealing step of the annealing process P2 can be performed on the as-deposited flowable dielectric layer 166 to cure the flowable dielectric layer 166. In some embodiments, the steam thermal annealing step of the annealing process P2 can be interchangeably referred to a curing step. In-situ means the steam thermal annealing step of the annealing process P2 is performed in the process chamber for depositing the flowable dielectric layer 166. In some embodiments, the steam thermal annealing step of the annealing process P2 can be performed in a different chamber (or ex-situ). The steam thermal annealing step of the annealing process P2 may increase the oxygen content of the as-deposited flowable dielectric layer 166, which is made of a network of SiO_{A}N_{B}H_{C} (or SiONH), and most of NH ions and H ions of the flowable dielectric layer 166 can be removed. An oxygen source, such as steam (H₂O), can be provided to assist the conversion of the SiONH network into SiO (or SiO₂) network. The steam thermal annealing step of the annealing process P2 causes the flowable dielectric layer 166 to shrink. The duration and the temperature of the steam thermal annealing step of the annealing process P2 affect the amount of shrinkage. The steam thermal annealing step of the annealing process P2 can be conducted in a furnace, in some embodiments. In some embodiments, a temperature for the steam thermal annealing step of the annealing process P2 may be in a range from about 150° C. to about 800° C., such as 150, 200, 300, 400, 500, 600, 700, or 800° C., by way of example and not limitation. In some embodiments, the steam thermal annealing step of the annealing process P2 may starts at about 150° C. and ramps up the temperature gradually to a predetermined temperature, such as about 800° C. The gas or gases used for the steam thermal annealing step of the annealing process P2 may include H₂O, O₂, N₂, or combinations thereof.

After the steam thermal annealing step of the annealing process P2 described above, a “dry” (without steam) thermal annealing step of the annealing process P2 is conducted to convert the SiOH and SiO network into SiO (or SiO₂) network. During the dry thermal annealing step of the annealing process P2, steam is not used. In some embodiments, an inert gas, such as N₂, is used during the dry thermal annealing step of the annealing process P2. In some embodiments, the gas or gases used for the dry thermal annealing step of the annealing process P2 may include O₂. In some embodiments, the anneal temperature of the dry thermal annealing step of the annealing process P2 may be less than about 800° C. The dry thermal annealing step of the annealing process P2 is conducted in a furnace, in some embodiments. The gas or gases used for the dry thermal annealing step of the annealing process P2 may include an inert gas, such as N₂, Ar, He or combinations thereof. The duration of the dry thermal annealing step of the annealing process P2 is a range from about 30 minutes to about 3 hours. The dry thermal annealing step of the annealing process P2 converts the network of SiOH and SiO in the flowable dielectric layer 166 to a network of SiO (or SiO₂). The dry thermal annealing step of the annealing process P2 may also cause flowable dielectric layer 166 to shrink further. The duration and temperature of the dry thermal annealing step of the annealing process P2 affect the amount of shrinkage. The steam annealing step and the dry thermal annealing step of the annealing process P2 of the annealing process P2 cause flowable dielectric layer 166 to shrink. In some embodiments, the volume of the flowable dielectric layer 166 shrinks in a range from about 5% to about 20%. The duration of the steam annealing step and the dry thermal annealing step of the annealing process P2 affect the amount of shrinking. In some embodiments, the dielectric layer 166 can be interchangeably referred to a flowable oxide, a dielectric material, or cured flowable oxide material.

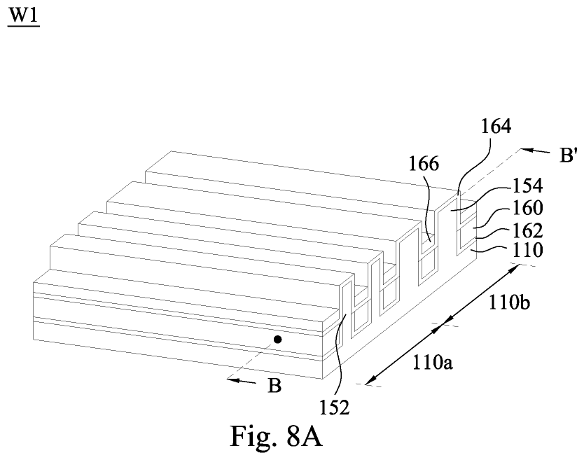

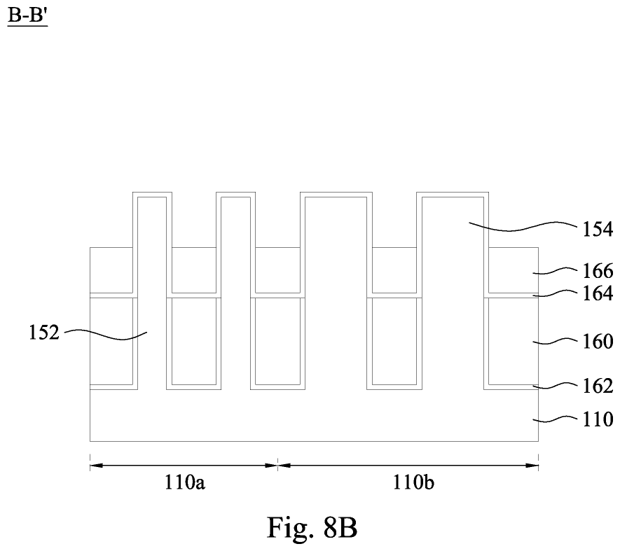

With reference to FIGS. 8A and 8B. A planarization process such as chemical mechanical polish (CMP) is performed to remove the excess dielectric layer 166 over the semiconductor fins 152 and 154. In some embodiments, the planarization process stops when the liner layer 164 is exposed. In such embodiments, the liner layer 164 may act as the CMP stop layer in the planarization. Subsequently, the dielectric layer 166 is recessed, for example, through an etching operation, in which diluted HF, SiCoNi (including HF and NH₃), or the like, may be used as the etchant. After recessing the dielectric layer 166, portions of the semiconductor fins 152 and 154 are higher than the top surface of the dielectric layer 166.

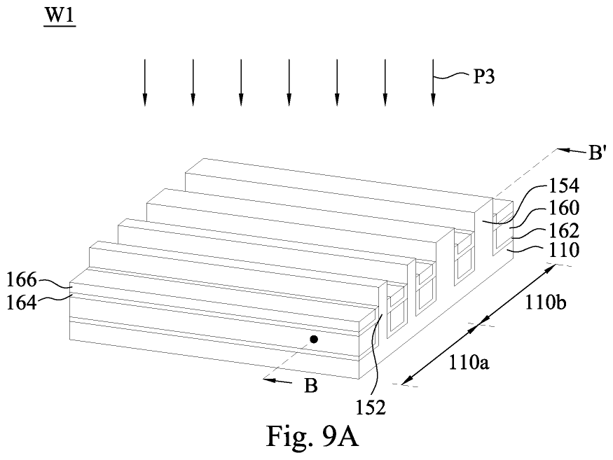

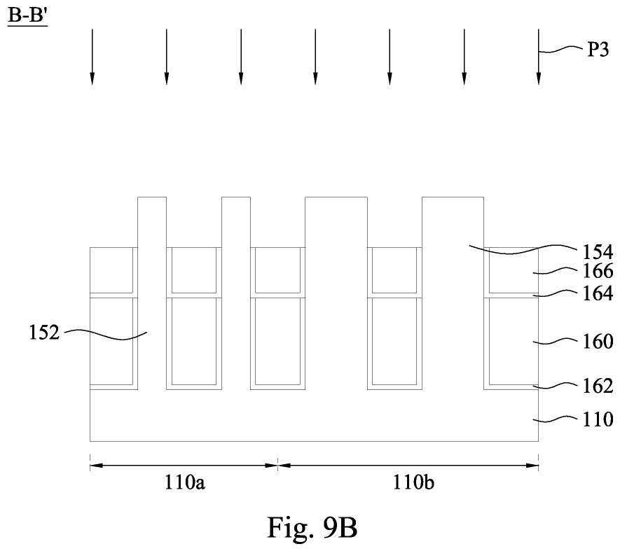

With reference to FIGS. 9A and 9B. An etching process P3 is performed to remove the liner layer 164 exposed from the dielectric layer 166. The etching process P3 is a selective etching process that uses an etchant etching the liner layer 164 at a faster etch rate than it etches the dielectric layer 166. For example, the etch rate of the etching process P3 to the liner layer 164 is greater than about twice the etch rate of the etching process P3 to the dielectric layer 166. If the etch rate of the etching process P3 to the liner layer 164 is lower than about twice the etch rate of the etching process P3 to the dielectric layer 166, the etching process P3 may excessively consume the dielectric layer 166 and thus the semiconductor fins 152 and 154 may be damaged, and thus the yield may reduce. In this way, the dielectric layer 166 remains substantially intact after removing the liner layer 164. In some embodiments, the etching process P3 may be performed using an isotropic etching process. For example, the etchant used in the etching process P3 includes phosphoric acid (H₃PO₄).

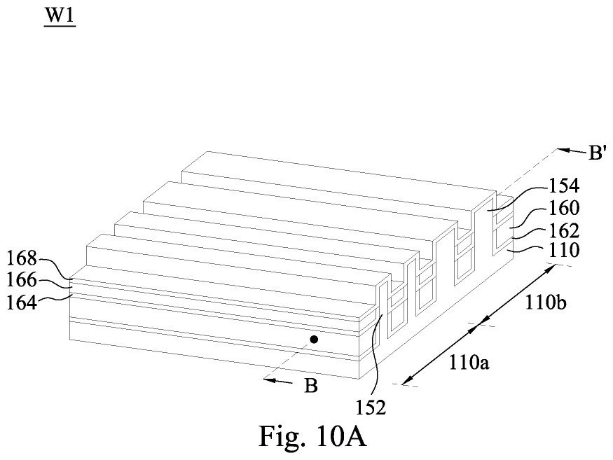

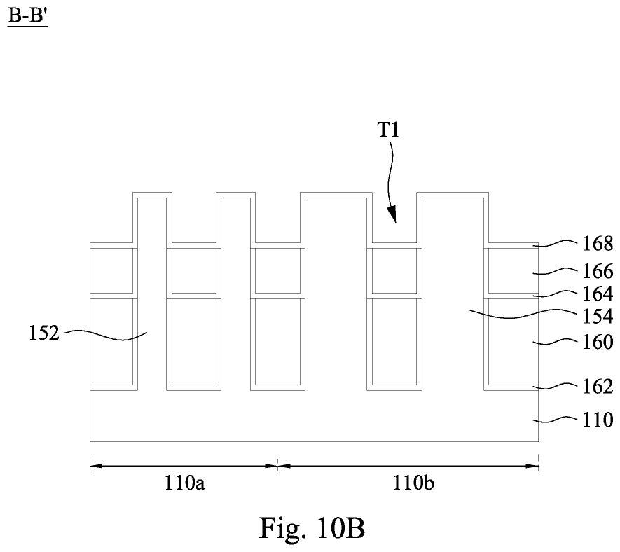

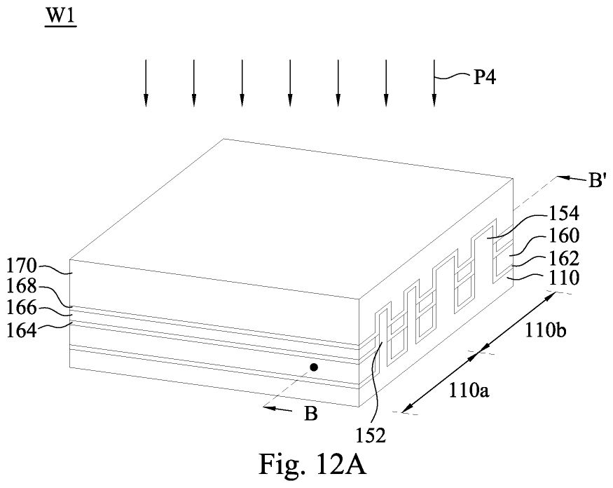

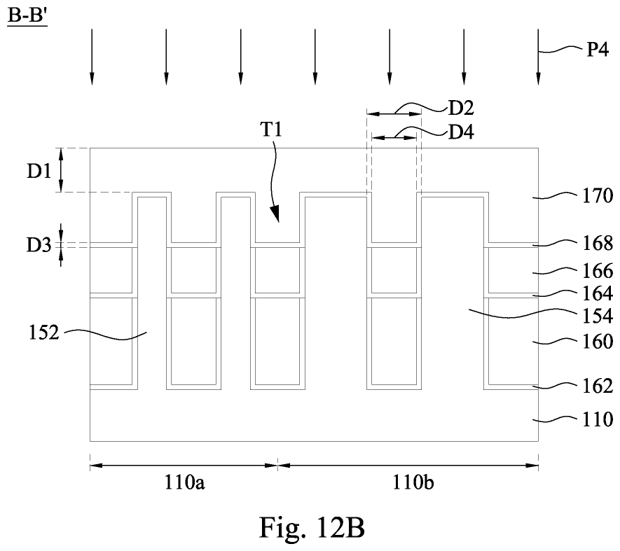

With reference to FIGS. 10A and 10B. A liner layer 168 is conformally formed over the substrate 110. The liner layer 168 is formed in trenches T1 (see FIG. 10B) and on the sidewalls of the semiconductor fins 152 and 154 and the top surfaces of the dielectric layer 166 and the liner layer 164. The liner layer 168 may be a conformal layer whose horizontal portions and vertical portions have thicknesses close to each other. By way of example but not limiting the present disclosure, the liner layer 168 may have a thickness between about 10 Å and about 40 Å. The liner layer 168 may prevent (or at least reduce) the diffusion of semiconductor material from substrate 110 into dielectric layer 166 formed subsequently (see FIGS. 12A and 12B) during a subsequent annealing process. Other processes and materials may be used.

In some embodiments, the liner layer 168 may be made of an oxide base dielectric material, a carbon base dielectric material, a nitride base dielectric material, combinations thereof, or other suitable materials. In some embodiments, the liner layer 168 may include SiOC, SiON, SiOCN, or combinations thereof. In some embodiments, the liner layer 168 may be made of a metal oxide. In some embodiments, the liner layer 168 may include, for example, a high-k dielectric material such as metal oxides, metal nitrides, metal silicates, transition metal-oxides, transition metal-nitrides, transition metal-silicates, oxynitrides of metals, metal aluminates, zirconium silicate, zirconium aluminate, or combinations thereof. In some embodiments, the liner layer 168 may be made of a material having a dielectric constant greater than about 10. In some embodiments, the liner layer 168 may include hafnium oxide (HfO₂), hafnium silicon oxide (HfSiO), hafnium silicon oxynitride (HfSiON), hafnium tantalum oxide (HfTaO), hafnium titanium oxide (HfTiO), hafnium zirconium oxide (HfZrO), lanthanum oxide (LaO), zirconium oxide (ZrO₂), titanium oxide (TiO₂), tantalum oxide (Ta₂O₅), yttrium oxide (Y₂O₃), strontium titanium oxide (SrTiO₃, STO), barium titanium oxide (BaTiO₃, BTO), barium zirconium oxide (BaZrO), hafnium lanthanum oxide (HfLaO), lanthanum silicon oxide (LaSiO), aluminum silicon oxide (AlSiO), aluminum oxide (Al₂O₃), silicon nitride (Si₃N₄), oxynitrides (SiON), any suitable materials, or combinations thereof. In some embodiments, the liner layer 168 may include SiCN, SiO₂, HZO (a mixture of HfO₂ and ZrO₂), PZT (PbZr_{0.52}Ti_{0.48}O₃), VDF-TrPE (ferroelectric polymer), any suitable materials, or combinations thereof. In alternative embodiments, the liner layer 168 may have a multilayer structure including, such as a silicon oxide layer (e.g., SiO₂ layer), a first high-k material layer (e.g., HfO₂ layer), and a second high-k material layer (e.g., ZrO₂ layer). In some embodiments, the liner layer 168 may be deposited using any suitable method, such as CVD, physical vapor deposition (PVD), ALD, PEALD, PECVD, SACVD, FCVD, spin-on, and/or the like, or a combination thereof. In some embodiments, the liner layer 168 can be interchangeably referred to a dielectric film.

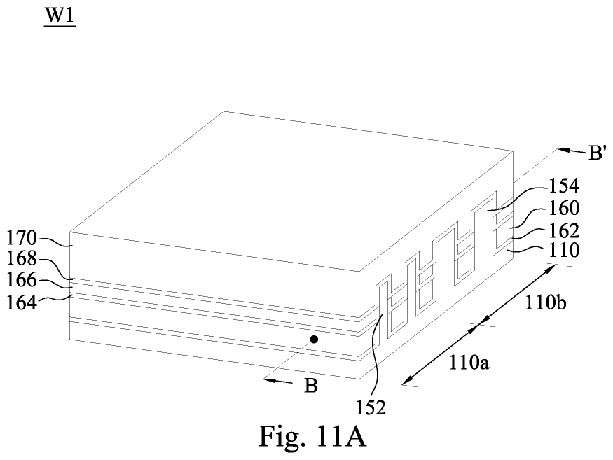

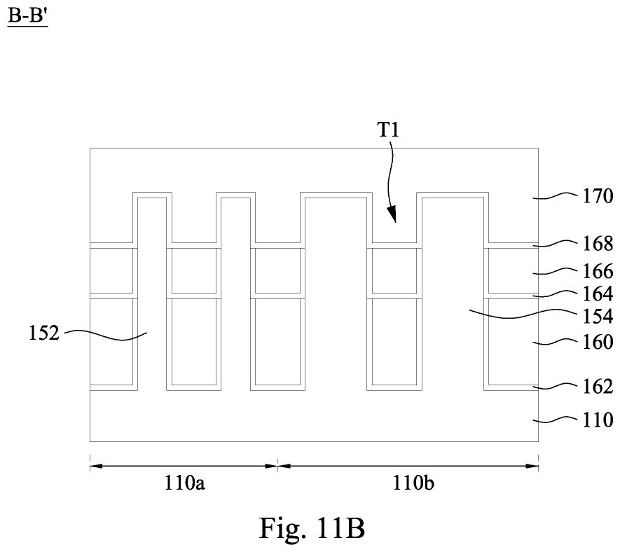

With reference to FIGS. 11A and 11B. A dielectric layer 170 is formed to overfill the trenches T1 (see FIG. 11B) and cover the semiconductor fins 152 and 154. In some embodiments, the dielectric layer 170 may be made of low-K dielectric materials. By way of example but not limiting the present disclosure, the dielectric layer 170 may be made of silicon oxide, silicon nitride, silicon oxynitride, fluoride-doped silicate glass (FSO), silicon carbide, silicon nitride, the like, or a combination thereof. In some embodiments, the dielectric layer 170 may be formed using flowable chemical vapor deposition (FCVD), spin-on coating, CVD, ALD, high-density plasma chemical vapor deposition (HDPCVD), LPCVD, the like, or a combination thereof. In some embodiments where FCVD is used to form the dielectric layer 170, a silicon- and nitrogen-containing precursor (for example, trisilylamine (TSA) or disilylamine (DSA)) can be used, and hence the resulting dielectric layer 170 can be flowable (jelly-like). In some embodiments where FCVD is used to form the dielectric layer 170, precursors including tri-silylamine, ammonia, and oxygen can be used, and hence the resulting dielectric layer 170 can be flowable (jelly-like). In some embodiments, the FCVD process may be performed under a temperature in a range from about 10° C. to about 500° C. In some embodiments, the dielectric layer 170 is formed using an alkylamino silane based precursor. During the deposition of the dielectric layer 170, plasma is turned on to activate the gaseous precursors for forming the flowable oxide. In some embodiments, the dielectric layer 170 may be formed using silane (SiH₄) and oxygen (O₂) as reacting precursors. In some embodiments, the dielectric layer 170 may be formed using a sub-atmospheric CVD (SACVD) process or high aspect-ratio process (HARP), in which process gases may include tetraethylorthosilicate (TEOS) and ozone (O₃). In some embodiments, the dielectric layer 170 may be formed using a spin-on-dielectric (SOD) process, such as hydrogen silsesquioxane (HSQ) or methyl silsesquioxane (MSQ). Other processes and materials may be used.

With reference to FIGS. 12A and 128. An annealing process P4 is performed, which converts flowable dielectric layer 170 into a solid dielectric material. In some embodiments, the annealing process P4 can be interchangeably referred to a thermal treatment. After the flowable dielectric layer 170 is deposited, an in-situ steam thermal annealing step of the annealing process P4 can be performed on the as-deposited flowable dielectric layer 170 to cure the flowable dielectric layer 170. In some embodiments, the steam thermal annealing step of the annealing process P1 can be interchangeably referred to a curing step. In-situ means the steam thermal annealing step of the annealing process P4 is performed in the process chamber for depositing the flowable dielectric layer 170. In some embodiments, the steam thermal annealing step of the annealing process P4 can be performed in a different chamber (or ex-situ). The steam thermal annealing step of the annealing process P4 may increase the oxygen content of the as-deposited flowable dielectric layer 170, which is made of a network of SiO_{A}N_{B}H_{C} (or SiONH), and most of NH ions and H ions of the flowable dielectric layer 170 can be removed. An oxygen source, such as steam (H₂O), can be provided to assist the conversion of the SiONH network into SiO (or SiO₂) network. The steam thermal annealing step of the annealing process P4 causes the flowable dielectric layer 170 to shrink. The duration and the temperature of the steam thermal annealing step of the annealing process P4 affect the amount of shrinkage.

The steam thermal annealing step of the annealing process P4 can be conducted in a furnace, in some embodiments. In some embodiments, a temperature for the steam thermal annealing step of the annealing process P4 may be less than about 500° C., by way of example and not limitation. In some embodiments, a temperature for the steam thermal annealing step of the annealing process P4 may be in a range of about 10° C. to about 500° C., such as 10, 50, 100, 150, 200, 250, 300, 350, 400, 450, or 500° C., by way of example and not limitation. In some embodiments, a temperature for the steam thermal annealing step of the annealing process P4 may be less than a temperature for the steam thermal annealing step of the annealing process P1 and/or P2. In some embodiments, a temperature for the steam thermal annealing step of the annealing process P4 may be less than a temperature for the dry thermal annealing step of the annealing process P1 and/or P2. In some embodiments, the steam thermal annealing step of the annealing process P4 may starts at about 150° C. and ramps up the temperature gradually to a predetermined temperature less than about 500° C. In some embodiments, the duration of the steam thermal annealing step of the annealing process P4 may be less than about 2 hrs. In some embodiments, the duration of the steam thermal annealing step of the annealing process P4 may be in a range from about 5 mins to about 2 hrs, such as 5, 10, 15, 30, 45, 60, 75, 90, 105, or 120 mins, by way of example and not limitation. The gas or gases used for the steam thermal annealing step of the annealing process P4 may include H₂O, O₂, N₂, or combinations thereof. In some embodiments, the steam thermal annealing step of the annealing process P4 may performing in an ambient having a H₂O ratio in a range from about 5% to about 100%, such as 5, 10, 20, 30, 40, 50, 60, 70, 80, 90, or 100%, by way of example and not limitation.

After the steam thermal annealing step of the annealing process P4 described above, a “dry” (without steam) thermal annealing step of the annealing process P4 is conducted to convert the SiOH and SiO network into SiO (or SiO₂) network. During the dry thermal annealing step of the annealing process P4, steam is not used. In some embodiments, an inert gas, such as N₂, is used during the dry thermal annealing step of the annealing process P4. In some embodiments, the gas or gases used for the dry thermal annealing step of the annealing process P4 may include O₂. In some embodiments, the anneal temperature of the dry thermal annealing step of the annealing process P4 may be less than about 800° C. In some embodiments, the dry thermal annealing step of the annealing process P4 may be performed under a higher temperature than the steam thermal annealing step of the annealing process P4. In some embodiments, the FCVD process for depositing the dielectric layer 170 as shown in FIGS. 11A and 11B may be performed under a lower temperature than the dry thermal annealing step of the annealing process P4.

The dry thermal annealing step of the annealing process P4 is conducted in a furnace, in some embodiments. The gas or gases used for the dry thermal annealing step of the annealing process P4 may include an inert gas, such as N₂, Ar, He or combinations thereof. The duration of the dry thermal annealing step of the annealing process P4 is a range from about 30 minutes to about 3 hours. The dry thermal annealing step of the annealing process P4 converts the network of SiOH and SiO in the flowable dielectric layer 170 to a network of SiO (or SiO₂). The dry thermal annealing step of the annealing process P4 may also cause flowable dielectric layer 170 to shrink further. The duration and temperature of the dry thermal annealing step of the annealing process P4 affect the amount of shrinkage. The steam annealing step and the dry thermal annealing step of the annealing process P4 of the annealing process P4 cause flowable dielectric layer 170 to shrink. In some embodiments, the volume of the flowable dielectric layer 170 shrinks in a range from about 5% to about 20%. The duration of the steam annealing step and the dry thermal annealing step of the annealing process P4 affect the amount of shrinking. In some embodiments, the dielectric layer 170 can be interchangeably referred to a flowable oxide, a dielectric material, or cured flowable oxide material.

By way of example and not limitation, a distance D1 from a top surface of the liner layer 168 to a top surface of the dielectric layer 170 may be less than about 100 nm, such as 10, 20, 30, 40, 50, 60, 70, 80, 90, or 100 nm. Spacing D2 between adjacent two semiconductor fins 154 may be in a range from about 15 to about 500 nm, such as 15, 17, 20, 50, 100, 150, 200, 250, 300, 350, 400, 450, or 500 nm, by way of example and not limitation. The liner layer 168 may have a thickness D3 in a range from about 2 to about 6 nm, such as 2, 3, 4, 5, or 6 nm, by way of example and not limitation. A distance D4 of vertical portions of the 168 in the trench T1 (see FIG. 12B) may be in a range from about 3 nm to about 496 nm, such as 3, 5, 8, 10, 50, 100, 150, 200, 250, 300, 350, 400, 450, 490, or 496 nm, by way of example and not limitation.

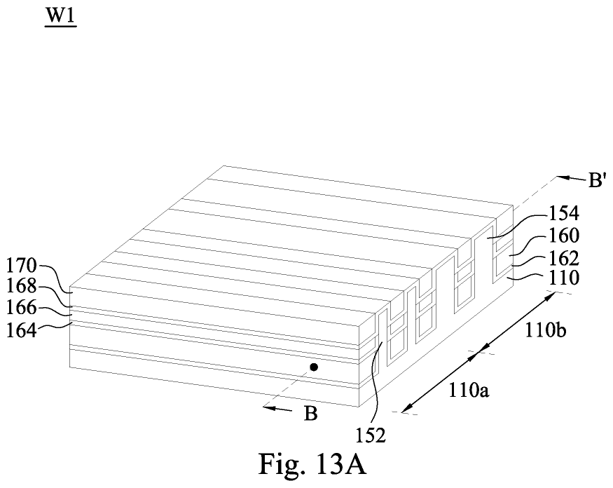

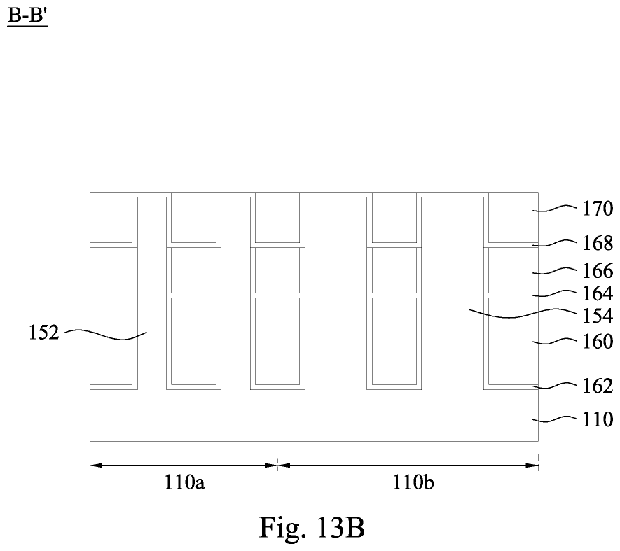

With reference to FIGS. 13A and 13B. A planarization process such as chemical mechanical polish (CMP) is performed to remove the excess dielectric layer 166 over the semiconductor fins 152 and 154. In some embodiments, the planarization process stops when the liner layer 168 is exposed. In such embodiments, the liner layer 168 may act as the CMP stop layer in the planarization.

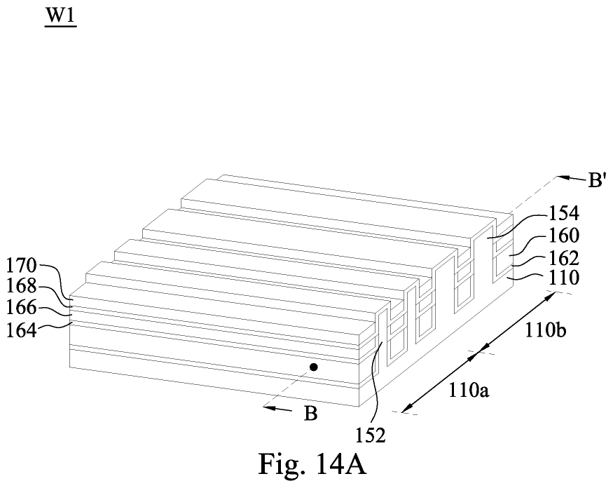

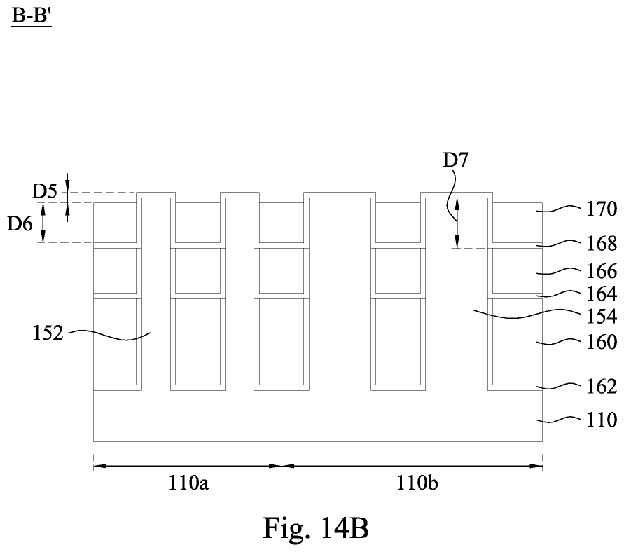

With reference to FIGS. 14A and 14B. The dielectric layer 170 is recessed, for example, through an etching operation, in which diluted HF, SiCoNi (including HF and NH₃), or the like, may be used as the etchant. After recessing the dielectric layer 170, portions of the semiconductor fins 152 and 154 may be higher than the top surface of the dielectric layer 170. In some embodiments, the portions of the semiconductor fins 152 and 154 may be level the top surface of the dielectric layer 170. In some embodiments, the portions of the semiconductor fins 152 and 154 may be lower than the top surface of the dielectric layer 170.

In some embodiments, the thickness D3 (see FIG. 12B) of the liner layer 168 may be thinner than the recessed dielectric layer 170. By way of example and not limitation, the recessed dielectric layer 170 may have a thickness D6 in a range from about 5 nm to about 15 nm, such as 5, 6, 7, 8, 9, 10, 11, 12, 13, 14, or 15. In some embodiments, the thickness D3 (see FIG. 12B) of the liner layer 168 may be less than a distance D5 from a top surface of the recessed dielectric layer 170 to a top surface of the liner layer 168. By way of example and not limitation, the distance D5 may be in a range from about 10 nm to about 20 nm, such as 10, 11, 12, 13, 14, 15, 16, 17, 18, 19, or 20 nm. In some embodiments, the thickness D3 (see FIG. 12B) of the liner layer 168 may be less than a distance D7 from a bottom surface of the liner layer 168 to a top surface of the semiconductor fin 154. By way of example and not limitation, the distance D7 may be in a range from about 20 nm to about 30 nm, such as 20, 21, 22, 23, 24, 25, 26, 27, 28, 29, or 30 nm.

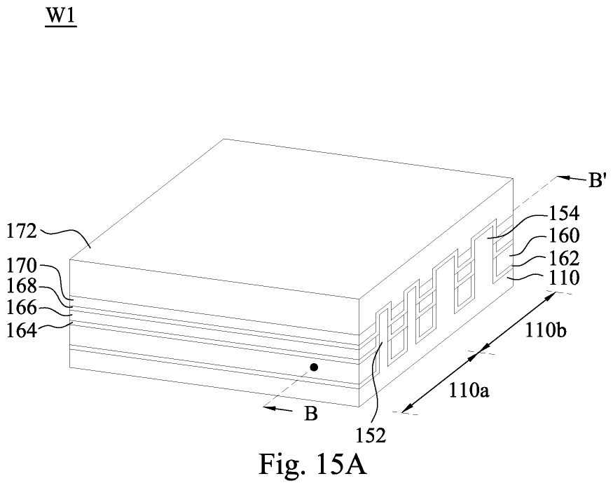

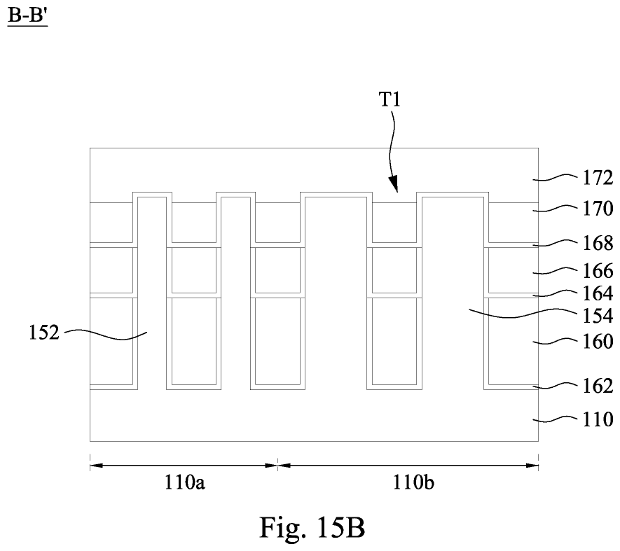

With reference to FIGS. 15A and 15B. A dielectric layer 172 is formed to overfill the trenches T1 (see FIG. 15B) and cover the semiconductor fins 152 and 154. In some embodiments, the dielectric layer 172 may be made of an oxide base dielectric material, a carbon base dielectric material, a nitride base dielectric material, combinations thereof, or other suitable materials. In some embodiments, the dielectric layer 172 may include SiOC, SiON, SiOCN, or combinations thereof. In some embodiments, the dielectric layer 172 may be made of a metal oxide. In some embodiments, the dielectric layer 172 may include, for example, a high-k dielectric material such as metal oxides, metal nitrides, metal silicates, transition metal-oxides, transition metal-nitrides, transition metal-silicates, oxynitrides of metals, metal aluminates, zirconium silicate, zirconium aluminate, or combinations thereof. In some embodiments, the dielectric layer 172 may be made of a material having a dielectric constant greater than about 10. In some embodiments, the dielectric layer 172 may include hafnium oxide (HfO₂), hafnium silicon oxide (HfSiO), hafnium silicon oxynitride (HfSiON), hafnium tantalum oxide (HfTaO), hafnium titanium oxide (HfTiO), hafnium zirconium oxide (HfZrO), lanthanum oxide (LaO), zirconium oxide (ZrO₂), titanium oxide (TiO₂), tantalum oxide (Ta₂O), yttrium oxide (Y₂O₃), strontium titanium oxide (SrTiO₃, STO), barium titanium oxide (BaTiO₃, BTO), barium zirconium oxide (BaZrO), hafnium lanthanum oxide (HfLaO), lanthanum silicon oxide (LaSiO), aluminum silicon oxide (AlSiO), aluminum oxide (Al₂O₃), silicon nitride (Si₃N₄), oxynitrides (SiON), any suitable materials, or combinations thereof. In some embodiments, the dielectric layer 172 may include SiCN, SiO₂, HZO (a mixture of HfO₂ and ZrO₂), PZT (PbZr_{0.52}Ti_{0.48}O₃), VDF-TrFE (ferroelectric polymer), any suitable materials, or combinations thereof. In alternative embodiments, the dielectric layer 172 may have a multilayer structure including, such as a silicon oxide layer (e.g., SiO₂ layer), a first high-k material layer (e.g., HfO₂ layer), and a second high-k material layer (e.g., ZrO₂ layer). In some embodiments, the dielectric layer 172 may be deposited using any suitable method, such as CVD, physical vapor deposition (PVD), ALD, PEALD, PECVD, SACVD, FCVD, spin-on, and/or the like, or a combination thereof. In some embodiments, the dielectric layer 172 can be interchangeably referred to a dielectric film. In some embodiments, the dielectric layer 172 may be made of a same material as the liner layer 168. In some embodiments, the dielectric layer 172 may be made of a different material than the liner layer 168.

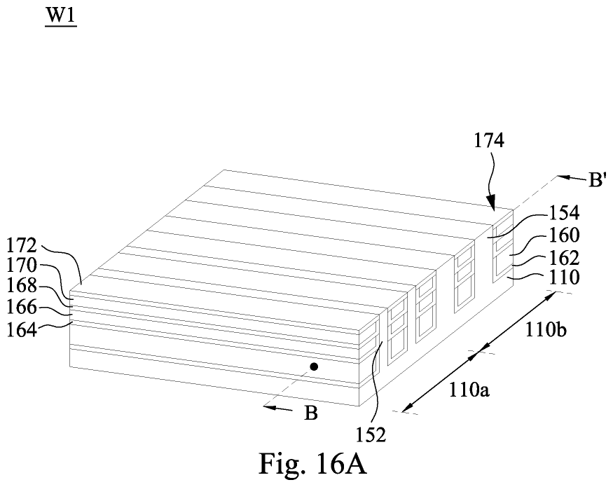

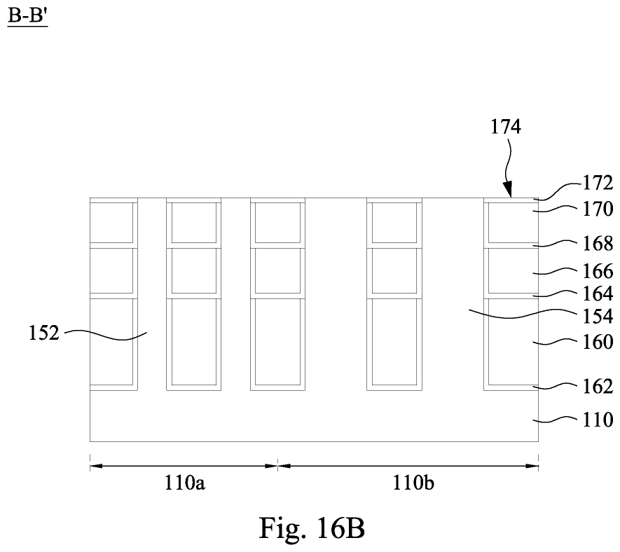

With reference to FIGS. 16A and 16B. A planarization process such as chemical mechanical polish (CMP) is performed to remove the dielectric layer 172 over the semiconductor fins 152 and 154. In some embodiments, the planarization process stops when the semiconductor fins 152 and 154 are exposed. In such embodiments, the semiconductor fins 152 and 154 may act as the CMP stop layer in the planarization. In some embodiments, the dielectric layers 172, 170, 166 and the liner layers 164, 168 can be collectively referred to as a dummy fin 174. In some embodiments, the dielectric layers 172, 170, 166, 160 and the liner layers 162, 164, 168 can be collectively referred to as a dummy fin. In some embodiments, the dummy fin can be interchangeably referred to as a dielectric fin. In some embodiments, the dielectric layers 172, 170 and the liner layer 168 can be collectively referred to as a core-shell structure. In some embodiments, at least one of the dielectric layers 172, 170, 166, 160 and the liner layers 162, 164, 168 in the dummy fin 174 may include sulfur. In some embodiments, at least any two of the dielectric layers 172, 170, 166, 160 and the liner layers 162, 164, 168 in the dummy fin 174 may include a same chemical element, such as sulfur (S).

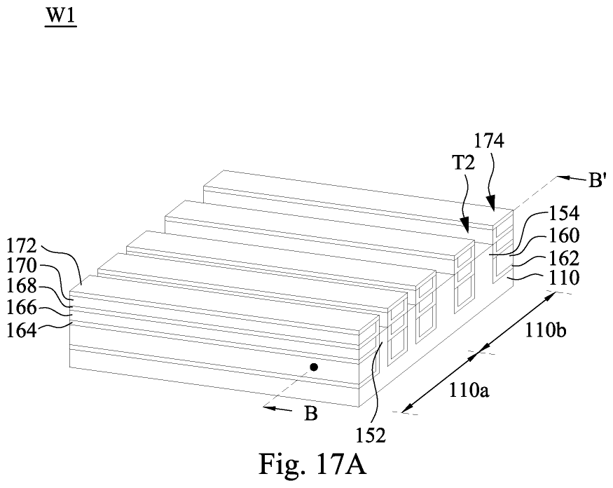

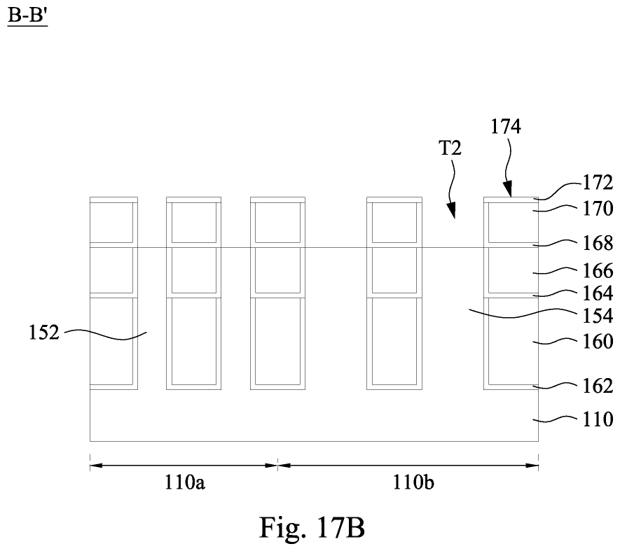

With reference to FIGS. 17A and 17B. Trenches T2 are formed in the semiconductor fins 152 and 154. In some embodiments, the semiconductor fins 152 and 154 may be etched such that top surfaces of the semiconductor fins 152 and 154 are in a position level with a bottom surface of the liner layer 168. In some embodiments, the etched semiconductor fins 152 and 154 have top surfaces in a position level lower than a bottom surface of the liner layer 168. In some embodiments, the etched semiconductor fins 152 and 154 have top surfaces in a position level higher than a bottom surface of the liner layer 168. The trenches T2 may be formed by etching the semiconductor fins 152 and 154 using an anisotropic etching process, such as a RIE, a NBE, or the like. The dielectric layer 172 and the liner layers 164 and 168 may be collectively mask portions of the semiconductor fins 152 and 154 during the etching processes used to form the trenches T2. A single etch process may be used to etch each of the semiconductor fins 152 and 154, or multiple etch processes may be used to etch the semiconductor fins 152 and 154. Timed etch processes may be used to stop the etching of the trenches T2 after the trenches T2 reach a desired depth. Subsequently, a cleaning step may be optionally performed to remove a native oxide of the semiconductor substrate 110. The cleaning may be performed using diluted hydrofluoric (HF) acid, by way of example and not limitation.

With reference to FIGS. 18A, 18B, and 18C. A gate dielectric layer 175 is blanket formed over the substrate 110 to cover the semiconductor fins 152 and 154 and the dielectric layer 172 and the liner layer 168, and a dummy gate electrode layer 177 is formed over the gate dielectric layer 175. In some embodiments, the gate dielectric layer 175 is made of high-k dielectric materials, such as metal oxides, transition metal-oxides, or the like. Examples of the high-k dielectric material include, but are not limited to, hafnium oxide (HfO₂), hafnium silicon oxide (HfSiO), hafnium tantalum oxide (HfTaO), hafnium titanium oxide (HfTiO), hafnium zirconium oxide (HfZrO), zirconium oxide, titanium oxide, aluminum oxide, hafnium dioxide-alumina (HfO₂—Al₂O₃) alloy, or other applicable dielectric materials. In some embodiments, the gate dielectric layer 175 is an oxide layer. The gate dielectric layer 175 may be formed by a deposition processes, such as chemical vapor deposition (CVD), physical vapor deposition (PVD), atomic layer deposition (ALD), plasma enhanced CVD (PECVD) or other suitable techniques.

In some embodiments, the dummy gate electrode layer 177 may include polycrystalline-silicon (poly-Si), poly-crystalline silicon-germanium (poly-SiGe), metallic nitrides, metallic silicides, metallic oxides, or metals. In some embodiments, the dummy gate electrode layer 177 includes a metal-containing material such as TiN, TaN, TaC, Co, Ru, Al, combinations thereof, or multi-layers thereof. The dummy gate electrode layer 177 may be deposited by CVD, physical vapor deposition (PVD), sputter deposition, or other techniques suitable for depositing conductive materials.

Subsequently, a patterned mask layer 179 is formed over the dummy gate electrode layer 177 and then patterned to form separated mask portions. The patterned mask layer 179 may be formed by a series of operations including deposition, photolithography patterning, and etching processes. The photolithography patterning processes may include photoresist coating (e.g., spin-on coating), soft baking, mask aligning, exposure, post-exposure baking, developing the photoresist, rinsing, drying (e.g., hard baking), and/or other applicable processes. The etching processes may include dry etching, wet etching, and/or other etching methods (e.g., reactive ion etching).

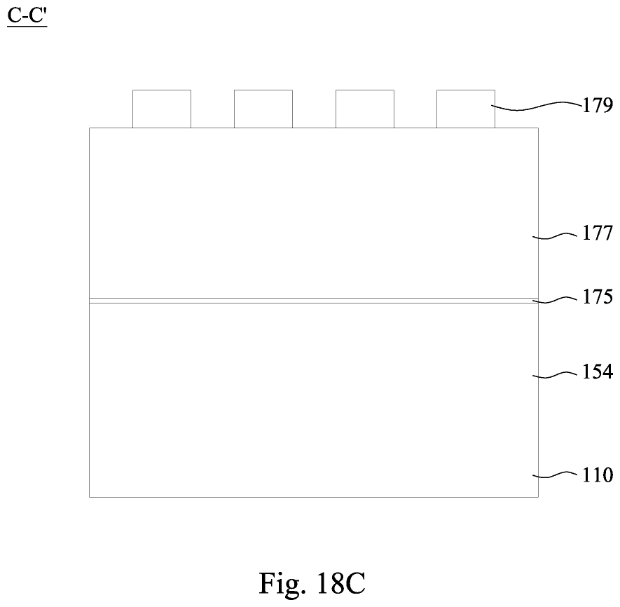

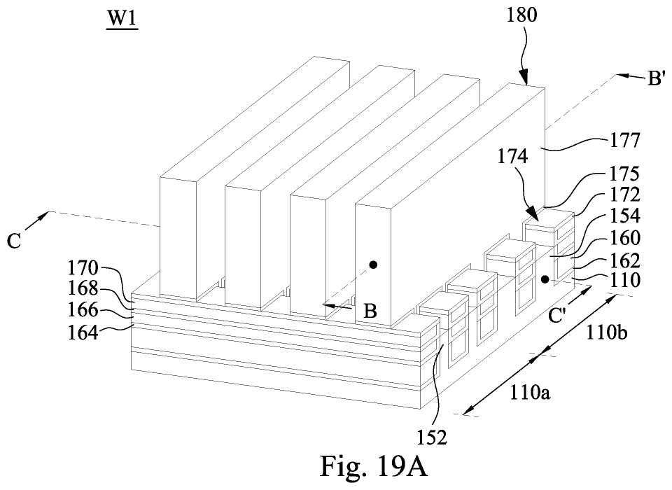

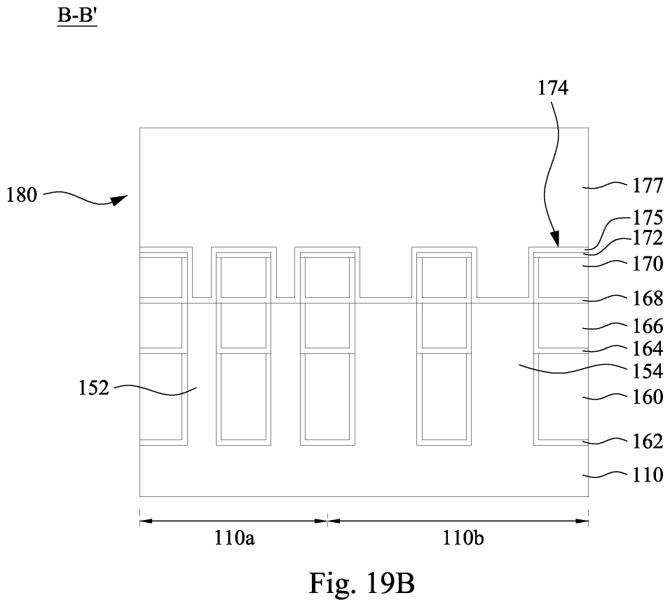

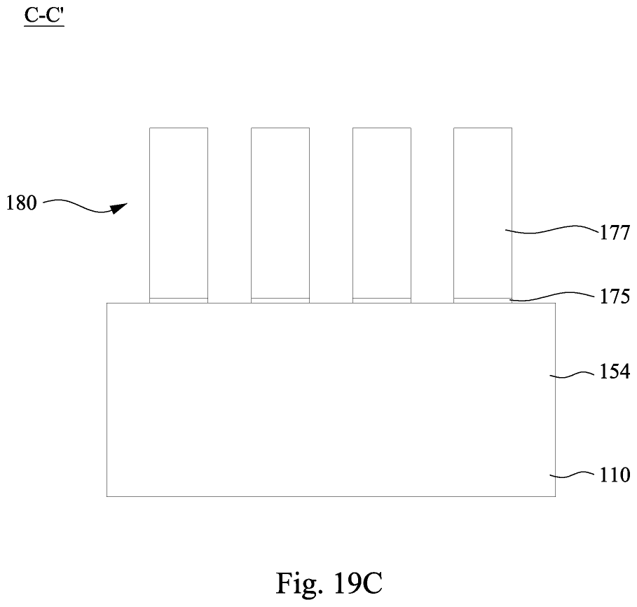

With reference to FIGS. 19A, 19B, and 19C. One or more etching processes are performed to form dummy gate structure 180 wrapping around the dummy fin 174 using the patterned mask 190 as an etching mask, and the patterned mask layer 179 is removed after the etching. The dummy gate structure includes a gate dielectric layer 175 and a dummy gate electrode layer 177 over the gate dielectric layer 175. The dummy gate structures 180 have substantially parallel longitudinal axes that are substantially perpendicular to a longitudinal axis of the semiconductor fins 152 and 154. The dummy gate structure 180 will be replaced with a replacement gate structure using a “gate-last” or replacement-gate process. In some embodiments, the dummy gate structure 180 can be interchangeably referred to a gate patter or a gate strip.

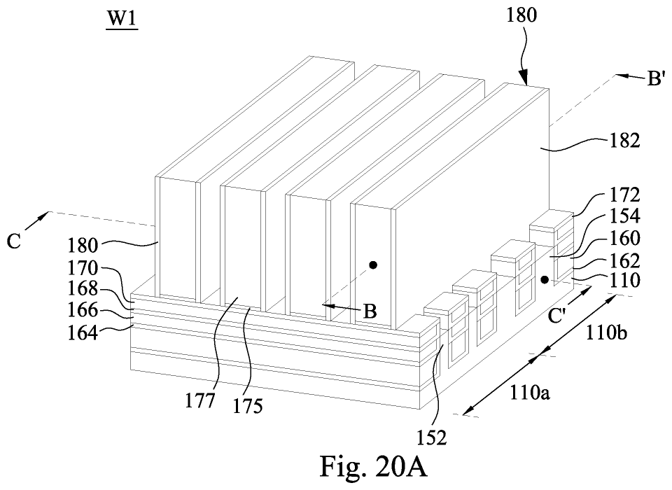

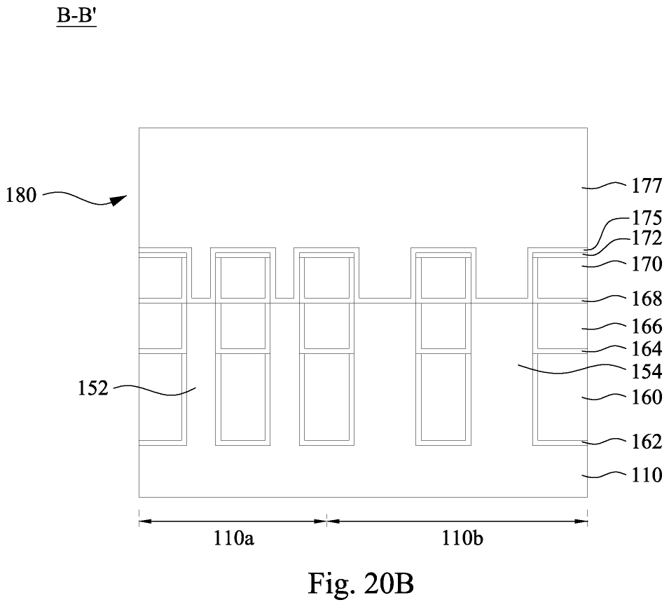

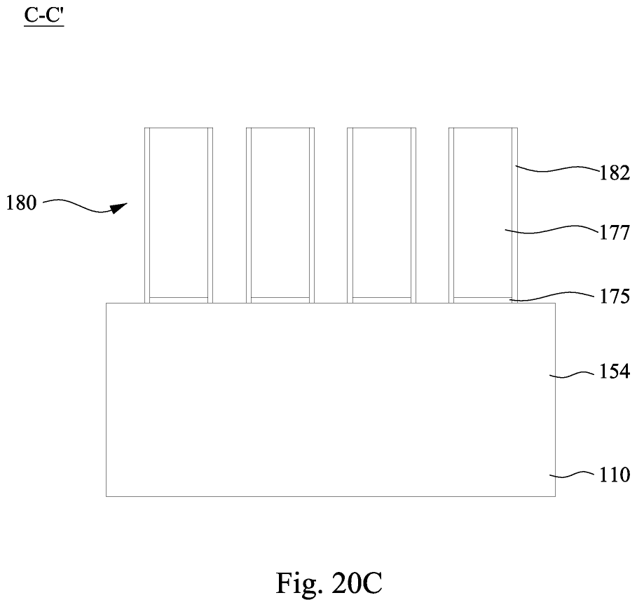

With reference to FIGS. 20A, 20B, and 20C. A gate spacer 182 is formed along sidewalls of the dummy gate structures 180. In some embodiments, the gate spacer 182 may include silicon oxide, silicon nitride, silicon oxynitride, silicon carbide, silicon carbonitride, silicon oxycarbonitride, silicon oxycarbide, porous dielectric materials, hydrogen doped silicon oxycarbide (SiOC:H), low-k dielectric materials, or other suitable dielectric materials. The gate spacer 182 may include a single layer or multilayer structure made of different dielectric materials. The method of forming the gate spacer 182 may include blanket forming a dielectric layer on the structure shown in FIG. 9 using, by way of example and not limitation, CVD, PVD or ALD, and then performing an etching process such as anisotropic etching to remove horizontal portions of the dielectric layer. The remaining portions of the dielectric layer on sidewalls of the dummy gate structure 180 can serve as the gate spacer 182. In some embodiments, the gate spacer 182 may be used to offset subsequently formed doped regions, such as source/drain regions. The gate spacer 182 may further be used for designing or modifying the source/drain region profile.

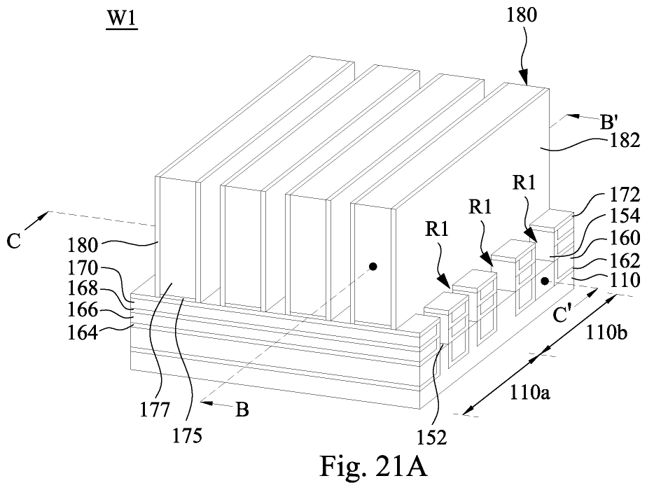

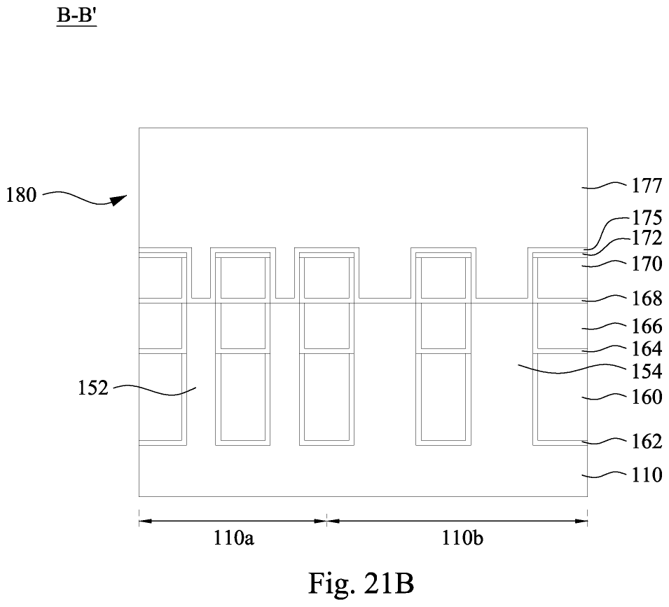

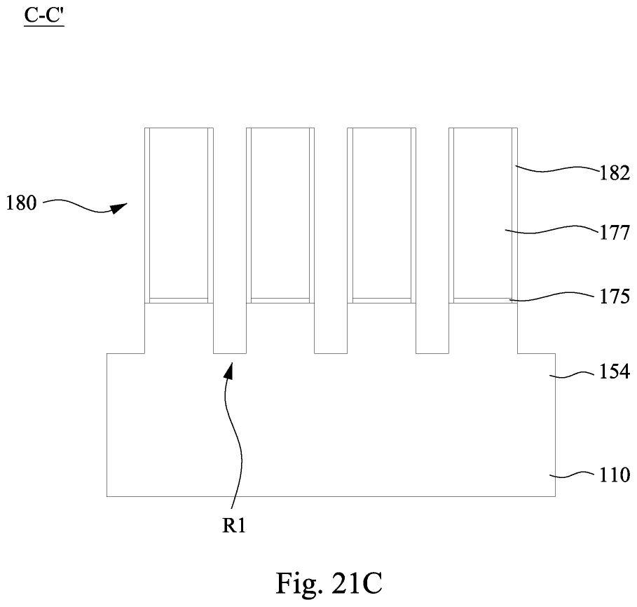

With reference to FIGS. 21A, 218, and 21C. Portions of the semiconductor fins 152 and 154 not covered by the dummy gate structure 180 and the gate spacer 182 are recessed to form recesses R1. In some embodiments, formation of the recesses R1 may include a dry etching process, a wet etching process, or combination dry and wet etching processes. This etching process may include reactive ion etch (RIE) using the dummy gate structures 180 and gate spacers 182 as masks, or by any other suitable removal process. After the etching process, a pre-cleaning process may be performed to clean the recesses R1 with hydrofluoric acid (HF) or other suitable solution in some embodiments.

With reference to FIGS. 22A, 22B, 22C, and 22D. Epitaxial source/drain structures 184, 185, 186, and/or 187 are respectively formed in the recesses R2 (see FIGS. 21A and 21C) to form an n-channel metal-oxide semiconductor (NMOS) transistor or a p-channel metal-oxide semiconductor (PMOS) transistor. In some embodiments, stress may enhance carrier mobility and performance of the MOS. The epitaxial source/drain structures 184, 185, 186, and/or 187 may be formed using one or more epitaxy or epitaxial (epi) processes, such that Si features, SiGe features, silicon phosphate (SiP) features, silicon carbide (SiC) features and/or other suitable features can be formed in a crystalline state on the semiconductor fins 152 and 154. The epitaxial source/drain structures 184, 185, 186, and/or 187 can be formed in different epitaxy processes. The epitaxial source/drain structures 184, 185, 186, and/or 187 may include semiconductor material such as germanium (Ge) or silicon (Si); or compound semiconductor materials, such as gallium arsenide (GaAs), aluminum gallium arsenide (AlGaAs); or semiconductor alloy, such as silicon germanium (SiGe), gallium arsenide phosphide (GaAsP). The epitaxial source/drain structures 184, 185, 186, and/or 187 have suitable crystallographic orientation (e.g., a (100), (110), or (111) crystallographic orientation). In some embodiments, lattice constants of the epitaxial source/drain structures 184, 185, 186, and/or 187 are different from that of the semiconductor fins 152 and 154, so that the channel region between the epitaxial source/drain structures 184, 185, 186, and/or 187 can be strained or stressed by the epitaxial source/drain structures 184, 185, 186, and/or 187 to improve carrier mobility of the semiconductor device and enhance the device performance.

In some embodiments, the epitaxial source/drain structure 184, 185, 186, and/or 187 may be an n-type epitaxy structure, and the epitaxial source/drain structure 184, 185, 186, and/or 187 may be a p-type epitaxy structures. The epitaxial source/drain structure 184, 185, 186, and/or 187 may include SiP, SiC, SiPC, Si, III-V compound semiconductor materials or combinations thereof, and the pitaxial source/drain structure 184, 185, 186, and/or 187 may include SiGe, SiGeC, Go, Si, III-V compound semiconductor materials, or combinations thereof. During the formation of the epitaxial source/drain structure 184, 185, 186, and/or 187, n-type impurities such as phosphorous or arsenic may be doped with the proceeding of the epitaxy. By way of example and not limitation, when the epitaxial source/drain structure 184, 185, 186, and/or 187 includes SIC or Si, n-type impurities are doped. Moreover, during the formation of the epitaxial source/drain structure 184, 185, 186, and/or 187, p-type impurities such as boron or BF₂ may be doped with the proceeding of the epitaxy. By way of example and not limitation, when the epitaxial source/drain structure 184, 185, 186, and/or 187 includes SiGe, p-type impurities are doped. In some embodiments, the epitaxial source/drain structures 184 and 185 may have a same conductivity type. In some embodiments, the epitaxial source/drain structures 184 and 185 may have different conductivity types. In some embodiments, the epitaxial source/drain structures 186 and 187 may have a same conductivity type. In some embodiments, the epitaxial source/drain structures 186 and 187 may have different conductivity types.

The epitaxy processes include CVD deposition techniques (e.g., vapor-phase epitaxy (VPE) and/or ultra-high vacuum CVD (UHV-CVD)), molecular beam epitaxy, and/or other suitable processes. The epitaxy process may use gaseous and/or liquid precursors, which interact with the composition of the semiconductor fins 152 and 154 (e.g., silicon, silicon germanium, silicon phosphate, or the like). The epitaxial source/drain structures 184, 185, 186, and/or 187 may be in-situ doped. The doping species include p-type dopants, such as boron or BF₂; n-type dopants, such as phosphorus or arsenic; and/or other suitable dopants including combinations thereof. If the epitaxial source/drain structures 184, 185, 186, and/or 187 are not in-situ doped, a second implantation process (i.e., a junction implant process) is performed to dope the epitaxial source/drain structures 184, 185, 186, and/or 187. One or more annealing processes may be performed to activate the epitaxial source/drain structures 184, 185, 186, and/or 187. The annealing processes include rapid thermal annealing (RTA) and/or laser annealing processes. In some embodiments, the epitaxial source/drain structures 184, 185, 186, and/or 187 can be interchangeably referred to sources/drain regions, sources/drain patterns, or epitaxial structures.

With reference to FIGS. 23A, 23B, 23C, and 23D. A contact etch stop layer (CESL) 190 is formed over the source/drain structures 184, 185, 186, and 187, the dummy gate structures 180, and the gate spacers 182, and an interlayer dielectric (ILD) layer 192 is formed over the CESL 190, followed by performing a CMP process to remove excessive material of the ILD layer 192 and CESL 190 to expose the dummy gate structures 180. The CMP process may planarize a top surface of the ILD layer 192 with top surfaces of the dummy gate structures 180 and gate spacers 182. In some embodiments, the ILD layer 192 includes silicon oxide, silicon nitride, silicon oxynitride, tetraethoxysilane (TEOS), phosphosilicate glass (PSG), borophosphosilicate glass (BPSG), low-k dielectric material, and/or other suitable dielectric materials. Examples of low-k dielectric materials include, but are not limited to, fluorinated silica glass (FSG), carbon doped silicon oxide, amorphous fluorinated carbon, parylene, bis-benzocyclobutenes (BCB), or polyimide. The ILD layer 192 may be formed using, by way of example and not limitation, CVD, ALD, spin-on-glass (SOG) or other suitable techniques. In some embodiments, the CESL 190 includes silicon nitride, silicon oxynitride or other suitable materials. The CESL 190 can be formed using, by way of example and not limitation, plasma enhanced CVD, low pressure CVD, ALD or other suitable techniques.

With reference to FIG. 24. One or more etching processes including wet etch and/or dry etch is performed to remove a portion of the dummy gate structure 180 vertically above a corresponding one of the dummy fins 174 as shown in FIG. 24. Hence, an opening O1 is formed above the corresponding dummy fin 174. Subsequently, the opening O1 can be further vertically expanded. Specifically, the dielectric layers 172, 170, 166 and the liner layers 164, 168 exposed by the opening O1 can be removed, such that the dielectric layer 160 and the liner layer 162 can be exposed from the opening O1. Therefore, a portion of the dummy gate structure 180 within the device region 110a can be physically separated from another portion of the dummy gate structure 180 within the device region 110b. The etching process is a selective etching process that uses an etchant etching the dielectric layers 172, 170, 166 and the liner layers 164, 168 at a faster etch rate than it etches the semiconductor fins 152 and 154. For example, the etch rates of the etching process to the dielectric layers 172, 170, 166 and the liner layers 164, 168 are greater than about twice the etch rate of the etching process to the semiconductor fins 152 and 154. If the etch rates of the etching process to the dielectric layers 172, 170, 166 and the liner layers 164, 168 are lower than about twice the etch rate of the etching process to the dielectric layers 172, 170, 166 and the liner layers 164, 168, the etching process may excessively consume the semiconductor fins 152 and 154 and thus the semiconductor fins 152 and 154 may be damaged, and thus the yield may reduce. In this way, the semiconductor fins 152 and 154 remains substantially intact after removing the dielectric layers 172, 170, 166 and the liner layers 164, 168. In some embodiments, the etching process may be performed using an isotropic etching process.

Subsequently, a dielectric material 194 is filled in the opening O1 and formed over the ILD layer 192 and CESL 190, followed by performing a CMP process to remove excessive material of the dielectric material 194 to expose remainders of the dummy gate structure 180. The CMP process may planarize a top surface of the dielectric material 194 with top surfaces of the remainders of the dummy gate structures 180. As shown in FIG. 24, the dielectric material 194 runs through the dummy gate structure 180 to land on the dielectric layer 160 and the liner layer 162. In some embodiments, the dielectric material 194 is interposed between two gate structures so as to act as an isolator between two active devices.

In some embodiments, the dielectric material 194 may include SiOC, SiON, SiOCN, or combinations thereof. In some embodiments, the dielectric material 194 may be made of a metal oxide. In some embodiments, the dielectric material 194 may include, for example, a high-k dielectric material such as metal oxides, metal nitrides, metal silicates, transition metal-oxides, transition metal-nitrides, transition metal-silicates, oxynitrides of metals, metal aluminates, zirconium silicate, zirconium aluminate, or combinations thereof. In some embodiments, the dielectric material 194 may be made of a material having a dielectric constant greater than about 10. In some embodiments, the dielectric material 194 may include hafnium oxide (HfO₂), hafnium silicon oxide (HfSiO), hafnium silicon oxynitride (HfSiON), hafnium tantalum oxide (HfTaO), hafnium titanium oxide (HfTiO), hafnium zirconium oxide (HfZrO), lanthanum oxide (LaO), zirconium oxide (ZrO₂), titanium oxide (TiO₂), tantalum oxide (Ta₂O₅), yttrium oxide (Y₂O₃), strontium titanium oxide (SrTiO₃, STO), barium titanium oxide (BaTiO₃, BTO), barium zirconium oxide (BaZrO), hafnium lanthanum oxide (HfLaO), lanthanum silicon oxide (LaSiO), aluminum silicon oxide (AlSiO), aluminum oxide (Al₂O₃), silicon nitride (Si₃N₄), oxynitrides (SiON), any suitable materials, or combinations thereof. In some embodiments, the dielectric material 194 may include SICN, SiO₂, HZO (a mixture of HfO₂ and ZrO₂), PZT (PbZr_{0.32}Ti_{0.48}O₃), VDF-TrFE (ferroelectric polymer), any suitable materials, or combinations thereof. In alternative embodiments, the dielectric material 194 may have a multilayer structure including, such as a silicon oxide layer (e.g., SiO₂ layer), a first high-k material layer (e.g., HfO₂ layer), and a second high-k material layer (e.g., ZrO₂ layer). In some embodiments, the dielectric material 194 may be deposited using any suitable method, such as CVD, physical vapor deposition (PVD), ALD, PEALD, PECVD, SACVD, FCVD, spin-on, and/or the like, or a combination thereof. In some embodiments, the dielectric material 194 can be interchangeably referred to a dielectric film.

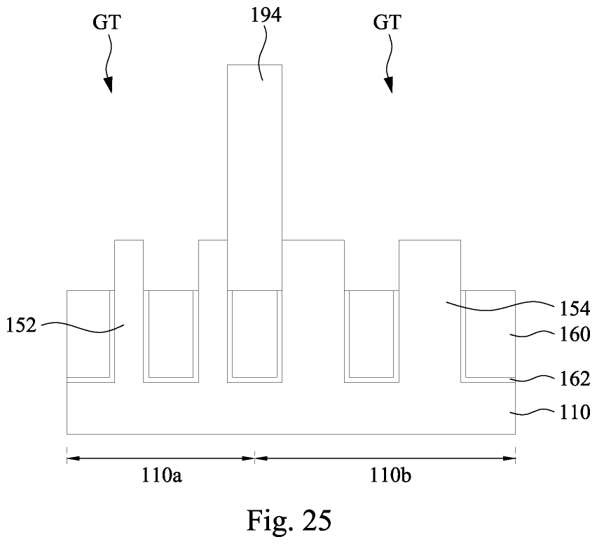

With reference to FIG. 25. The reminders of the dummy gate structure 180 (see FIG. 24) are removed to form gate trenches OT with the gate spacers 182 as their sidewalls. Widths of the gate trenches GT are associated with the corresponding dummy gate structures 180. In some embodiments, the dummy gate structures 180 are removed by performing a first etching process and performing a second etching process after the first etching process. In some embodiments, the dummy gate electrode layer 177 (as shown in FIG. 24) is mainly removed by the first etching process, and the gate dielectric layer 175 (as shown in FIG. 24) is mainly removed by the second etching process that employs a different etchant than that used in the first etching process. In some embodiments, the dummy gate electrode layer 177 is removed, while the gate dielectric layer 175 remains in the gate trenches GT.

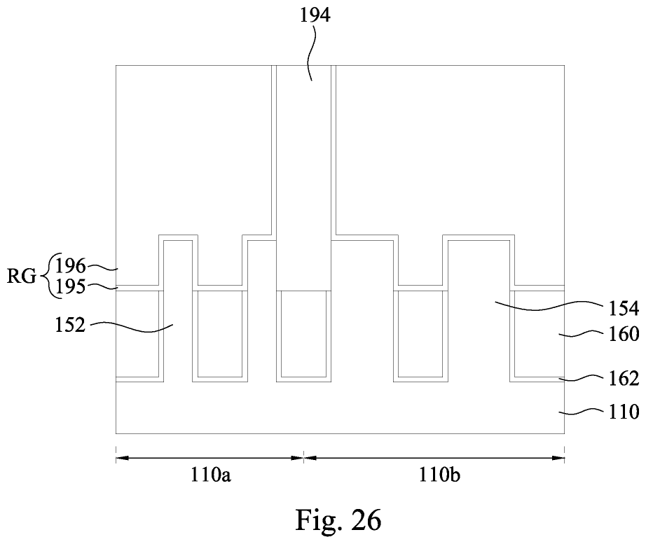

With reference to FIG. 26. Replacement gate structures RG are respectively formed in the gate trenches GT. An exemplary method of forming these replacement gate structures may include blanket forming a gate dielectric layer over the wafer W, forming one or more work function metals over the blanket gate dielectric layer, and performing a CMP process to remove excessive materials of the one or more work function metals and the gate dielectric layer outside the gate trenches GT. As a result of this method, the replacement gate structures RG each include a gate dielectric layer 195 and a work function metal 196 wrapped around by the gate dielectric layer 195. In some embodiments, the gate structure RG can be interchangeably referred to a gate patter or a gate strip.

In some embodiments, the gate dielectric layer 195 may include, for example, a high-k dielectric material such as metal oxides, metal nitrides, metal silicates, transition metal-oxides, transition metal-nitrides, transition metal-silicates, oxynitrides of metals, metal aluminates, zirconium silicate, zirconium aluminate, or combinations thereof. In some embodiments, the gate dielectric layer 195 may include hafnium oxide (HfO₂), hafnium silicon oxide (HfSiO), hafnium silicon oxynitride (HfSiON), hafnium tantalum oxide (HfTaO), hafnium titanium oxide (HfTiO), hafnium zirconium oxide (HfZrO), lanthanum oxide (LaO), zirconium oxide (ZrO), titanium oxide (TiO), tantalum oxide (Ta₂O₅), yttrium oxide (Y₂O₃), strontium titanium oxide (SrTiO₃, STO), barium titanium oxide (BaTiO₃, BTO), barium zirconium oxide (BaZrO), hafnium lanthanum oxide (HfLaO), lanthanum silicon oxide (LaSiO), aluminum silicon oxide (AlSiO), aluminum oxide (Al₂O₃), silicon nitride (Si₃N₄), oxynitrides (SiON), and combinations thereof. In alternative embodiments, the gate dielectric layer 195 may have a multilayer structure such as one layer of silicon oxide (e.g., interfacial layer) and another layer of high-k material. In some embodiments, the gate dielectric layer 195 is made of the same material because they are formed from the same dielectric layer blanket deposited over the substrate 110.

The work function metal 196 includes suitable work function metals to provide suitable work functions. In some embodiments, the work function metal 196 may include one or more n-type work function metals (N-metal) for forming an n-type transistor on the substrate 110. The n-type work function metals may exemplarily include, but are not limited to, titanium aluminide (TiAl), titanium aluminium nitride (TiAlN), carbo-nitride tantalum (TaCN), hafnium (Hf), zirconium (Zr), titanium (Ti), tantalum (Ta), aluminum (Al), metal carbides (e.g., hafnium carbide (HfC), zirconium carbide (ZrC), titanium carbide (TiC), aluminum carbide (AlC)), aluminides, and/or other suitable materials. In alternative embodiments, the work function metal 196 may include one or more p-type work function metals (P-metal) for forming a p-type transistor on the substrate 110. The p-type work function metals may exemplarily include, but are not limited to, titanium nitride (TiN), tungsten nitride (WN), tungsten (W), ruthenium (Ru), palladium (Pd), platinum (Pt), cobalt (Co), nickel (Ni), conductive metal oxides, and/or other suitable materials. At least two of the work function metals are made of different work function metals so as to achieve suitable work functions in some embodiments. In some embodiments, an entirety of the work function metal 196 is a work function metal. In some embodiments, the term “work function” refers to the minimum energy (usually expressed in electron volts) needed to remove an electron from a neutral solid to a point immediately outside the solid surface (or energy needed to move an electron from the Fermi energy level into vacuum). Here “immediately” means that the final electron position is far from the surface on the atomic scale but still close to the solid surface on the macroscopic scale.

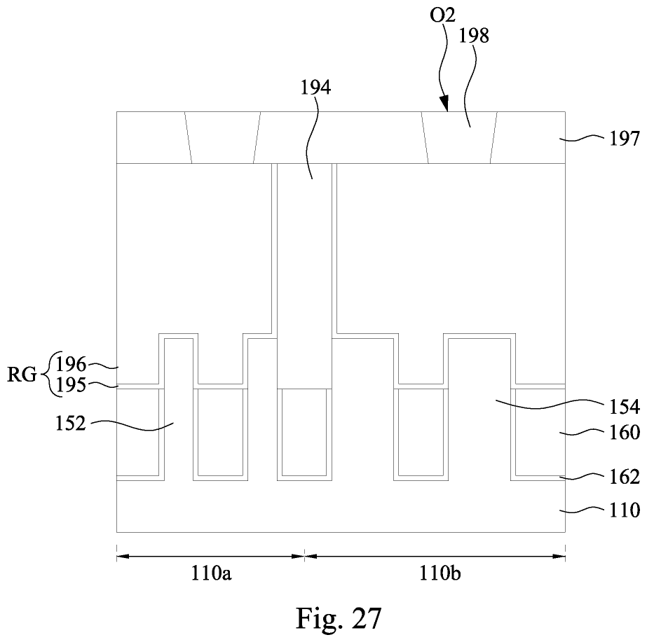

With reference to FIG. 27. An ILD layer 197 is formed over the replacement gate structures RG and the dielectric material 194. Subsequently, contact holes O2 may be formed by any suitable process in the ILD layer 197. Subsequently, a conductive material layer fills in the contact holes O2. In some embodiments, the conductive material layer includes TiN, TaN, Ta, Ti, Hf, Zr, Ni, W, Co, Cu, Ag, Al, Zn, Ca, Au, Mg, Mo, Cr, or the like. In some embodiments, the conductive material layer may be formed by CVD, PVD, plating, ALD, or other suitable technique. Subsequently, A CMP process is performed to remove a portion of the conductive material layer above a top surface of the ILD layer 197. After planarization, the gate contacts 198 are formed. The gate contacts 198 go through the ILD layer 197 to provide electrical contact to the replacement gate structures RG.

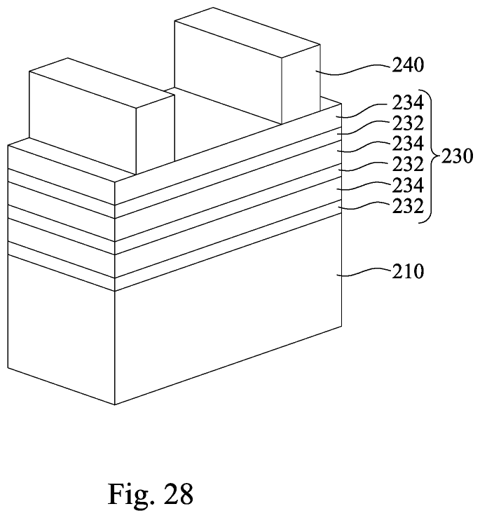

In some embodiments, embodiments of the present disclosure can be directed to gate all around (GAA) transistor structures as shown in FIGS. 28 to 36. The GAA transistor structures may be patterned by any suitable method. For example, the structures may be patterned using one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used to pattern the GAA structure.

The present disclosure is related to integrated circuit (IC) structures and methods of forming the same. More particularly, some embodiments of the present disclosure are related to gate-all-around (GAA) devices including improved isolation structures to reduce current leakage from channels to the substrate. A GAA device includes a device that has its gate structure, or portions thereof, formed on four-sides of a channel region (e.g., surrounding a portion of a channel region). The channel region of a GAA device may include nanosheet channels, bar-shaped channels, and/or other suitable channel configurations. In some embodiments, the channel region of a GAA device may have multiple horizontal nanosheets or horizontal bars vertically spaced, making the GAA device a stacked horizontal GAA (S-HGAA) device. The GAA devices presented herein include a p-type metal-oxide-semiconductor GAA device and an n-type metal-oxide-semiconductor GAA device stack together. Further, the GAA devices may have one or more channel regions (e.g., nanosheets) associated with a single, contiguous gate structure, or multiple gate structures. One of ordinary skill may recognize other examples of semiconductor devices that may benefit from aspects of the present disclosure. In some embodiments, the nanosheets can be interchangeably referred to as nanowires, fork-sheets, nanoslabs, nanorings, or nanostructures having nano-scale size (e.g., a few nanometers), depending on their geometry. In addition, the embodiments of the disclosure may also be applied, however, to a variety of metal oxide semiconductor transistors (e.g., complementary-field effect transistor (CFET) and fin field effect transistor (FinFET)).

Some embodiments discussed herein are discussed in the context of nano-FETs formed using a gate-last process. In some embodiments, a gate-first process may be used. Also, some embodiments contemplate aspects used in planar devices, such as planar FETs, or in fin field-effect transistors (FinFETs). For example, FinFETs may include fins on a substrate, with the fins acting as channel regions for the FinFETs. Similarly, planar FETs may include a substrate, with portions of the substrate acting as channel regions for the planar PETs.

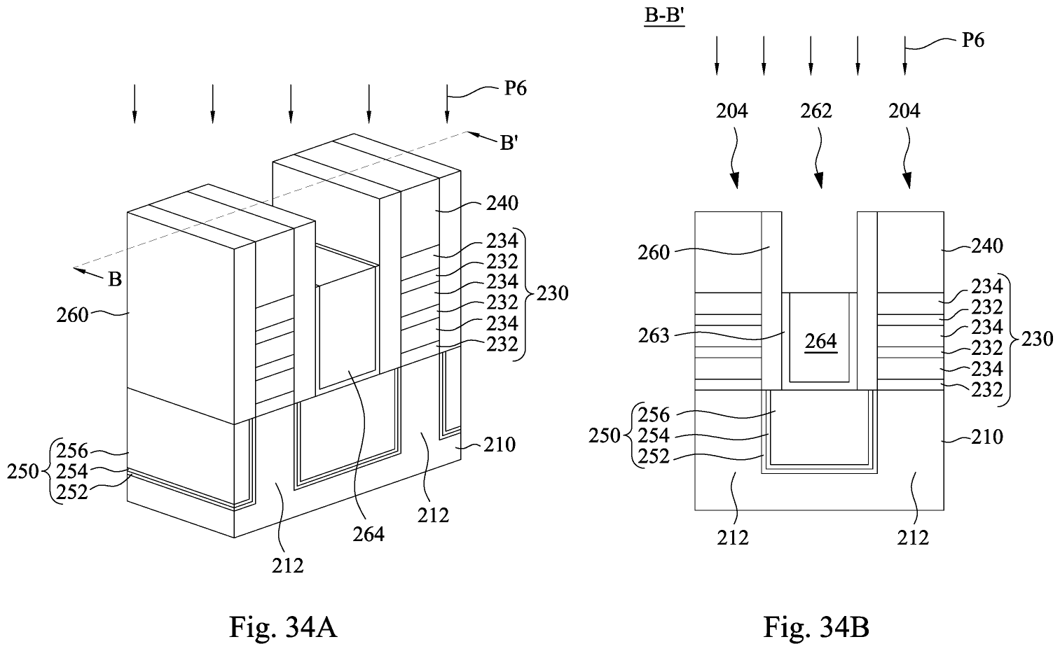

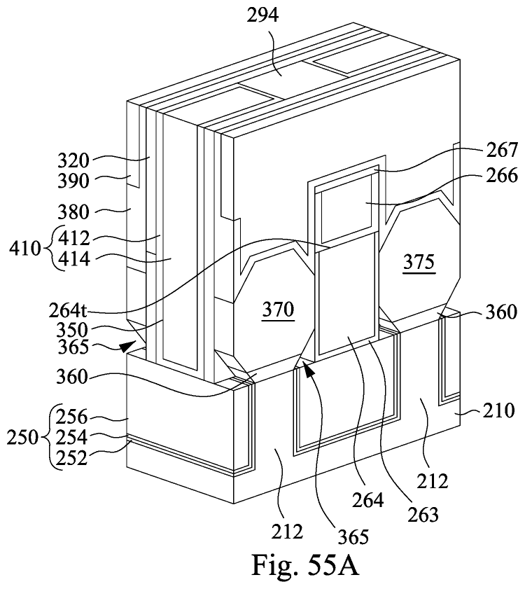

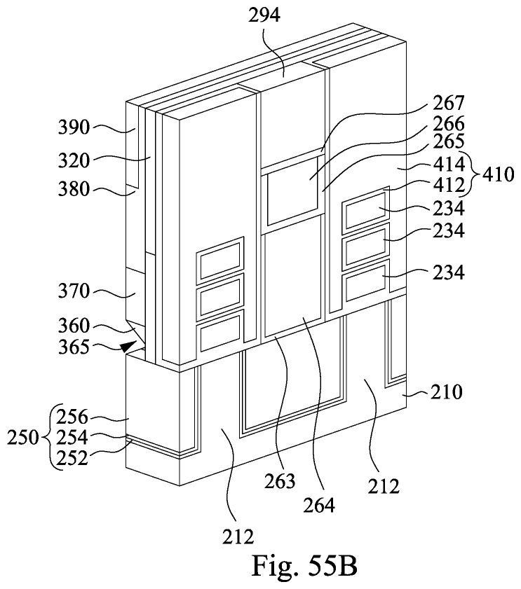

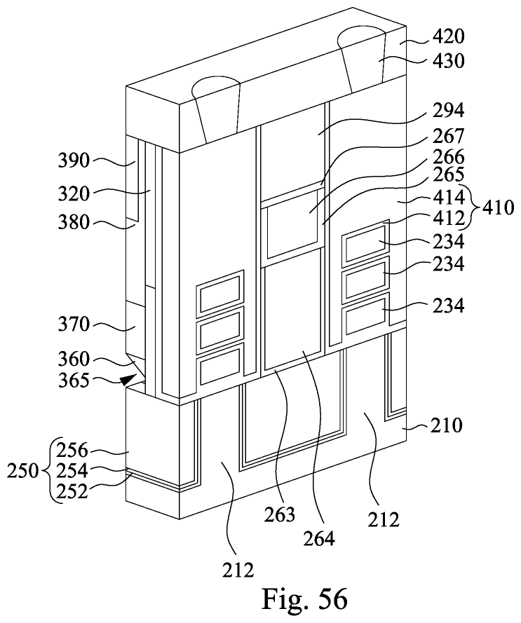

Reference is made to FIGS. 28-56. FIGS. 28, 29, 30, 31, 32, 33, 34A, 35A, 36A, 37A, 38A, 39A, 40A, 41A, 42A, 43, 44, 45, 46, 47, 48, 49, 50A, 51A, 52A, 53A, 54A, and 55A illustrate perspective views of intermediate stages of a semiconductor structure in accordance with some embodiments. FIGS. 34B, 35B, 36B, 378, 38B, 39B, 40B, 41B, 42B, 50B, 51B, 52B, 53B, 54A, and 55B illustrate cross-sectional views obtained from the reference cross-sections B-B′ in FIGS. 34A, 35A, 36A, 37A, 38A, 39A, 40A, 41A, 42A, 50A, 51A, 52A, 53A, 54A, and 55A respectively. FIG. 56 illustrates a cross-sectional view of an intermediate stage of a semiconductor structure corresponding to FIG. 55B in accordance with some embodiments.

With reference to FIG. 28. A substrate 210, which may be a part of a wafer, is provided. In some embodiments, the substrate 210 may include silicon (Si). Alternatively, the substrate 210 may include germanium (Ge), silicon germanium (SiGe), gallium arsenide (GaAs) or other appropriate semiconductor materials. In some embodiments, the substrate 210 may include a semiconductor-on-insulator (SOI) structure such as a buried dielectric layer. Also alternatively, the substrate 210 may include a buried dielectric layer such as a buried oxide (BOX) layer, such as that formed by a method referred to as separation by implantation of oxygen (SIMOX) technology, wafer bonding, SEC, or another appropriate method. In various embodiments, the substrate 210 may include any of a variety of substrate structures and materials.

A semiconductor stack 230 is formed on the substrate 210 through epitaxy, such that the semiconductor stack 230 forms crystalline layers. The semiconductor stack 230 includes semiconductor layers 232 and 234 stacked alternatively. In some embodiments, the germanium percentage of the semiconductor layers 232 is in the range between about 20 percent and about 30 percent. In some embodiments, the thickness of the semiconductor layers 232 is in the range between about 5 nm and about 15 nm. The semiconductor layers 234 may be pure silicon layers that are free from germanium. The semiconductor layers 234 may also be substantially pure silicon layers, for example, with a germanium percentage lower than about 1 percent. Furthermore, the semiconductor layers 234 may be intrinsic, which are not doped with p-type and n-type impurities. There may be two, three, four, or more of the semiconductor layers 234. In some embodiments, the thickness of the semiconductor layers 234 is in the range between about 3 nm and about 10 nm. In some other embodiments, however, the semiconductor layers 234 can be silicon germanium or germanium for p-type semiconductor device, or can be III-V materials, such as InAs, InGaAs, InGaAsSb, GaAs, InPSb, or other suitable materials.

A patterned hard mask 240 is formed over the semiconductor stack 230. In some embodiments, the patterned hard mask 240 is formed of silicon nitride, silicon oxynitride, silicon carbide, silicon carbo-nitride, or the like. The patterned hard mask 240 covers a portion of the semiconductor stack 230 while leaves another portion of the semiconductor stack 230 uncovered.

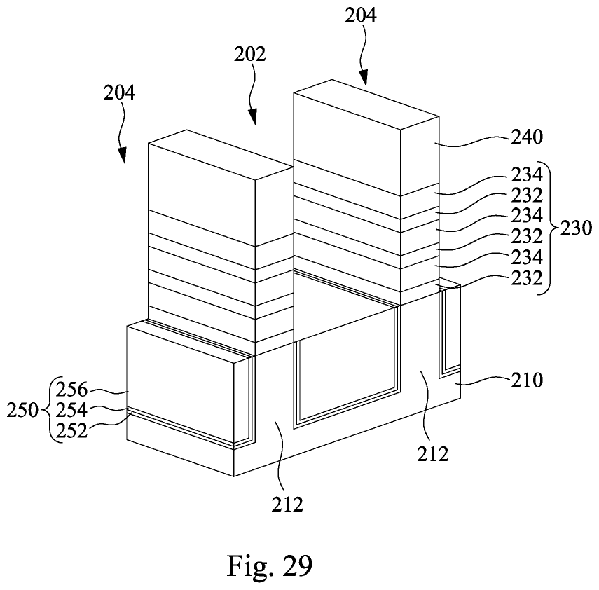

With reference to FIG. 29. The semiconductor stack 230 and the substrate 210 of FIG. 1 are patterned using the patterned hard mask 240 as a mask to form trenches 202. Accordingly, a plurality of semiconductor strips 204 are formed. The trenches 202 extend into the substrate 210, and have lengthwise directions substantially parallel to each other. The trenches 202 form base portions 212 in the substrate 210, where the base portions 212 protrude from the substrate 210, and the semiconductor strips 204 are respectively formed above the base portions 212 of the substrate 210. The remaining portions of the semiconductor stack 230 are accordingly referred to as the semiconductor strips 204 alternatively. In some embodiments, the semiconductor layers 234 may also be referred to as oxide-definition (OD) regions, or semiconductive channel patterns. In some embodiments where the semiconductor layer 234 is made of silicon germanium, the semiconductor layer 234 may have a germanium atomic concentration in a range from about 15% to about 35%, such as 15, 16, 17, 18, 19, 20, 21, 22, 23, 24, 25, 26, 27, 28, 29, 30, 31, 32, 33, 34, or 35%.

Isolation structures 250, which may be shallow trench isolation (STI) regions, are formed in the trenches 202. The formation may include filling the trenches 202 with a dielectric layer(s), for example, using flowable chemical vapor deposition (FCVD), and performing a chemical mechanical polish (CMP) to level the top surface of the dielectric material with the top surface of the hard mask 240. The isolation structures 250 are then recessed. The top surface of the resulting isolation structures 250 may be level with the bottom surface of the semiconductor stack 230, or may be at an intermediate level between the top surface and the bottom surface of the semiconductor stack 230.

In some embodiments, each of the isolation structures 250 includes a first liner layer 252, a second liner layer 254, and a filling material 256. The first liner layer 252 is in contact with the substrate 210 and may be a dielectric layer, such as silicon oxide, silicon nitride, silicon oxynitride, SiCN, SiCₓO_{y}N_{z}, or combinations thereof. The second liner layer 254 is on and in contact with the first liner layer 252 and may be a semiconductor layer such as a silicon layer. The filling material 256 is on and in contact with the second liner layer 254 and may be a dielectric material, such as silicon oxide, silicon nitride, silicon oxynitride, SiCN, SiCₓO_{y}N_{z}, or combinations thereof. In some other embodiments, the second liner layer 254 is omitted. In still some other embodiments, the first and second liner layers 252 and 254 are omitted. In some embodiments, the filling material 256 can be interchangeably referred to a flowable oxide, a dielectric material, or cured flowable oxide material.

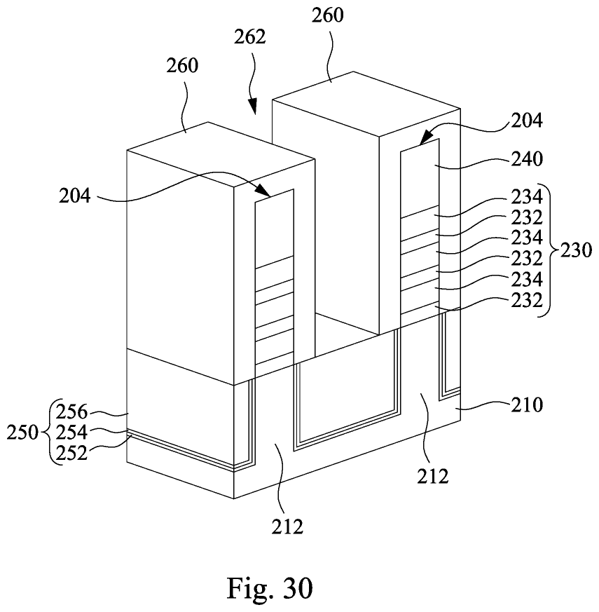

With reference to FIG. 30. Cladding layers 260 are formed above the isolation structures 250 and respectively cover the semiconductor strips 204. In some embodiments, the cladding layers 260 are made of semiconductor materials, such as SiGe or other suitable materials. In some embodiments, the cladding layers 260 and the semiconductor layers 232 may have substantially the same or similar materials/components, such the cladding layers 260 and the semiconductor layers 232 have similar etching rates under the same etchant. The cladding layers 260 are separated from each other, such that trenches 262 are formed therebetween.

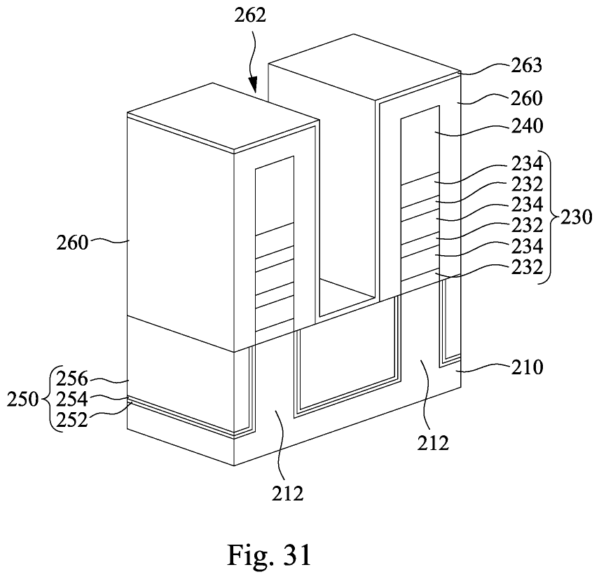

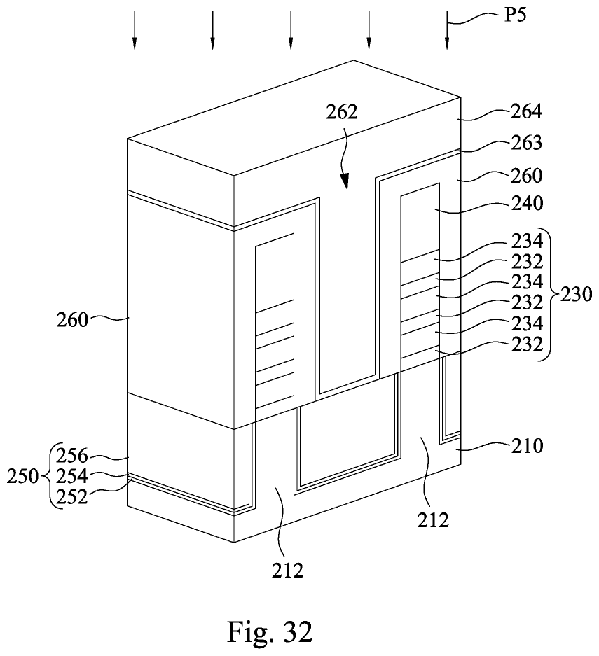

With reference to FIG. 31. A liner layer 263 is conformally formed over the substrate 210. The liner layer 263 is formed in trenches 262 and on the sidewalls of the cladding layers 260 and the top surface of the filling material 256. The liner layer 263 may be a conformal layer whose horizontal portions and vertical portions have thicknesses close to each other. By way of example but not limiting the present disclosure, the liner layer 263 may have a thickness between about 10 Å and about 40 Å. The liner layer 263 may prevent (or at least reduce) the diffusion of semiconductor material from semiconductor stack 230 into dielectric layer 264 (see FIG. 32) formed subsequently during a subsequent annealing process. Other processes and materials may be used. In some embodiments, the liner layer 263 may be made of an oxide base dielectric material, a carbon base dielectric material, a nitride base dielectric material, combinations thereof, or other suitable materials. By way of example but not limiting the present disclosure, the liner layer 263 may include SiN, SiOC, SiON, SiOCN, or combinations thereof. In some embodiments, the liner layer 162 may be deposited using any suitable method, such as CVD, physical vapor deposition (PVD), ALD, PEALD, PECVD, SACVD, FCVD, spin-on, and/or the like, or a combination thereof. In some embodiments, the liner layer 263 can be interchangeably referred to a dielectric film.

With reference to FIG. 32. A dielectric layer 264 is formed to overfill the trenches 262 and cover the semiconductor stack 230. The dielectric layer 264 in the trenches 262 can be referred to as a shallow trench isolation (STI) structure. In some embodiments, the dielectric layer 264 may be made of low-K dielectric materials. By way of example but not limiting the present disclosure, the dielectric layer 264 may be made of silicon oxide, silicon nitride, silicon oxynitride, fluoride-doped silicate glass (FSG), silicon carbide, silicon nitride, the like, or a combination thereof. In some embodiments, the dielectric layer 264 may be formed using flowable chemical vapor deposition (FCVD), spin-on coating, CVD, ALD, high-density plasma chemical vapor deposition (HDPCVD), LPCVD, the like, or a combination thereof. In some embodiments where FCVD is used to form the dielectric layer 264, a silicon- and nitrogen-containing precursor (for example, trisilylamine (TSA) or disilylamine (DSA)) is used, and hence the resulting dielectric layer 264 is flowable (jelly-like). In some embodiments, the dielectric layer 264 is formed using an alkylamino silane based precursor. During the deposition of the dielectric layer 264, plasma is turned on to activate the gaseous precursors for forming the flowable oxide. In some embodiments, the dielectric layer 264 may be formed using silane (SiH₄) and oxygen (O₂) as reacting precursors. In some embodiments, the dielectric layer 264 may be formed using a sub-atmospheric CVD (SACVD) process or high aspect-ratio process (HARP), in which process gases may include tetraethylorthosilicate (TEOS) and ozone (O₃). In some embodiments, the dielectric layer 264 may be formed using a spin-on-dielectric (SOD) process, such as hydrogen silsesquioxane (HSQ) or methyl silsesquioxane (MSQ). Other processes and materials may be used.

Subsequently, an annealing process P5 is performed, which converts flowable dielectric layer 264 into a solid dielectric material. In some embodiments, the annealing process P5 can be interchangeably referred to a thermal treatment. After the flowable dielectric layer 264 is deposited, an in-situ steam thermal annealing step of the annealing process P5 can be performed on the as-deposited flowable dielectric layer 264 to cure the flowable dielectric layer 264. In some embodiments, the steam thermal annealing step of the annealing process P5 can be interchangeably referred to a curing step. In-situ means the steam thermal annealing step of the annealing process P5 is performed in the process chamber for depositing the flowable dielectric layer 264. In some embodiments, the steam thermal annealing step of the annealing process P5 can be performed in a different chamber (or ex-situ). The steam thermal annealing step of the annealing process P5 may increase the oxygen content of the as-deposited flowable dielectric layer 264, which is made of a network of SiO_{A}N_{B}H_{C} (or SiONH), and most of NH ions and H ions of the flowable dielectric layer 264 can be removed. An oxygen source, such as steam (H₂O), can be provided to assist the conversion of the SiONH network into SiO (or SiO₂) network. The steam thermal annealing step of the annealing process P5 causes the flowable dielectric layer 264 to shrink. The duration and the temperature of the steam thermal annealing step of the annealing process P5 affect the amount of shrinkage. The steam thermal annealing step of the annealing process P5 can be conducted in a furnace, in some embodiments. In some embodiments, a temperature for the steam thermal annealing step of the annealing process P5 may be in a range from about 150° C. to about 800° C., such as 150, 200, 300, 400, 500, 600, 700, or 800° C., by way of example and not limitation. In some embodiments, the steam thermal annealing step of the annealing process P5 may starts at about 150° C. and ramps up the temperature gradually to a predetermined temperature, such as about 800° C. The gas or gases used for the steam thermal annealing step of the annealing process P5 may include H₂O, O₂, N₂, or combinations thereof.

After the steam thermal annealing step of the annealing process P5 described above, a “dry” (without steam) thermal annealing step of the annealing process P5 is conducted to convert the SiOH and SiO network into SiO (or SiO₂) network. During the dry thermal annealing step of the annealing process P5, steam is not used. In some embodiments, an inert gas, such as N₂, is used during the dry thermal annealing step of the annealing process P5. In some embodiments, the gas or gases used for the dry thermal annealing step of the annealing process P5 may include O₂. In some embodiments, the anneal temperature of the dry thermal annealing step of the annealing process P5 may be less than about 800° C. The dry thermal annealing step of the annealing process P5 is conducted in a furnace, in some embodiments. The gas or gases used for the dry thermal annealing step of the annealing process P5 may include an inert gas, such as N₂, Ar, He or combinations thereof. The duration of the dry thermal annealing step of the annealing process P5 is a range from about 30 minutes to about 3 hours. The dry thermal annealing step of the annealing process P5 converts the network of SiOH and SiO in the flowable dielectric layer 264 to a network of SiO (or SiO₂). The dry thermal annealing step of the annealing process P5 may also cause flowable dielectric layer 264 to shrink further. The duration and temperature of the dry thermal annealing step of the annealing process P5 affect the amount of shrinkage. The steam annealing step and the dry thermal annealing step of the annealing process P5 of the annealing process P5 cause flowable dielectric layer 264 to shrink. In some embodiments, the volume of the flowable dielectric layer 264 shrinks in a range from about 5% to about 20%. The duration of the steam annealing step and the dry thermal annealing step of the annealing process P5 affect the amount of shrinking. In some embodiments, the dielectric layer 264 can be interchangeably referred to a flowable oxide, a dielectric material, or cured flowable oxide material.

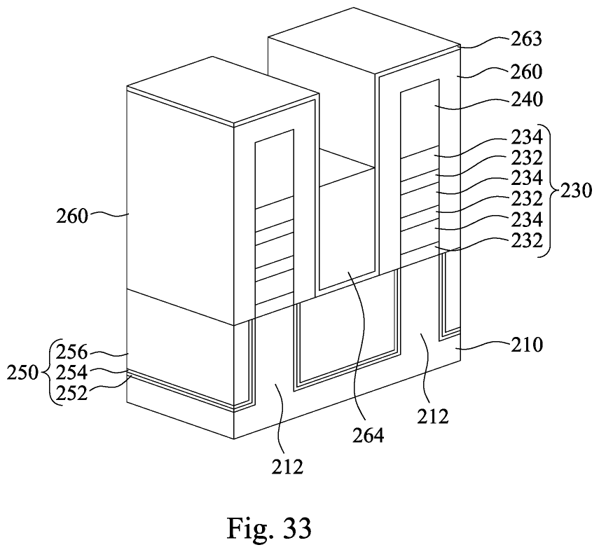

With reference to FIG. 33. A planarization process such as chemical mechanical polish (CMP) is performed to remove the excess dielectric layer 264 over the semiconductor stack 230. In some embodiments, the planarization process stops when the liner layer 263 is exposed. In such embodiments, the liner layer 263 may act as the CMP stop layer in the planarization. Subsequently, the dielectric layer 264 is recessed, for example, through an etching operation, in which diluted HF, SiCoNi (including HF and NH₃), or the like, may be used as the etchant. After recessing the dielectric layer 264, portions of the patterned hard mask 240 are higher than the top surface of the dielectric layer 264. In some embodiments, after recessing the dielectric layer 264, portions of the semiconductor stack 230 are higher than the top surface of the dielectric layer 264.

With reference to FIGS. 34A and 34B. A planarization process such as chemical mechanical polish (CMP) is performed to remove the excess dielectric layer 264 and the cladding layers 260 over the patterned hard mask 240. In some embodiments, the planarization process stops when the patterned hard mask 240 is exposed. In such embodiments, the patterned hard mask 240 may act as the CMP stop layer in the planarization. Subsequently, an etching process P6 is performed to remove the liner layer 263 exposed from the dielectric layer 264. The etching process P6 is a selective etching process that uses an etchant etching the liner layer 263 at a faster etch rate than it etches the dielectric layer 264, the cladding layers 260, and the patterned hard mask 240. For example, the etch rate of the etching process P6 to the liner layer 263 is greater than about twice the etch rate of the etching process P6 to the dielectric layer 264, the cladding layers 260, and the patterned hard mask 240. If the etch rate of the etching process P6 to the liner layer 263 is lower than about twice the etch rate of the etching process P6 to the dielectric layer 264, the cladding layers 260, and the patterned hard mask 240, the etching process P6 may excessively consume the dielectric layer 264, the cladding layers 260, and the patterned hard mask 240 and thus the semiconductor stack 230 may be damaged, and thus the yield may reduce. In this way, the dielectric layer 264, the cladding layers 260, and the patterned hard mask 240 remain substantially intact after removing the liner layer 263. In some embodiments, the etching process P6 may be performed using an isotropic etching process. For example, the etchant used in the etching process P6 includes phosphoric acid (H₃PO₄).

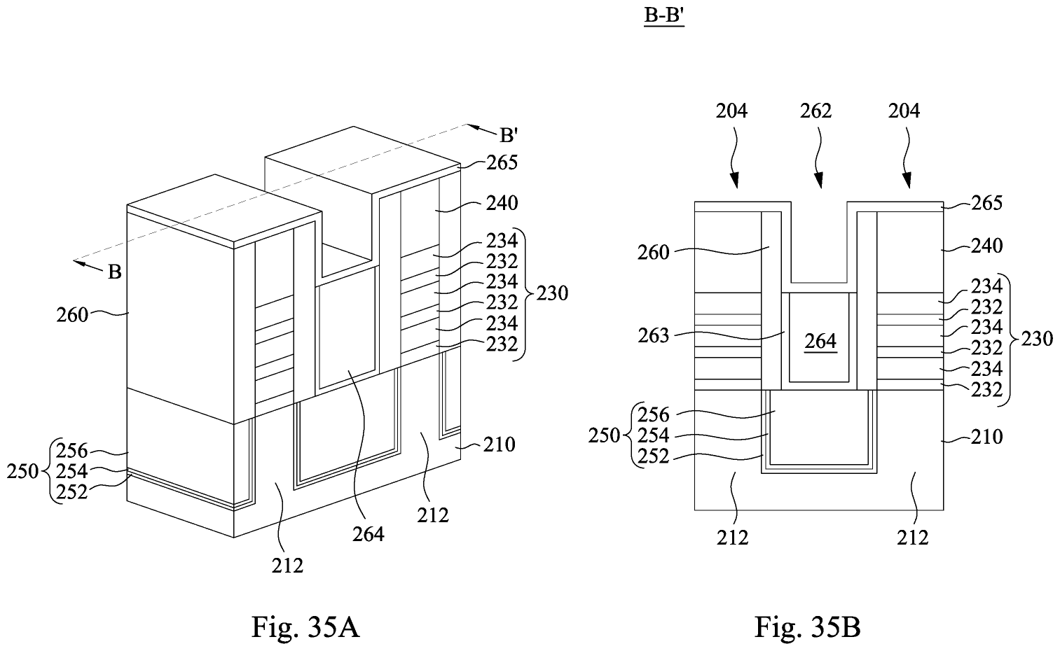

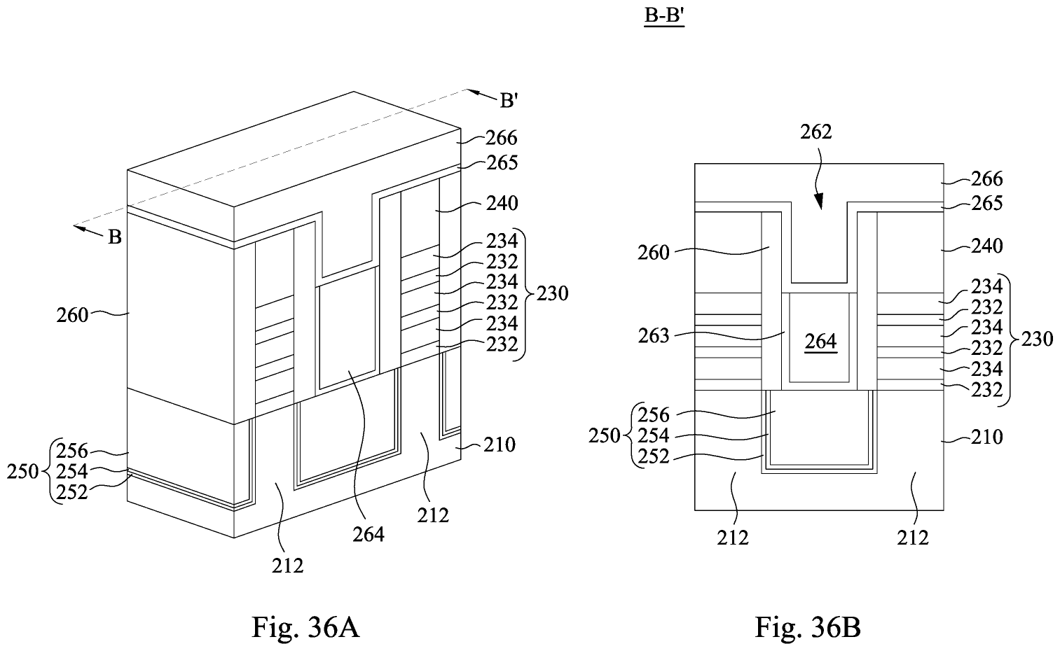

With reference to FIGS. 35A and 35B. A liner layer 265 is conformally formed over the substrate 210. The liner layer 265 is formed in trenches 262 (see FIG. 35B) and on the sidewalls of the cladding layers 260 and the top surfaces of the dielectric layer 264 and the liner layer 263. The liner layer 265 may be a conformal layer whose horizontal portions and vertical portions have thicknesses close to each other. By way of example but not limiting the present disclosure, the liner layer 265 may have a thickness between about 10 Å and about 40 Å. The liner layer 265 may prevent (or at least reduce) the diffusion of semiconductor material from the semiconductor stack 230 into dielectric layer 266 (see FIGS. 36A and 36B) formed subsequently during a subsequent annealing process. Other processes and materials may be used.

In some embodiments, the liner layer 265 may be made of an oxide base dielectric material, a carbon base dielectric material, a nitride base dielectric material, combinations thereof, or other suitable materials. In some embodiments, the liner layer 265 may include SiOC, SiON, SiOCN, or combinations thereof. In some embodiments, the liner layer 265 may be made of a metal oxide. In some embodiments, the liner layer 265 may include, for example, a high-k dielectric material such as metal oxides, metal nitrides, metal silicates, transition metal-oxides, transition metal-nitrides, transition metal-silicates, oxynitrides of metals, metal aluminates, zirconium silicate, zirconium aluminate, or combinations thereof. In some embodiments, the liner layer 265 may be made of a material having a dielectric constant greater than about 10. In some embodiments, the liner layer 265 may include hafnium oxide (HfO₂), hafnium silicon oxide (HfSiO), hafnium silicon oxynitride (HfSiON), hafnium tantalum oxide (HfTaO), hafnium titanium oxide (HfTiO), hafnium zirconium oxide (HfZrO), lanthanum oxide (LaO), zirconium oxide (ZrO₂), titanium oxide (TiO₂), tantalum oxide (Ta₂O₅), yttrium oxide (Y₂O₃), strontium titanium oxide (SrTiO₃, STO), barium titanium oxide (BaTiO₃, BTO), barium zirconium oxide (BaZrO), hafnium lanthanum oxide (HfLaO), lanthanum silicon oxide (LaSiO), aluminum silicon oxide (AlSiO), aluminum oxide (Al₂O₃), silicon nitride (Si₃N₄), oxynitrides (SiON), any suitable materials, or combinations thereof. In some embodiments, the liner layer 265 may include SiCN, SiO₂, HZO (a mixture of HfO₂ and ZrO₂), PZT (PbZr_{0.52}Ti_{0.48}O₃), VDF-TrFE (ferroelectric polymer), any suitable materials, or combinations thereof. In alternative embodiments, the liner layer 265 may have a multilayer structure including, such as a silicon oxide layer (e.g., SiO₂ layer), a first high-k material layer (e.g., HfO₂ layer), and a second high-k material layer (e.g., ZrO₂ layer). In some embodiments, the liner layer 265 may be deposited using any suitable method, such as CVD, physical vapor deposition (PVD), ALD, PEALD, PECVD, SACVD, FCVD, spin-on, and/or the like, or a combination thereof. In some embodiments, the liner layer 265 can be interchangeably referred to a dielectric film.

With reference to FIGS. 36A and 36B. A dielectric layer 266 is formed to overfill the trenches 262 (see FIG. 368) and cover the semiconductor stack 230. In some embodiments, the dielectric layer 266 may be made of low-K dielectric materials. By way of example but not limiting the present disclosure, the dielectric layer 266 may be made of silicon oxide, silicon nitride, silicon oxynitride, fluoride-doped silicate glass (FSG), silicon carbide, silicon nitride, the like, or a combination thereof. In some embodiments, the dielectric layer 266 may be formed using flowable chemical vapor deposition (FCVD), spin-on coating, CVD, ALD, high-density plasma chemical vapor deposition (HDPCVD), LPCVD, the like, or a combination thereof. In some embodiments where FCVD is used to form the dielectric layer 266, a silicon- and nitrogen-containing precursor (for example, trisilylamine (TSA) or disilylamine (DSA)) is used, and hence the resulting dielectric layer 266 is flowable (jelly-like). In some embodiments where FCVD is used to form the dielectric layer 266, precursors including tri-silylamine, ammonia, and oxygen can be used, and hence the resulting dielectric layer 266 can be flowable (jelly-like). In some embodiments, the FCVD process may be performed under a temperature in a range from about 10° C. to about 500° C. In some embodiments, the dielectric layer 266 is formed using an alkylamino silane based precursor. During the deposition of the dielectric layer 266, plasma is turned on to activate the gaseous precursors for forming the flowable oxide. In some embodiments, the dielectric layer 266 may be formed using silane (SiH₄) and oxygen (O₂) as reacting precursors. In some embodiments, the dielectric layer 266 may be formed using a sub-atmospheric CVD (SACVD) process or high aspect-ratio process (HARP), in which process gases may include tetraethylorthosilicate (TEOS) and ozone (O₃). In some embodiments, the dielectric layer 266 may be formed using a spin-on-dielectric (SOD) process, such as hydrogen silsesquioxane (HSQ) or methyl silsesquioxane (MSQ). Other processes and materials may be used.

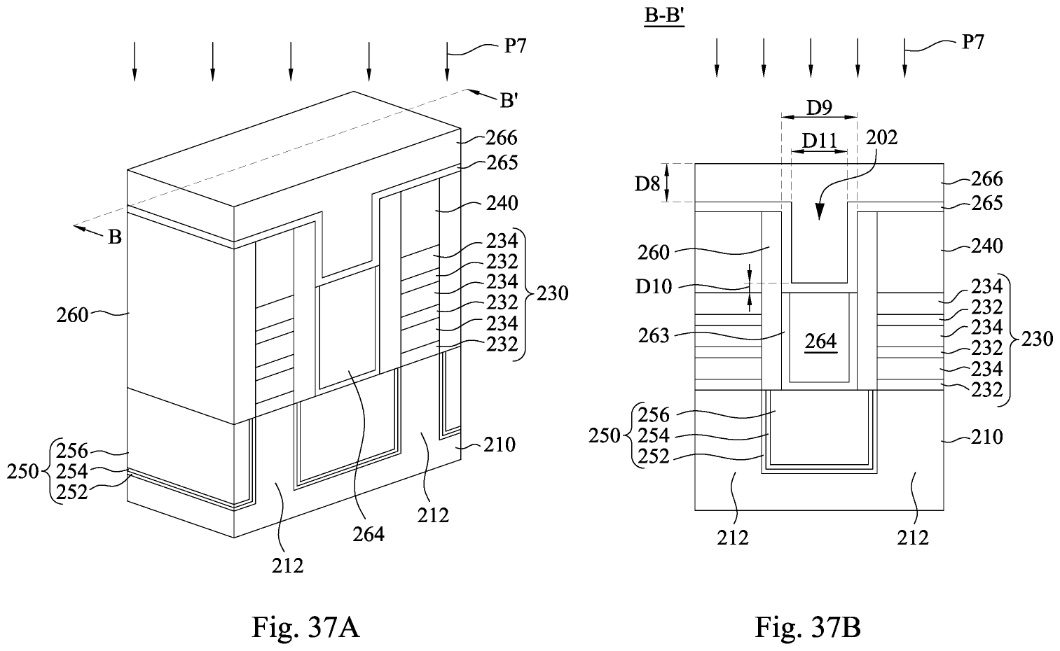

With reference to FIGS. 37A and 37B. An annealing process P7 is performed, which converts flowable dielectric layer 266 into a solid dielectric material. In some embodiments, the annealing process P7 can be interchangeably referred to a thermal treatment. After the flowable dielectric layer 266 is deposited, an in-situ steam thermal annealing step of the annealing process P7 can be performed on the as-deposited flowable dielectric layer 266 to cure the flowable dielectric layer 266. In some embodiments, the steam thermal annealing step of the annealing process P1 can be interchangeably referred to a curing step. In-situ means the steam thermal annealing step of the annealing process P7 is performed in the process chamber for depositing the flowable dielectric layer 266. In some embodiments, the steam thermal annealing step of the annealing process P7 can be performed in a different chamber (or ex-situ). The steam thermal annealing step of the annealing process P7 may increase the oxygen content of the as-deposited flowable dielectric layer 266, which is made of a network of SiO_{A}N_{B}H_{C} (or SiONH), and most of NH ions and H ions of the flowable dielectric layer 266 can be removed. An oxygen source, such as steam (H₂O), can be provided to assist the conversion of the SiONH network into SiO (or SiO₂) network. The steam thermal annealing step of the annealing process P7 causes the flowable dielectric layer 266 to shrink. The duration and the temperature of the steam thermal annealing step of the annealing process P7 affect the amount of shrinkage.

The steam thermal annealing step of the annealing process P7 can be conducted in a furnace, in some embodiments. In some embodiments, a temperature for the steam thermal annealing step of the annealing process P7 may be less than about 500° C., by way of example and not limitation. In some embodiments, a temperature for the steam thermal annealing step of the annealing process P7 may be in a range of about 10° C. to about 500° C., such as 10, 50, 100, 150, 200, 250, 300, 350, 400, 450, or 500° C., by way of example and not limitation. In some embodiments, a temperature for the steam thermal annealing step of the annealing process P7 may be less than a temperature for the steam thermal annealing step of the annealing process P5. In some embodiments, a temperature for the steam thermal annealing step of the annealing process P7 may be less than a temperature for the dry thermal annealing step of the annealing process P5. In some embodiments, the steam thermal annealing step of the annealing process P7 may starts at about 150° C. and ramps up the temperature gradually to a predetermined temperature less than about 500° C. In some embodiments, the duration of the steam thermal annealing step of the annealing process P7 may be less than about 2 hrs. In some embodiments, the duration of the steam thermal annealing step of the annealing process P7 may be in a range from about 5 mins to about 2 hrs, such as 5, 10, 15, 30, 45, 60, 75, 90, 105, or 120 mins, by way of example and not limitation. The gas or gases used for the steam thermal annealing step of the annealing process P4 may include H₂O, O₂, N₂, or combinations thereof. In some embodiments, the steam thermal annealing step of the annealing process P7 may performing in an ambient having a H₂O ratio in a range from about 5% to about 100%, such as 5, 10, 20, 30, 40, 50, 60, 70, 80, 90, or 100%, by way of example and not limitation.

After the steam thermal annealing step of the annealing process P7 described above, a “dry” (without steam) thermal annealing step of the annealing process P7 is conducted to convert the SiOH and SiO network into SiO (or SiO₂) network. During the dry thermal annealing step of the annealing process P7, steam is not used. In some embodiments, an inert gas, such as N₂, is used during the dry thermal annealing step of the annealing process P7. In some embodiments, the gas or gases used for the dry thermal annealing step of the annealing process P7 may include O₂. In some embodiments, the anneal temperature of the dry thermal annealing step of the annealing process P7 may be less than about 800° C. In some embodiments, the dry thermal annealing step of the annealing process P7 may be performed under a higher temperature than the steam thermal annealing step of the annealing process P7. In some embodiments, the FCVD process for depositing the dielectric layer 266 as shown in FIGS. 36A and 36B may be performed under a lower temperature than the dry thermal annealing step of the annealing process P7.

The dry thermal annealing step of the annealing process P7 is conducted in a furnace, in some embodiments. The gas or gases used for the dry thermal annealing step of the annealing process P7 may include an inert gas, such as N₂, Ar, He or combinations thereof. The duration of the dry thermal annealing step of the annealing process P7 is a range from about 30 minutes to about 3 hours. The dry thermal annealing step of the annealing process P7 converts the network of SiOH and SiO in the flowable dielectric layer 266 to a network of SiO (or SiO₂). The dry thermal annealing step of the annealing process P7 may also cause flowable dielectric layer 266 to shrink further. The duration and temperature of the dry thermal annealing step of the annealing process P7 affect the amount of shrinkage. The steam annealing step and the dry thermal annealing step of the annealing process P7 of the annealing process P7 cause flowable dielectric layer 266 to shrink. In some embodiments, the volume of the flowable dielectric layer 266 shrinks in a range from about 5% to about 20%. The duration of the steam annealing step and the dry thermal annealing step of the annealing process P7 affect the amount of shrinking. In some embodiments, the dielectric layer 264 can be interchangeably referred to a flowable oxide, a dielectric material, or cured flowable oxide material.

By way of example and not limitation, a distance D8 from a top surface of the liner layer 265 to a top surface of the dielectric layer 266 may be less than about 100 nm, such as 10, 20, 30, 40, 50, 60, 70, 80, 90, or 100 nm. Spacing D9 between adjacent two cladding layers 260 may be in a range from about 15 to about 500 nm, such as 15, 17, 20, 50, 100, 150, 200, 250, 300, 350, 400, 450, or 500 nm, by way of example and not limitation. The liner layer 265 may have a thickness D10 in a range from about 2 to about 6 nm, such as 2, 3, 4, 5, or 6 nm, by way of example and not limitation. A distance D11 of vertical portions of the 168 in the trench 202 may be in a range from about 3 nm to about 496 nm, such as 3, 5, 8, 10, 50, 100, 150, 200, 250, 300, 350, 400, 450, 490, or 496 nm, by way of example and not limitation.

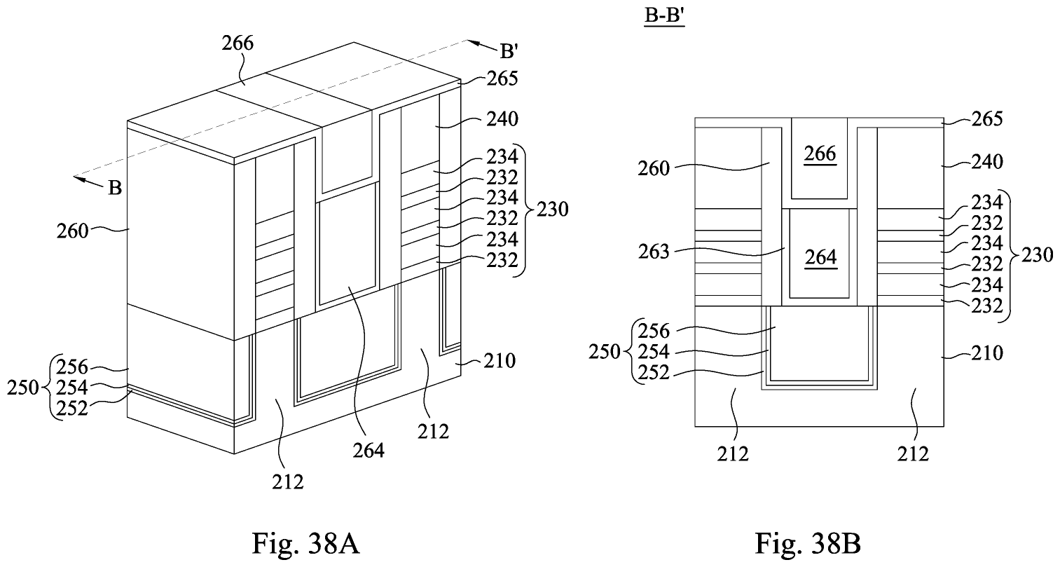

With reference to FIGS. 38A and 38B. A planarization process such as chemical mechanical polish (CMP) is performed to remove the excess dielectric layer 264 over the semiconductor stack 230. In some embodiments, the planarization process stops when the liner layer 265 is exposed. In such embodiments, the liner layer 265 may act as the CMP stop layer in the planarization.

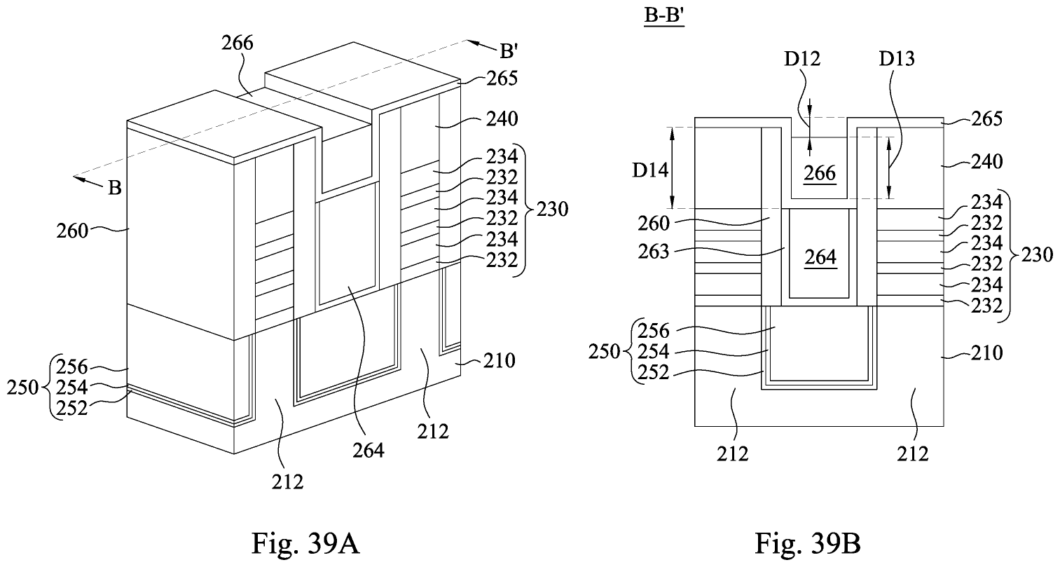

With reference to FIGS. 39A and 39B. The dielectric layer 266 is recessed, for example, through an etching operation, in which diluted HF, SiCoNi (including HF and NH₃), or the like, may be used as the etchant. After recessing the dielectric layer 266, portions of the patterned hard mask 240 may be higher than the top surface of the dielectric layer 266. In some embodiments, the thickness D10 (see FIG. 37B) of the liner layer 265 may be thinner than the recessed dielectric layer 266. By way of example and not limitation, the recessed dielectric layer 266 may have a thickness D13 in a range from about 5 nm to about 15 nm, such as 5, 6, 7, 8, 9, 10, 11, 12, 13, 14, or 15. In some embodiments, the thickness D10 (see FIG. 37B) of the liner layer 265 may be less than a distance D12 from a top surface of the recessed dielectric layer 266 to a top surface of the liner layer 265. By way of example and not limitation, the distance D12 may be in a range from about 10 nm to about 20 nm, such as 10, 11, 12, 13, 14, 15, 16, 17, 18, 19, or 20 nm. In some embodiments, the thickness D10 (see FIG. 37B) of the liner layer 265 may be less than a distance D14 from a bottom surface of the liner layer 265 to a top surface of the hard mask 240 and/or the cladding layer 260. By way of example and not limitation, the distance D14 may be in a range from about 20 nm to about 30 nm, such as 20, 21, 22, 23, 24, 25, 26, 27, 28, 29, or 30 nm.

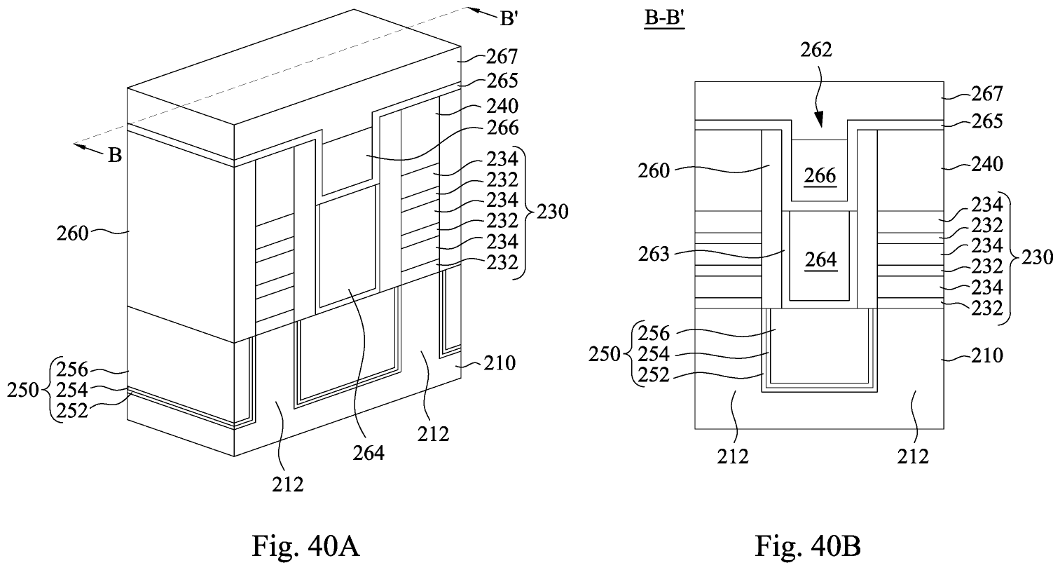

With reference to FIGS. 40A and 40B. A dielectric layer 267 is formed to overfill the trenches 262 (see FIG. 40B) and cover the semiconductor stack 230. In some embodiments, the dielectric layer 267 may be made of an oxide base dielectric material, a carbon base dielectric material, a nitride base dielectric material, combinations thereof, or other suitable materials. In some embodiments, the dielectric layer 267 may include SiOC, SiON, SiOCN, or combinations thereof. In some embodiments, the dielectric layer 267 may be made of a metal oxide. In some embodiments, the dielectric layer 267 may include, for example, a high-k dielectric material such as metal oxides, metal nitrides, metal silicates, transition metal-oxides, transition metal-nitrides, transition metal-silicates, oxynitrides of metals, metal aluminates, zirconium silicate, zirconium aluminate, or combinations thereof. In some embodiments, the dielectric layer 267 may be made of a material having a dielectric constant greater than about 10. In some embodiments, the dielectric layer 267 may include hafnium oxide (HfO₂), hafnium silicon oxide (HfSiO), hafnium silicon oxynitride (HfSiON), hafnium tantalum oxide (HfTaO), hafnium titanium oxide (HfTiO), hafnium zirconium oxide (HfZrO), lanthanum oxide (LaO), zirconium oxide (ZrO₂), titanium oxide (TiO₂), tantalum oxide (Ta₂O₅), yttrium oxide (Y₂O₃), strontium titanium oxide (SrTiO₃, STO), barium titanium oxide (BaTiO₃, BTO), barium zirconium oxide (BaZrO), hafnium lanthanum oxide (HfLaO), lanthanum silicon oxide (LaSiO), aluminum silicon oxide (AlSiO), aluminum oxide (Al₂O₃), silicon nitride (Si₃N₄), oxynitrides (SiON), any suitable materials, or combinations thereof. In some embodiments, the dielectric layer 267 may include SiCN, SiO₂, HZO (a mixture of HfO₂ and ZrO₂), PZT (PbZr_{0.52}Ti_{0.48}O₃), VDF-TrFE (ferroelectric polymer), any suitable materials, or combinations thereof. In alternative embodiments, the dielectric layer 267 may have a multilayer structure including, such as a silicon oxide layer (e.g., SiO₂ layer), a first high-k material layer (e.g., HfO₂ layer), and a second high-k material layer (e.g., ZrO₂ layer). In some embodiments, the dielectric layer 267 may be deposited using any suitable method, such as CVD, physical vapor deposition (PVD), ALD, PEALD, PECVD, SACVD, FCVD, spin-on, and/or the like, or a combination thereof. In some embodiments, the dielectric layer 267 can be interchangeably referred to a dielectric film. In some embodiments, the dielectric layer 267 may be made of a same material as the liner layer 265. In some embodiments, the dielectric layer 267 may be made of a different material than the liner layer 265.

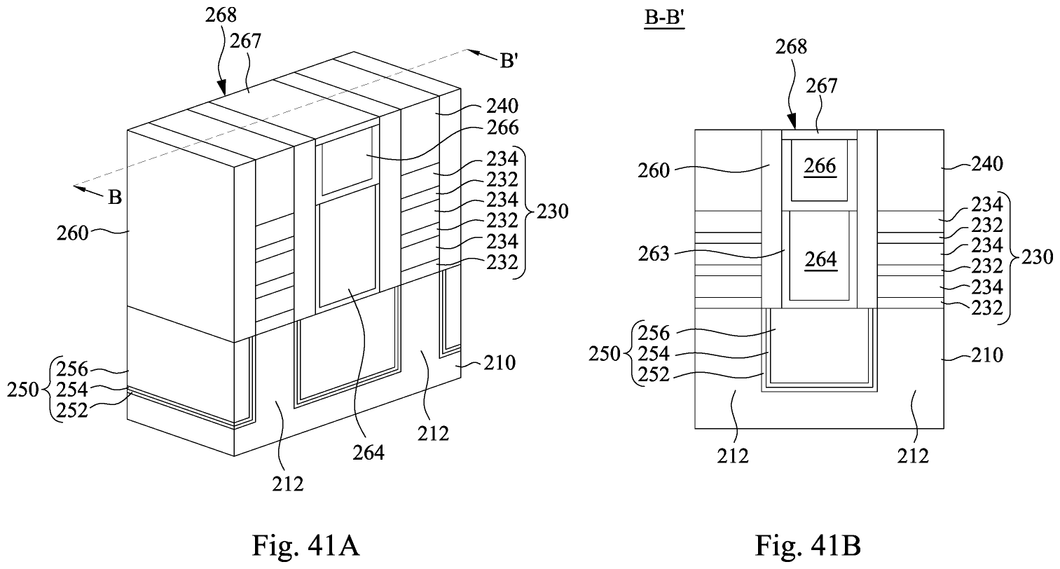

With reference to FIGS. 41A and 41B. A planarization process such as chemical mechanical polish (CMP) is performed to remove the dielectric layer 267 over the patterned hard mask 240. In some embodiments, the planarization process stops when the patterned hard mask 240 is exposed. In such embodiments, the semiconductor patterned hard mask 240 may act as the CMP stop layer in the planarization. In some embodiments, the dielectric layers 264, 266, 267 and the liner layers 263, 265 can be collectively referred to as a dummy fin 268. In some embodiments, the dummy fin can be interchangeably referred to as a dielectric fin. In some embodiments, the dielectric layers 266, 267 and the liner layer 265 can be collectively referred to as a core-shell structure. In some embodiments, the dummy fin 268 may include sulfur (S). In some embodiments, at least one of the dielectric layers 264, 266, 267 and the liner layers 263, 265 in the dummy fin 268 may include sulfur. In some embodiments, at least any two of the dielectric layers 264, 266, 267 and the liner layers 263, 265 in the dummy fin 268 may include a same chemical element, such as sulfur (S).

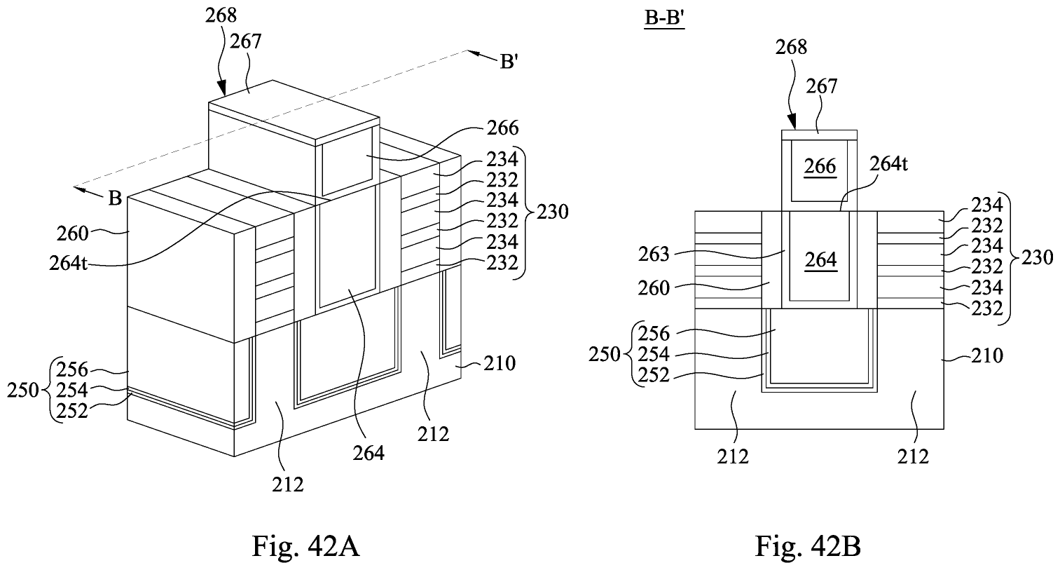

With reference to FIGS. 42A and 428. The patterned hard masks 240 (see FIGS. 41A and 41B) are removed, and then the topmost semiconductor layer 232 and portions of the cladding layers 260 above top surfaces of the topmost semiconductor layer 234 are removed. As such, top surfaces of the cladding layers 260 are substantially level with the top surface 264t of the dielectric layer 264. In some embodiments, multiple etching processes are performed to etch back the cladding layers 260 and remove the hard masks 240 and the topmost semiconductor layer 232. The etching processes include dry etching process, wet etching process, or combinations thereof.

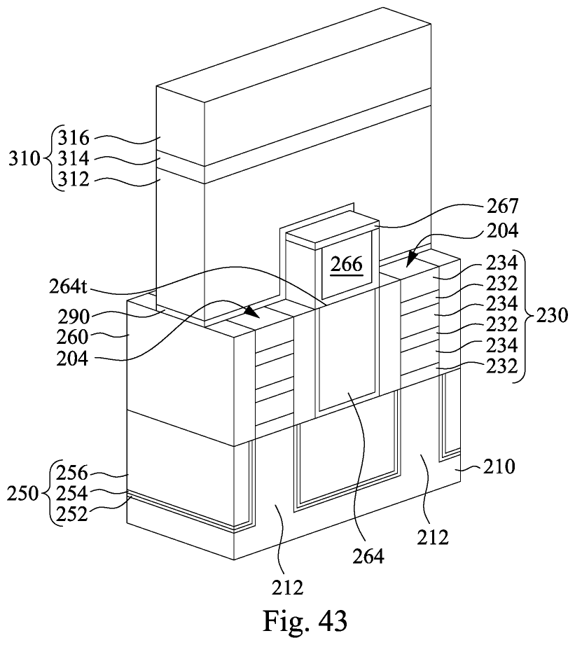

With reference to FIG. 43. An interfacial layer 290 is conformally formed above the structure of FIGS. 42A and 42B. In some embodiments, the interfacial layer 290 may include silicon dioxide, silicon nitride, a high-K dielectric material or other suitable material. In various examples, the interfacial layer 290 may be deposited by an ALD process, a CVD process, a subatmospheric CVD (SACVD) process, a flowable CVD process, a PVD process, or other suitable process. By way of example, the interfacial layer 290 may be used to prevent damage to the semiconductor strips 230 by subsequent processing (e.g., subsequent formation of the dummy gate structure).

Subsequently, at least one dummy gate structure 310 is formed above the interfacial layer 290. The dummy gate structure 310 includes a dummy gate layer 312, a pad layer 314 formed over the dummy gate layer 312, and a mask layer 316 formed over the pad layer 314. In some embodiments, a dummy gate layer (not shown) may be formed over the interfacial layer 290, and the pad layer 314 and the mask layer 316 are formed over the dummy gate layer. The dummy gate layer is then patterned using the pad layer 314 and the mask layer 316 as masks to form the dummy gate layer 312. As such, the dummy gate layer 312, the pad layer 314, and the mask layer 316 are referred to as the dummy gate structure 310. In some embodiments, the dummy gate layer 312 may be made of polycrystalline-silicon (poly-Si), poly-crystalline silicon-germanium (poly-SiGe), or other suitable materials. The pad layer 314 may be made of silicon nitride or other suitable materials, and the mask layer 316 may be made of silicon dioxide or other suitable materials. In some embodiments, the dummy gate structure 310 can be interchangeably referred to a gate patter or a gate strip.

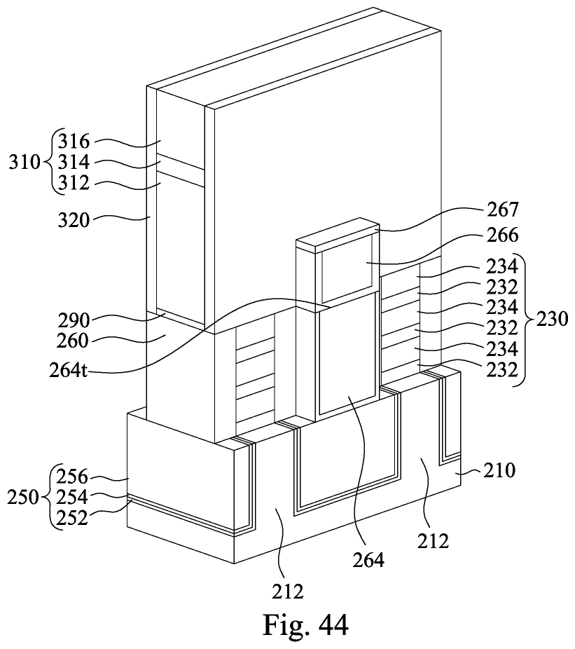

With reference to FIG. 44. Gate spacers 320 are respectively formed on sidewalls of the dummy gate structure 310. The gate spacers 320 may include a seal spacer and a main spacer (not shown). The gate spacers 320 include one or more dielectric materials, such as silicon oxide, silicon nitride, silicon oxynitride, SiCN, SiCxOyNz, or combinations thereof. The seal spacers are formed on sidewalls of the dummy gate structure 310 and the main spacers are formed on the seal spacers. The gate spacers 320 can be formed using a deposition method, such as plasma enhanced chemical vapor deposition (PECVD), low-pressure chemical vapor deposition (LPCVD), sub-atmospheric chemical vapor deposition (SACVD), or the like. The formation of the gate spacers 320 may include blanket forming spacer layers, and then performing etching operations to remove the horizontal portions of the spacer layers. The remaining vertical portions of the gate spacer layers form the gate spacers 320. Subsequently, the semiconductor strips 204 (see FIG. 43) and the cladding layers 260 are further patterned using the dummy gate structure 310 and the gate spacers 320 as masks, such that portions of the isolation structures 250 and the base portions 212 of the substrate 210 are exposed. In some embodiments, the patterning process is performed with an anisotropic dry etch process.

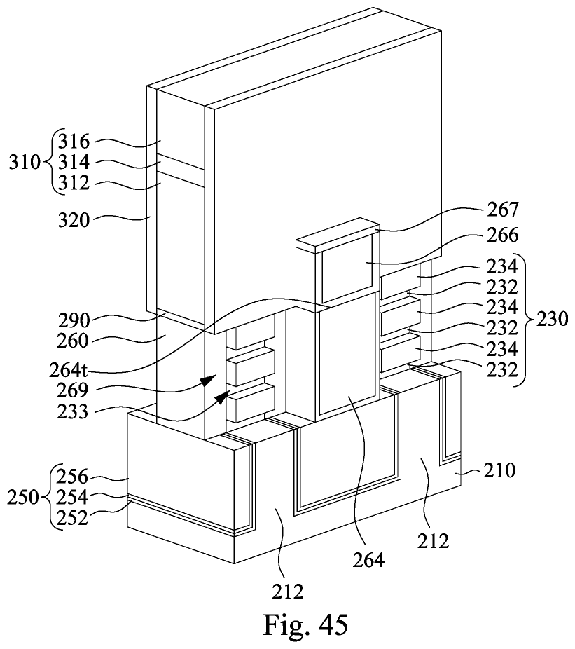

With reference to FIG. 45. The semiconductor layers 232 and the cladding layers 260 are horizontally recessed (etched) so that edges of the semiconductor layers 232 and the cladding layers 260 are located substantially below the gate spacers 320 and recesses 233 and 269 are formed. The etching of the semiconductor layers 232 and the cladding layers 260 includes wet etching and/or dry etching. A wet etchant such as a tetramethylammonium hydroxide (TMAH) solution can be used to selectively etch the semiconductor layers 232 and the cladding layers 260.

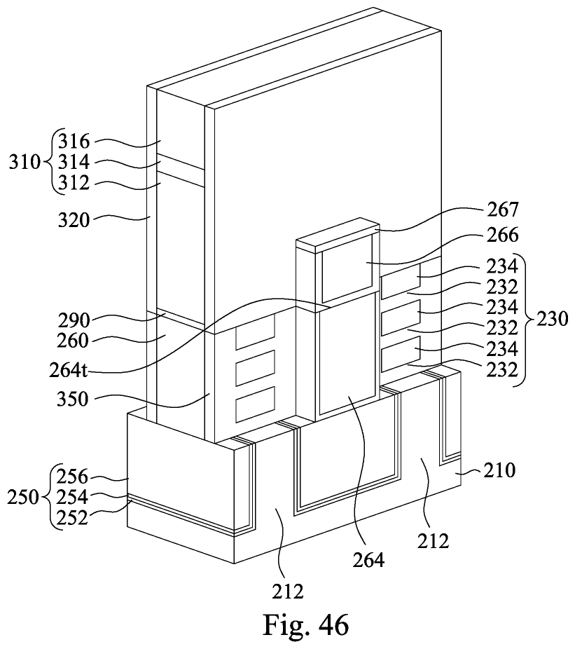

With reference to FIG. 46. Inner sidewall spacers 350 are respectively formed in the recesses 233 and 239 (see FIG. 45) of the semiconductor layers 232 and the cladding layers 260. For example, a dielectric material layer is formed over the structure of FIG. 45, and one or more etching operations are performed to form the inner sidewall spacers 350. In some embodiments, the inner sidewall spacers 350 includes a silicon nitride-based material, such as SiN, SiON, SiOCN or SiCN and combinations thereof and is different from the material of the gate spacers 320. In some embodiments, the inner sidewall spacers 350 are silicon nitride. The dielectric material layer can be formed using CVD, including LPCVD and PECVD, PVD, ALD, or other suitable processes. The etching operations include one or more wet and/or dry etching operations. In some embodiments, the etching is an isotropic etching in some embodiments.

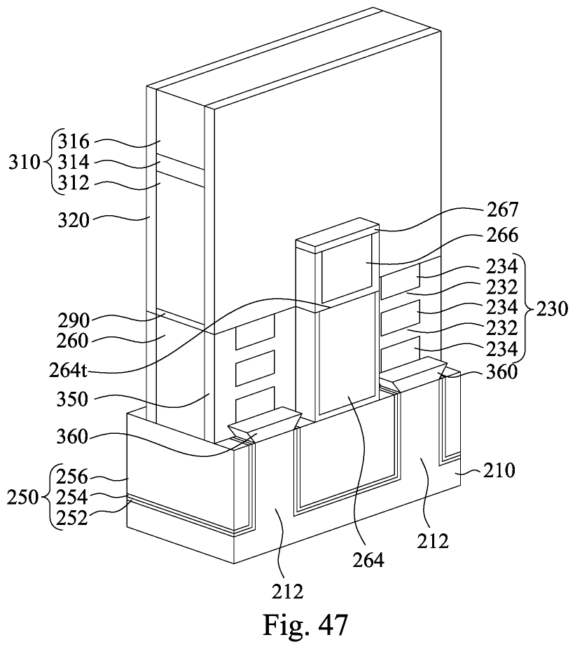

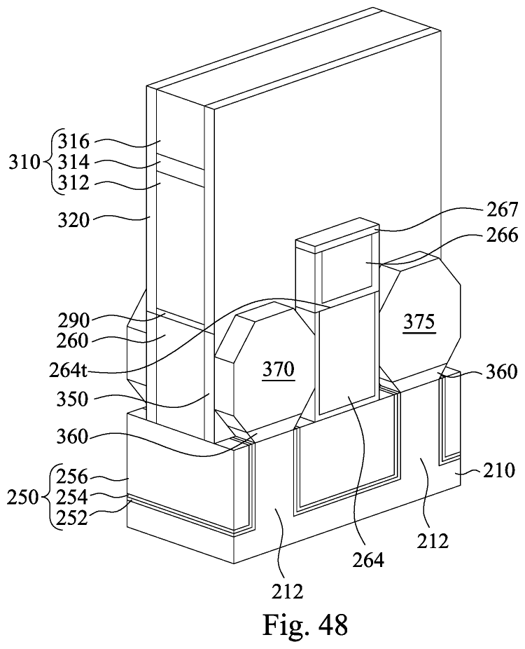

With reference to FIG. 47. Bottom epitaxial structures 360 are respectively formed on the base portions 212 of the substrate 210. In some embodiments, semiconductor materials are deposited on the base portions 212 to form the bottom epitaxial structures 360. The semiconductor materials include a single element semiconductor material, such as germanium (Ge) or silicon (Si), compound semiconductor materials, such as gallium arsenide (GaAs) or aluminum gallium arsenide (AlGeAs), or a semiconductor alloy, such as silicon germanium (SiGe) or gallium arsenide phosphide (GaAsP). The bottom epitaxial structures 360 have suitable crystallographic orientations (e.g., a (100), (110), or (111) crystallographic orientation). The epitaxial processes include CVD deposition techniques (e.g., vapor-phase epitaxy (VPE) and/or ultra-high vacuum CVD (UHV-CVD)), molecular beam epitaxy, and/or other suitable processes. In some embodiments, the bottom epitaxial structures 360 are intrinsic. That is, the bottom epitaxial structures 360 are undoped. The undoped bottom epitaxial structures 360 are benefit for reducing current leakage from top epitaxial structures 370 and 375 (see FIG. 48) to the substrate 210.

With reference to FIG. 48. Top epitaxial structures 370 and 375 are respectively formed on the bottom epitaxial structures 360. In some embodiments, semiconductor materials are deposited on the bottom epitaxial structures 360 to form the top epitaxial structures 370 and 375. The semiconductor materials include a single element semiconductor material, such as germanium (Ge) or silicon (Si), compound semiconductor materials, such as gallium arsenide (GaAs) or aluminum gallium arsenide (AlGaAs), or a semiconductor alloy, such as silicon germanium (SiGe) or gallium arsenide phosphide (GaAsP). The top epitaxial structures 370 and 375 have suitable crystallographic orientations (e.g., a (100), (110), or (111) crystallographic orientation). In some embodiments, the top epitaxial structures 370 and 375 include source/drain epitaxial structures. In some embodiments, where an N-type device is desired, the top epitaxial structures 370 may include an epitaxially grown silicon phosphorus (SiP) or silicon carbon (SiC). In some embodiments, where a P-type device is desired, the top epitaxial structures 375 may include an epitaxially grown silicon germanium (WiGe). The epitaxial processes include CVD deposition techniques (e.g., vapor-phase epitaxy (VPE) and/or ultra-high vacuum CVD (UHV-CVD)), molecular beam epitaxy, and/or other suitable processes. Desired p-type or n-type impurities may be, or may not be, doped while the epitaxial process. The doping may be achieved by an ion implantation process, plasma immersion ion implantation (PIII) process, gas and/or solid source diffusion process, other suitable process, or combinations thereof.

The dummy fin 268 can be configured to limit the space for epitaxially growing the top epitaxial structures 370 and 375. As a result, the top epitaxial structures 370 and 375 are confined between the dummy fin 268. This can be used to produce any desirable size of the top epitaxial structures 370 and 375, particularly small top epitaxial structures 370 and 375 for reducing parasitic capacitances. Further, air gaps 365 may be formed under the top epitaxial structures 370 and 375. For example, the air gap 365 is defined by the top epitaxial structure 370 (or 375), the bottom epitaxial structure 360, the dummy fin 268, and the isolation structure 250. In some embodiments, the top epitaxial structures 370 and 375 are in contact with the dummy fin 268, and the bottom epitaxial structures 360 are spaced apart from the dummy fin 268. In some embodiments, the top epitaxial structures 370 and/or 375 can be interchangeably referred to sources/drain regions, sources/drain patterns, or epitaxial structures.

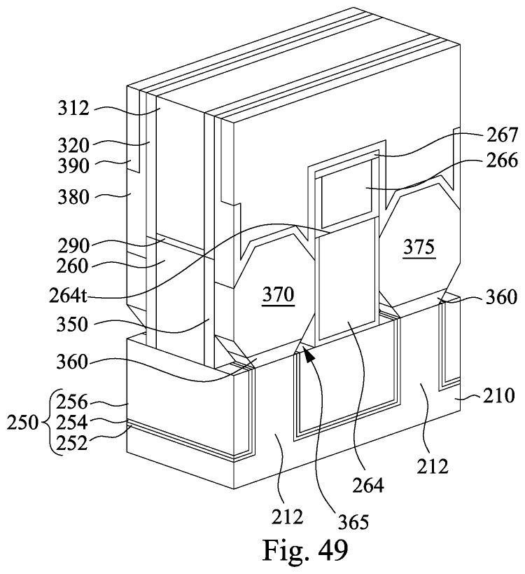

With reference to FIG. 49. A contact etch stop layer (CESL) 380 is conformally formed over the structure of FIG. 48. In some embodiments, the CESL 380 can be a stressed layer or layers. In some embodiments, the CESL 380 has a tensile stress and is formed of Si₃N₄. In some other embodiments, the CESL 380 includes materials such as oxynitrides. In yet some other embodiments, the CESL 380 may have a composite structure including a plurality of layers, such as a silicon nitride layer overlying a silicon oxide layer. The CESL 380 can be formed using plasma enhanced CVD (PECVD), however, other suitable methods, such as low pressure CVD (LPCVD), atomic layer deposition (ALD), and the like, can also be used.

An interlayer dielectric (ILD) 290 is then formed on the CESL 380. The ILD 390 may be formed by chemical vapor deposition (CVD), high-density plasma CVD, spin-on, sputtering, or other suitable methods. In some embodiments, the ILD 390 includes silicon oxide. In some other embodiments, the ILD 390 may include silicon oxy-nitride, silicon nitride, compounds including Si, O, C and/or H (e.g., silicon oxide, SiCOH and SiOC), a low-k material, or organic materials (e.g., polymers). After the ILD 390 is formed, a planarization operation, such as CMP, is performed, so that the pad layer 314 and the mask layer 316 (see FIG. 48) are removed and the dummy gate layer 312 is exposed.

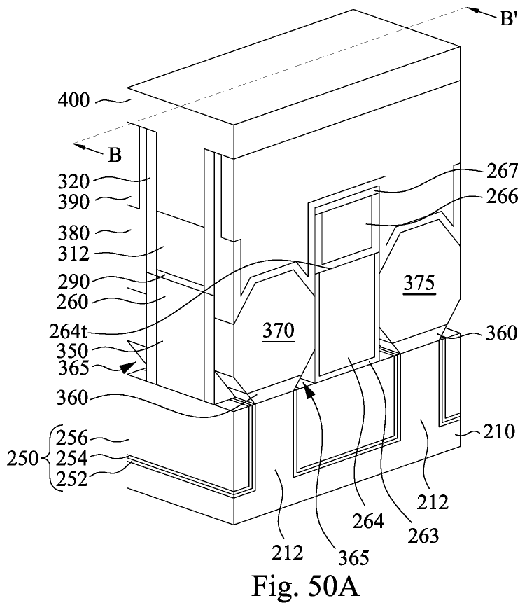

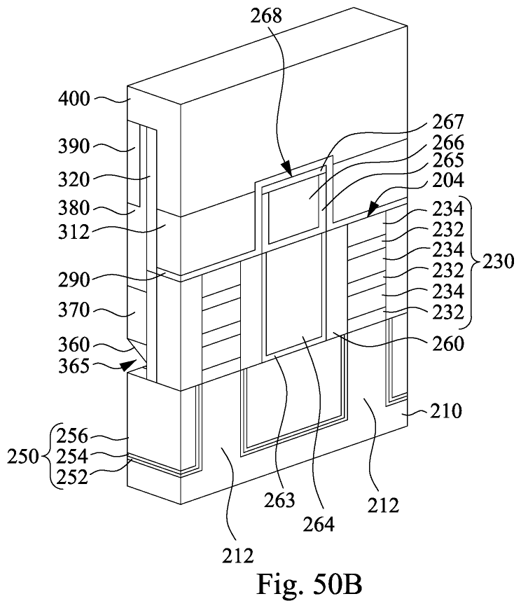

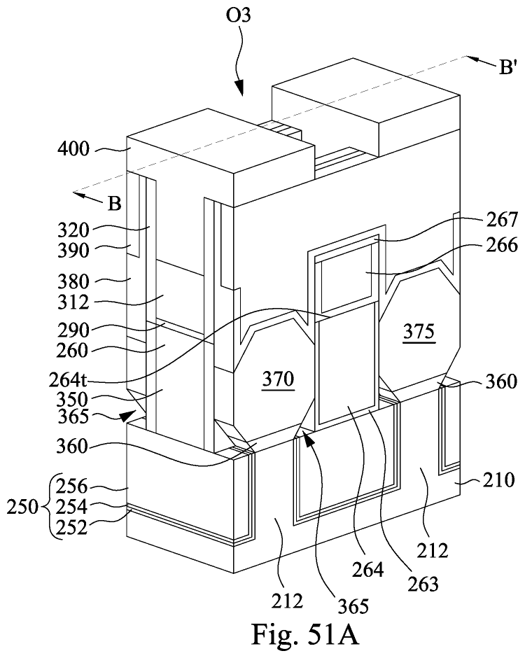

With reference to FIGS. 50A and 50B. The dummy gate layer 312 is etched back to expose portions of the interfacial layer 290 above the dummy fin 268 (see FIG. 50B). Subsequently, a resist layer 400 is formed above the etched back dummy gate layer 312. The resist layer 400 covers the dummy gate layer 312, the interfacial layer 290, the CESL 380, and the ILD 390.

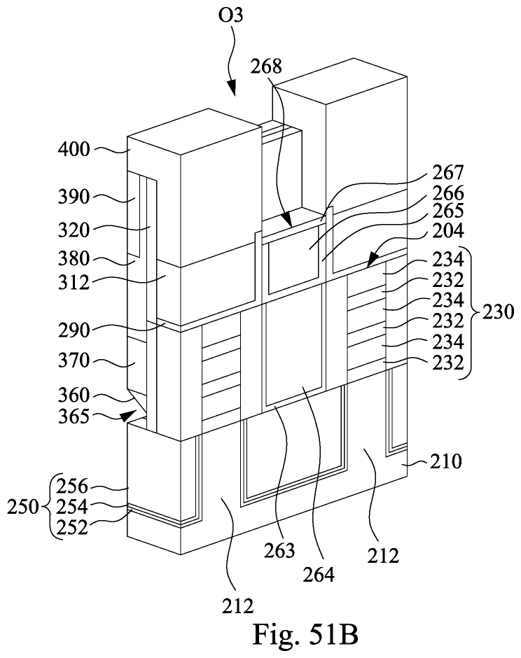

With reference to FIGS. 51A and 51B. The resist layer 400 is patterned to form an opening O3 therein, and the opening O3 exposes the interfacial layer 290 overlying the dummy fin 268. Subsequently, one or more etching processes including wet etch and/or dry etch is performed to remove a portion of the interfacial layer 290 overlying the dummy fin 268 as shown in FIG. 50B. Therefore, different portions of the gate structure 310 can be physically separated from each other by the opening O3.

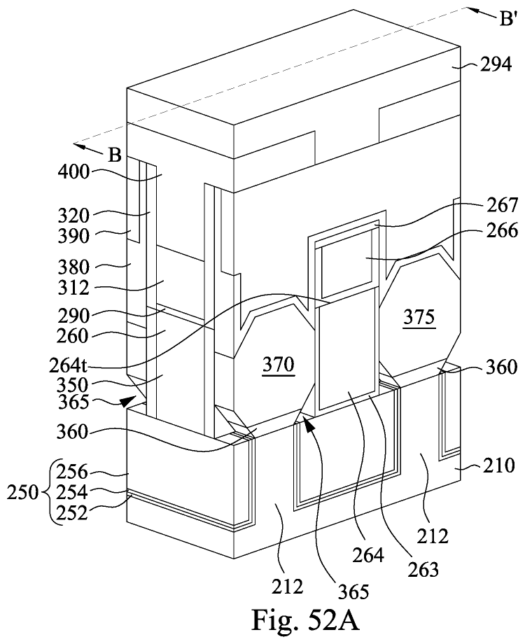

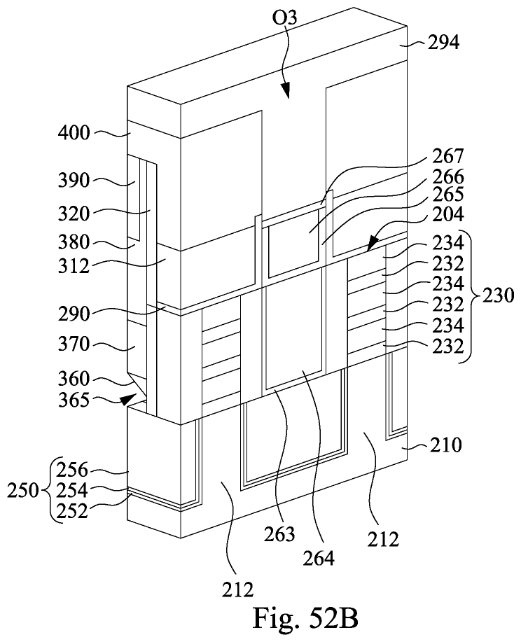

With reference to FIGS. 52A and 52B. A dielectric material 294 is filled in the opening O3 (see FIG. 52B) and formed over the resist layer 400. In some embodiments, the dielectric material 294 may include SiOC, SiON, SiOCN, or combinations thereof. In some embodiments, the dielectric material 294 may be made of a metal oxide. In some embodiments, the dielectric material 294 may include, for example, a high-k dielectric material such as metal oxides, metal nitrides, metal silicates, transition metal-oxides, transition metal-nitrides, transition metal-silicates, oxynitrides of metals, metal aluminates, zirconium silicate, zirconium aluminate, or combinations thereof. In some embodiments, the dielectric material 294 may be made of a material having a dielectric constant greater than about 10. In some embodiments, the dielectric material 294 may include hafnium oxide (HfO₂), hafnium silicon oxide (HfSiO), hafnium silicon oxynitride (HfSiON), hafnium tantalum oxide (HfTaO), hafnium titanium oxide (HfTiO), hafnium zirconium oxide (HfZrO), lanthanum oxide (LaO), zirconium oxide (ZrO₂), titanium oxide (TiO₂), tantalum oxide (Ta₂O₅), yttrium oxide (Y₂O₃), strontium titanium oxide (SrTiO₃, STO), barium titanium oxide (BaTiO₃, BTO), barium zirconium oxide (BaZrO), hafnium lanthanum oxide (HfLaO), lanthanum silicon oxide (LaSiO), aluminum silicon oxide (AlSiO), aluminum oxide (Al₂O₃), silicon nitride (Si₃N₄), oxynitrides (SiON), any suitable materials, or combinations thereof. In some embodiments, the dielectric material 294 may include SICN, SiO₂, HZO (a mixture of HfO₂ and ZrO₂), PZT (PbZr_{0.52}Ti_{0.44}O₃), VDF-TrFE (ferroelectric polymer), any suitable materials, or combinations thereof. In alternative embodiments, the dielectric material 294 may have a multilayer structure including, such as a silicon oxide layer (e.g., SiO₂ layer), a first high-k material layer (e.g., HfO₂ layer), and a second high-k material layer (e.g., ZrO₂ layer). In some embodiments, the dielectric material 294 may be deposited using any suitable method, such as CVD, physical vapor deposition (PVD), ALD, PEALD, PECVD, SACVD, FCVD, spin-on, and/or the like, or a combination thereof. In some embodiments, the dielectric material 294 can be interchangeably referred to a dielectric film.

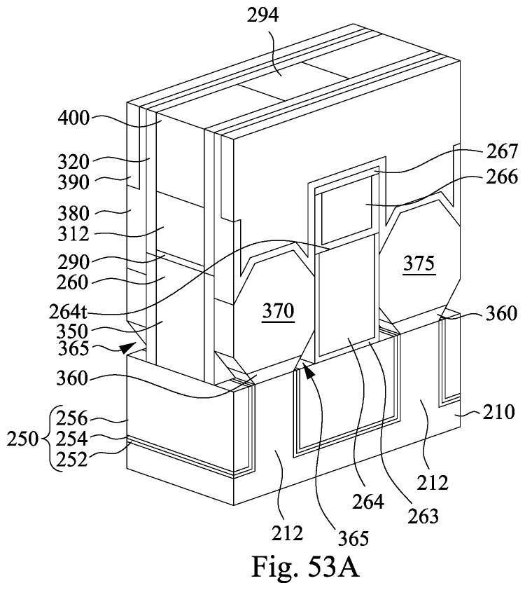

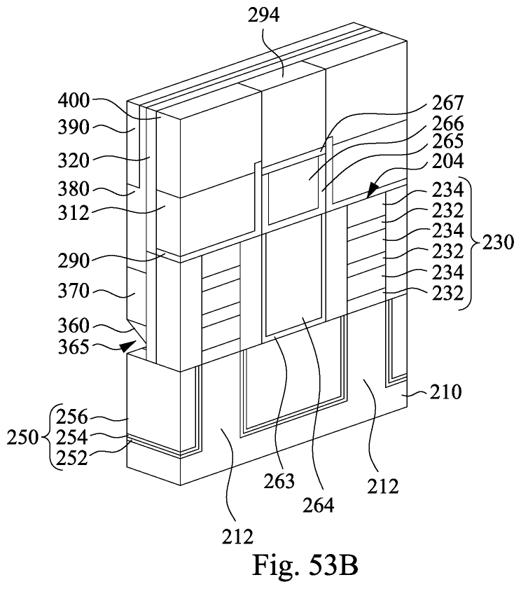

With reference to FIGS. 53A and 53B. A planarization process such as chemical mechanical polish (CMP) is performed to remove the dielectric material 294 and the resist layer 400 over the semiconductor stack 230. In some embodiments, the planarization process stops when the CESL 380, the ILD 390, and/or the gate spacers 320 are exposed. In such embodiments, the CESL 380, the ILD 390, and/or the gate spacers 320 may act as the CMP stop layer in the planarization. As shown in FIGS. 53A and 53B, the dielectric material 294 runs through the dummy gate layer 312 and the interfacial layer 290 to land on the dummy fin 268. In some embodiments, the dielectric material 294 is interposed between two gate structures so as to act as an isolator between two active devices.

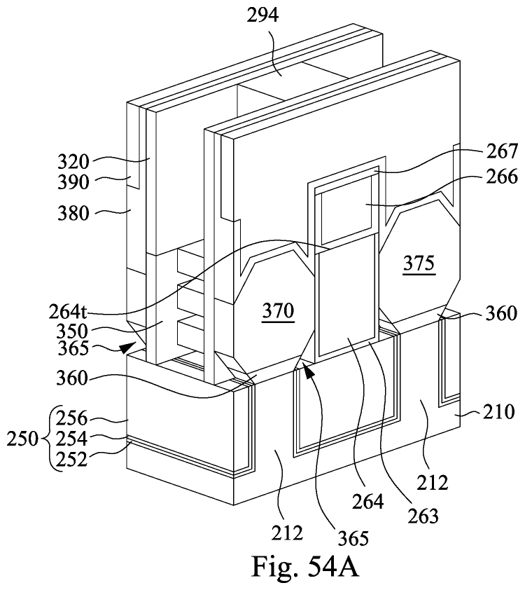

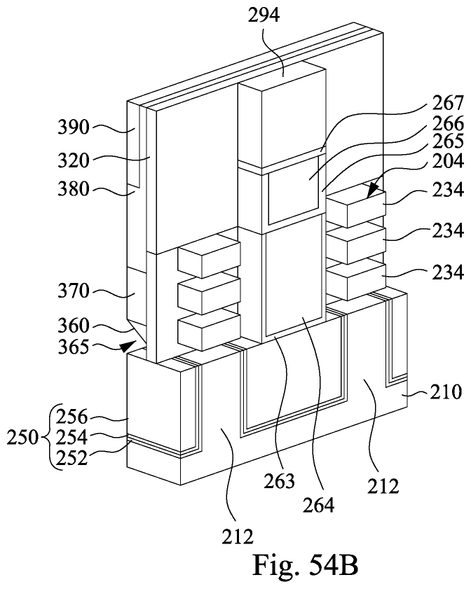

With reference to FIGS. 54A and 54B. After the etching process, a remainder of the resist layer 400 (see FIGS. 53A and 53B) may be stripped by, for example, an ashing process, such as a plasma ashing process using O₂ or another stripping process, and a cleaning process, such as a wet dip in dilute hydrofluoric acid or an organic chemical, may be performed to remove any contaminants from the surface of the dummy gate layer 312. The dummy gate layer 312 and the interfacial layer 290 (see FIGS. 53A and 53B) are then removed, thereby exposing the semiconductor layers 234 and the cladding layers 260. The ILD 390 protects the epitaxial structures 370 and 375 during the removal of the dummy gate layer 312. The dummy gate layer 312 can be removed using plasma dry etching and/or wet etching. When the dummy gate layer 312 is polysilicon and the ILD 390 is silicon oxide, a wet etchant such as a TMAH solution can be used to selectively remove the dummy gate layer 312. The dummy gate layer 312 is thereafter removed using plasma dry etching and/or wet etching. Subsequently, the interfacial layer 290 is removed as well. As such, the cladding layers 260 and the topmost semiconductor layers 234 are exposed. After the dummy gate layer 312 (see FIG. 53B) is removed, the remaining semiconductor layers 232 and the cladding layers 260 (see FIG. 53B) are removed, thereby forming sheets (or wires or rods or columns) of the semiconductor layers 234. The semiconductor layers 232 and the cladding layers 260 can be removed or etched using an etchant that can selectively etch the semiconductor layers 232 and the cladding layers 260. In some embodiments, the etchant for removing the semiconductor layers 232 and the cladding layers 260 is F₁ (Fluorine).

With reference to FIGS. 55A and 55B. A gate structure 410 is formed and/or filled between the gate spacers 320 or the inner sidewall spacers 350. That is, the gate structure 410 encircles (wraps) the semiconductor layers 234. The gate spacers 320 are disposed on opposite sides of the gate structure 410. The gate structure 410 includes a gate dielectric layer 412 and a gate electrode 414. The gate electrode 414 includes one or more work function metal layer (s) and a filling metal. The gate dielectric layer 412 is conformally formed. That is, the gate dielectric layer 412 is in contact with the isolation structures 250, the bottom isolation layers 230, the protection layers 125, the semiconductor layers 234, the dummy fin structures 268, in which the semiconductor layers 234 are referred to as channels of the semiconductor device. The gate dielectric layer 412 is spaced apart from the bottom spacers 240 in some embodiments. Furthermore, the gate dielectric layer 412 surrounds the semiconductor layers 234, and spaces between the semiconductor layers 234 are still left after the deposition of the gate dielectric layer 412. In some embodiments, the gate dielectric layer 412 includes a high-k material (k is greater than 7) such as hafnium oxide (HfO₂), zirconium oxide (ZrO₂), lanthanum oxide (La₂O₃), hafnium aluminum oxide (HfAlO₂), hafnium silicon oxide (HfSlO₂), aluminum oxide (Al₂O₃), or other suitable materials. In some embodiments, the gate dielectric layer 412 may be formed by performing an ALD process or other suitable process. In some embodiments, the thickness of the gate dielectric layer 412 is in a range of about 10 nm to about 30 nm.

The work function metal layer is conformally formed on the gate dielectric layer 412, and the work function metal layer surrounds the semiconductor layers 234 in some embodiments. The work function metal layer may include materials such as TiN, TaN, TiAlSi, TiSiN, TiAl, TaAl, or other suitable materials. In some embodiments, the work function metal layer may be formed by performing an ALD process or other suitable process. The filling metal fills the remained space between the gate spacers 320 and between the inner sidewall spacers 350. That is, the work function metal layer(s) is in contact with and between the gate dielectric layer 412 and the filling metal. The filling metal may include material such as tungsten or aluminum. After the deposition of the gate dielectric layer 412 and the gate electrode 414, a planarization process, such as a CMP process, may be then performed to remove excess portions of the gate dielectric layer 412 and the gate electrode 414 to form the gate structure 410. In some embodiments, the gate structure 410 can be interchangeably referred to a gate patter or a gate strip.

With reference to FIG. 56. An ILD layer 420 is formed over the replacement gate structures 310 and the dielectric material 294. Subsequently, contact holes O2 may be formed by any suitable process in the ILD layer 420. Subsequently, a conductive material fills in the contact holes O2. In some embodiments, the conductive material may includes TiN, TaN, Ta, Ti, Hf, Zr, Ni, W, Co, Cu, Ag, Al, Zn, Ca, Au, Mg, Mo, Cr, or the like. In some embodiments, the conductive material layer may be formed by CVD, PVD, plating, ALD, or other suitable technique. Subsequently, a CMP process may be performed to remove a portion of the conductive material above a top surface of the ILD layer 420. After planarization, the gate contacts 430 are formed. The gate contacts 430 go through the ILD layer 420 to provide electrical contact to the replacement gate structures 310.

Therefore, based on the above discussions, it can be seen that the present disclosure offers advantages. It is understood, however, that other embodiments may offer additional advantages, and not all advantages are necessarily disclosed herein, and that no particular advantage is required for all embodiments. The present disclosure in various embodiments provides a method for curing the flowable CVD oxide without a high temperature, and thus the surrounding semiconductive fin structure will not be impacted by the curing process.

In some embodiments, a method includes forming fin structures upwardly extending above a semiconductor substrate; conformally depositing a first dielectric layer over the fin structures; depositing a flowable oxide over the first dielectric layer and between the fin structures; performing, at a temperature lower than about 500° C., a steam annealing process on the flowable oxide to cure the flowable oxide; after performing the steam annealing process, etching the cured flowable oxide until a top surface of the cured flowable oxide is lower than top surfaces of the fin structures; forming a second dielectric layer over the cured flowable oxide; forming a first gate structure extending across a first one of the fin structures and a second gate structure extending across a second one of the fin structures; forming first sources/drain regions on the first one of the fin structures and second sources/drain regions on the second one of the fin structures. In some embodiments, the method further includes after performing the steam annealing process, performing a dry annealing process on the flowable oxide under a higher temperature than the steam annealing process. In some embodiments, the dry annealing process is performed at a temperature lower than about 800° C. In some embodiments, the steam annealing process is performed in a time duration less than about 2 hours. In some embodiments, the steam annealing process is performing in an ambient having a H₂O concentration in a range from about 5% to about 100%. In some embodiments, depositing the flowable oxide is performed with precursors comprising tri-silylamine, ammonia, and oxygen. In some embodiments, depositing the flowable oxide is performed at a temperature in a range from about 10° C. to about 500° C. In some embodiments, the first dielectric layer is made of metal oxide. In some embodiments, the second dielectric layer is made of metal oxide. In some embodiments, the flowable oxide comprises sulfur.

In some embodiments, a method includes forming first and second semiconductive channel patterns on a substrate; conformally depositing a first metal oxide layer over the first and second semiconductive channel patterns; filling a trench formed between the first and second semiconductive channel patterns with a dielectric material by using a flowable chemical vapor deposition (FCVD) process; curing the dielectric material in a steam-containing ambient at a first temperature; after curing the dielectric material, annealing the dielectric material in a steam-free ambient at a second temperature, the second temperature being higher than the first temperature; thinning down the dielectric material; depositing a second metal oxide layer over the thinned dielectric material; planarizing the first and second metal oxide layers until the first and second semiconductive channel patterns are exposed; forming first sources/drain patterns on the first semiconductive channel pattern and second sources/drain patterns on the second semiconductive channel pattern; forming a first gate pattern between the first sources/drain patterns and a second gate pattern between the second sources/drain patterns. In some embodiments, curing the dielectric material is performed at a temperature lower than about 500° C. In some embodiments, the FCVD process is performed at a third temperature lower than the second temperature. In some embodiments, the first semiconductive channel pattern is made of silicon germanium having a germanium atomic concentration in a range from about 17% to about 30%. In some embodiments, the first metal oxide layer comprises sulfur.

In some embodiments, the semiconductor structure includes first and second nanostructured pedestals, a shallow trench isolation (STI) structure, a cured flowable oxide material, a first metal oxide layer, a second metal oxide layer, a first gate strip, a second gate strip, first epitaxial structures, and second epitaxial structures. The first and second nanostructured pedestals are on a substrate and each has a top surface and opposite side surfaces. The STI structure laterally surrounds lower portions of the first and second nanostructured pedestals. The cured flowable oxide material is laterally between the first and second nanostructured pedestals and is over the STI structure. The cured flowable oxide material is free of void. The first metal oxide layer is laterally between the first and second nanostructured pedestals. The first metal oxide layer cups an underside of the cured flowable oxide material. The first metal oxide layer has an U-shaped profile from a cross-sectional view. The second metal oxide layer is over the cured flowable oxide material. The first gate strip wraps around the top surface and the opposite side surfaces of the first nanostructured pedestal. The second gate strip wraps around the top surface and the opposite side surfaces of the second nanostructured pedestal. The first epitaxial structures are on the first nanostructured pedestal. The second epitaxial structures are on the second nanostructured pedestal. In some embodiments, the first metal oxide layer has a thinner thickness than the cured flowable oxide material. In some embodiments, the first metal oxide layer has a thickness in a range from about 3 nm to about 5 nm. In some embodiments, the cured flowable oxide material has a thickness in a range from about 7 nm to about 13 nm. In some embodiments, the second metal oxide layer comprises sulfur.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method, comprising:
forming fin structures upwardly extending above a semiconductor substrate;
conformally depositing a first dielectric layer over the fin structures;
depositing a flowable oxide over the first dielectric layer and between the fin structures;
performing, at a temperature lower than about 500° C., a steam annealing process on the flowable oxide to cure the flowable oxide;
after performing the steam annealing process, etching the cured flowable oxide until a top surface of the cured flowable oxide is lower than top surfaces of the fin structures;
forming a second dielectric layer over the cured flowable oxide;
forming a first gate structure extending across a first one of the fin structures and a second gate structure extending across a second one of the fin structures; and
forming first sources/drain regions on the first one of the fin structures and second sources/drain regions on the second one of the fin structures.

2. The method of claim 1, further comprising:
after performing the steam annealing process, performing a dry annealing process on the flowable oxide under a higher temperature than the steam annealing process.

3. The method of claim 2, wherein the dry annealing process is performed at a temperature lower than about 800° C.

4. The method of claim 1, wherein the steam annealing process is performed in a time duration less than about 2 hours.

5. The method of claim 1, wherein the steam annealing process is performing in an ambient having a H₂O concentration in a range from about 5% to about 100%.

6. The method of claim 1, wherein depositing the flowable oxide is performed with precursors comprising tri-silylamine, ammonia, and oxygen.

7. The method of claim 1, wherein depositing the flowable oxide is performed at a temperature in a range from about 10° C. to about 500° C.

8. The method of claim 1, wherein the first dielectric layer is made of metal oxide.

9. The method of claim 1, wherein the second dielectric layer is made of metal oxide.

10. The method of claim 1, wherein the flowable oxide comprises sulfur.

11. A method, comprising:
forming first and second semiconductive channel patterns on a substrate;
conformally depositing a first metal oxide layer over the first and second semiconductive channel patterns;
filling a trench formed between the first and second semiconductive channel patterns with a dielectric material by using a flowable chemical vapor deposition (FCVD) process;
curing the dielectric material in a steam-containing ambient at a first temperature;
after curing the dielectric material, annealing the dielectric material in a steam-free ambient at a second temperature, the second temperature being higher than the first temperature;
thinning down the dielectric material;
depositing a second metal oxide layer over the thinned dielectric material;
planarizing the first and second metal oxide layers until the first and second semiconductive channel patterns are exposed;
forming first sources/drain patterns on the first semiconductive channel pattern and second sources/drain patterns on the second semiconductive channel pattern; and
forming a first gate pattern between the first sources/drain patterns and a second gate pattern between the second sources/drain patterns.

12. The method of claim 11, wherein curing the dielectric material is performed at a temperature lower than about 500° C.

13. The method of claim 11, wherein the FCVD process is performed at a third temperature lower than the second temperature.

14. The method of claim 11, wherein the first semiconductive channel pattern is made of silicon germanium having a germanium atomic concentration in a range from about 17% to about 30%.

15. The method of claim 11, wherein the first metal oxide layer comprises sulfur.

16. A semiconductor structure, comprising:
first and second nanostructured pedestals on a substrate and each having a top surface and opposite side surfaces;
a shallow trench isolation (STI) structure laterally surrounding lower portions of the first and second nanostructured pedestals;
a cured flowable oxide material laterally between the first and second nanostructured pedestals and over the STI structure, the cured flowable oxide material being free of void;
a first metal oxide layer laterally between the first and second nanostructured pedestals, the first metal oxide layer cupping an underside of the cured flowable oxide material, and the first metal oxide layer having an U-shaped profile from a cross-sectional view;
a second metal oxide layer over the cured flowable oxide material;
a first gate strip wrapping around the top surface and the opposite side surfaces of the first nanostructured pedestal, and a second gate strip wrapping around the top surface and the opposite side surfaces of the second nanostructured pedestal; and
first epitaxial structures on the first nanostructured pedestal, and second epitaxial structures on the second nanostructured pedestal.

17. The semiconductor structure of claim 16, wherein the first metal oxide layer has a thinner thickness than the cured flowable oxide material.

18. The semiconductor structure of claim 16, wherein the first metal oxide layer has a thickness in a range from about 3 nm to about 5 nm.

19. The semiconductor structure of claim 16, wherein the cured flowable oxide material has a thickness in a range from about 7 nm to about 13 nm.

20. The semiconductor structure of claim 16, wherein the second metal oxide layer comprises sulfur.
